(19) United States
(12) Patent Application Publication
(10) Pub. No.: US 2026/0241881 A1
(43) Pub. Date: Aug. 20, 2026

(54) COMPONENT FOR VEHICLE INTERIOR

(71) Applicant: Yanfeng International Automotive Technology Co. Ltd., Novi, MI (US)

(72) Inventors: Michael Edwards Phillips, Holland, MI (US); Jennifer A. Stroebe, Holland, MI (US); Jason Denbow, Fennville, MI (US); Jason Mathew Hipshier, Hudsonville, MI (US); Michael Robert Catlin, Holland, MI (US); Michael John Thomas, Ann Arbor, MI (US)

(21) Appl. No.: 19/644,082

(22) Filed: Apr. 10, 2026

Related U.S. Application Data
(63) Continuation of application No. PCT/US2024/053146, filed on Oct. 26, 2024.

(30) Foreign Application Priority Data
Oct. 26, 2024 (WO) PCT/US2024/053146

(51) Int. Cl. B60R 16/03; B60R 13/02; B60R 16/02; H05K 1/03

(52) U.S. Cl. CPC B60R 16/03; B60R 16/0215; H05K 1/0366; B60R 13/02

(57) ABSTRACT

A component for a vehicle interior comprising a composite structure is disclosed. The composite structure comprises a structural substrate comprising a compression-formed fiber panel and a conductor arrangement such as a functional circuit; the compression-formed fiber panel may be formed with the conductor arrangement; the conductor arrangement and a connection point; the composite structure may comprise a feature for the connection point to provide a connector such as a projection, flange, tab, block, plug-socket, angled tab, resin structure; the connector may comprise an internal connector, external connector, edge connector at/within a perimeter/body of the fiber panel; the connector may comprise a conductive trace, multi-layer pattern, insulated lead/band and/or conductive wire and/or conductive thread. The connector may connect the conductor arrangement to a power source, vehicle system, network.

### CROSS-REFERENCE TO RELATED APPLICATIONS

The present application is a continuation of PCT/International Patent Application No. PCT/US2024/053146 titled “COMPONENT FOR VEHICLE INTERIOR filed Oct. 26, 2024, which claims priority to: (a) U.S. patent application Ser. No. 18/495,375 titled “VEHICLE TRIM COMPONENT” filed Oct. 26, 2023; (b) U.S. Provisional Patent Application No. 63/682,845 titled “COMPONENT FOR VEHICLE INTERIOR” filed Aug. 14, 2024; and (c) U.S. Provisional Patent Application No. 63/682,850 titled “COMPONENT FOR VEHICLE INTERIOR” filed Aug. 14, 2024.

The present application claims priority to and incorporates by reference in full the following patent applications: (a) U.S. patent application Ser. No. 18/495,375 titled “VEHICLE TRIM COMPONENT” filed Oct. 26, 2023; (b) U.S. Provisional Patent Application No. 63/682,845 titled “COMPONENT FOR VEHICLE INTERIOR” filed Aug. 14, 2024; (c) U.S. Provisional Patent Application No. 63/682,850 titled “COMPONENT FOR VEHICLE INTERIOR” filed Aug. 14, 2024; (d) PCT/International Patent Application No. PCT/US2024/053146 titled “COMPONENT FOR VEHICLE INTERIOR filed Oct. 26, 2024.

The present application relates to and incorporates by reference in full the following patent applications/documents: (1) U.S. patent application Ser. No. 18/495,375 titled “VEHICLE TRIM COMPONENT” filed Oct. 26, 2023; (2) U.S. Provisional Patent Application No. 63/682,845 titled “COMPONENT FOR VEHICLE INTERIOR” filed Aug. 14, 2024; (3) U.S. Provisional Patent Application No. 63/682,850 titled “COMPONENT FOR VEHICLE INTERIOR” filed Aug. 14, 2024; (4) PCT/International Patent Application No. PCT/US2024/053146 titled “COMPONENT FOR VEHICLE INTERIOR filed Oct. 26, 2024; (5) U.S. Pat. No. 8,939,745 titled “SYSTEM AND METHOD FOR MANUFACTURING A VEHICLE TRIM COMPONENT VIA CONCURRENT COMPRESSION FORMING AND INJECTION MOLDING” from U.S. patent application Ser. No. 13/595,741 filed Aug. 27, 2012; (6) U.S. Patent Application Publication No. US2020/0406513 titled “VEHICLE TRIM COMPONENT” from U.S. patent application Ser. No. 17/021,335 filed Sep. 15, 2020.

### FIELD

The present invention relates to a vehicle interior component.

The present invention also relates to an improved vehicle interior component comprising a composite structure such as a substrate comprising a panel such as a fiber panel and a cover and a conductor arrangement and/or functional element/layer.

### BACKGROUND

It is known to provide a vehicle interior component.

It would be advantageous to provide an improved vehicle interior component comprising a composite structure such as a substrate comprising a panel such as a fiber panel and a cover and a conductor arrangement and/or functional element/layer.

It would be advantageous to provide an improved vehicle interior component comprising a composite structure such as a substrate comprising a panel such as a fiber panel and a cover and a conductor arrangement and/or functional element/layer comprising a functional circuit.

It would be advantageous to provide an improved vehicle interior component comprising a composite structure such as a substrate comprising a panel such as a fiber panel and a cover and a functional element/layer comprising a conductor arrangement.

It would be advantageous to provide an improved vehicle interior component comprising a composite structure such as a substrate comprising a panel such as a fiber panel and a cover and a conductor arrangement and/or functional element/layer configured to comprise a functional circuit.

It would be advantageous to provide an improved vehicle interior component comprising a composite structure configured to provide a circuit element.

It would be advantageous to provide a vehicle interior component comprising a composite structure configured to provide an arrangement of conductors for a circuit element.

It would be advantageous to provide a vehicle interior component comprising a composite structure configured to provide an arrangement of conductors for a circuit element to provide a functional circuit.

It would be advantageous to provide a vehicle interior component comprising a composite structure comprising a fiber panel configured to provide an arrangement of conductors for a circuit element to provide a functional circuit.

### SUMMARY

The present invention relates to a component for a vehicle interior comprising a composite structure comprising a structural substrate comprising a compression-formed fiber panel and a conductor arrangement; the compression-formed fiber panel may be formed by compression-forming of a fiber panel with the conductor arrangement; the conductor arrangement may be configured to provide a functional circuit and a connection point; the composite structure may comprise a feature for the connection point; the connection point may comprise a connector for the functional circuit; the connector may comprise a projection and/or a flange and/or a tab; the connector may comprise a connector block; the connector may comprise an internal connector; the connector may comprise an external connector; the connector may comprise an edge connector; the connector may comprise an internal edge connector and/or an external edge connector; the edge connector may comprise a tab on the composite structure configured to fit within a socket; the structural substrate may comprise a generally flat form; the tab may be provided at a perimeter of the structural substrate and/or within a perimeter of the structural substrate; the tab may be provided at an angle relative to the structural substrate; the connector may be integrated on and/or within the compression-formed fiber panel; the connector may be configured to connect to the functional circuit at the connection point; the connector may comprise a conductive trace and/or a pattern of conductive traces and/or a set of electrically conductive traces and/or a multi-layer conductor pattern and/or a set of conductive traces and/or a wire and/or an insulated wire and/or an exposed wire and/or a generally flat trace and/or a generally flat wire and/or a lead and/or a band and/or conductive wire and/or conductive thread; the connector may be provided within the fiber panel and/or provided on the fiber panel and/or provided into the fiber panel and/or provided onto the fiber panel; the connector may be formed into the compression-formed fiber panel; the connector of the composite structure may comprise a plug for the connection point; the connector may comprise a socket and a plug at the connection point; the plug may engage the socket to secure the connection of the functional circuit to vehicle systems; the feature may comprise a formed feature and/or a resin feature and/or a formed resin feature and/or a molded resin feature and/or a formed structure and/or a molded structure and/or a molded resin structure and/or an injection-molded structure and/or a structure configured to provide support for the connector and/or a module for the connector and/or a resin structure and/or a molded structure and/or a reinforcement and/or a rib; the feature may comprise a structure for the connector and/or a support for the connector and/or a housing for the connector; the feature may comprise a reinforcement for the fiber panel and/or a reinforcement for the functional circuit and/or a structural reinforcement for the composite structure; the feature may comprise at least one of a housing for an electrical connector and a cover for an electrical connector to the conductor arrangement and/or a connection point for the conductor arrangement and/or a wire; the connector may be configured to connect to a power source and/or at least one vehicle system.

The present invention relates to a component for a vehicle interior. The component may comprise a composite structure comprising a substrate comprising a fiber panel; the fiber panel may comprise a conductor arrangement; the conductor arrangement may be configured to provide a functional circuit for the composite structure; the substrate may comprise a structural substrate; the structural substrate may comprise a compression-formed fiber panel. The conductor arrangement and/or functional circuit may be configured to comprise at least one of: a conductor; a sensor/detector; an input device; an output device; an interactive device; a display; a switch; a light/lighting; a light element; a light guide. The conductor arrangement and/or functional circuit may be configured to comprise at least one of a light/lighting; a light element; a light guide; an LED; LED lighting; a display; a display panel; an antenna; a camera; a video-recorder; an image display/device; a user interface; an input device; an output device; an input/output device; a sensor; a detector; a switch; a touch sensor; an odor/scent detector; a microphone; a sound detector; a wireless charging device; a wireless connection area; a heating element; an electrified area; other device/technology. The composite structure may comprise a base; the base may comprise a structural substrate; the fiber panel may comprise a compression-formed fiber panel. The substrate may comprise a feature; the feature may comprise a formed feature; the feature may comprise a molded resin feature; the feature may comprise at least one of a molded resin structure and/or a molded resin border and/or a molded resin reinforcement; the conductor arrangement may comprise a formed circuit comprising the functional circuit. The composite structure may comprise a fiber panel with a circuit panel comprising the functional circuit; the composite structure may comprise the fiber panel and a circuit matrix; the composite structure may comprise a cover. The conductor arrangement may comprise a conductor; a conductor may be within the fiber panel; a conductor may be on the fiber panel. The conductor arrangement may comprise a conductive trace; the conductive trace may comprise a conductor; the conductor arrangement may comprise a pattern of electrically conductive traces; the conductor arrangement may comprise a set of electrically conductive traces; a conductive trace may be within the fiber panel and/or on the fiber panel; a conductive trace may be provided into the fiber panel and/or onto the fiber panel. The fiber panel may comprise a mixture of fibers and plastic; the fibers may comprise natural fibers; the fibers comprise at least one of synthetic fibers, glass fibers, carbon fibers and/or polymeric fibers; the fiber panel may comprise a substantially rigid panel; the fiber panel may comprise a plurality of fibers and a resin configured to bind the fibers; the resin may comprise thermoplastic resin; the fiber panel may be configured to provide structural properties comprising rigidity and strength; the fiber panel may comprise a generally rigid panel formed from a fiber mat; the fiber panel may comprise a contoured fiber panel. The composite structure may comprise a feature on the fiber panel; the feature may be configured to provide a connection point for the functional circuit; the feature may comprise a molded resin structure; the feature may comprise a structure configured to provide support for a module for the functional circuit. The composite structure may comprise a flexible circuit formed on and/or in and/or with the fiber panel; the fiber panel may comprise the circuit board comprising the functional circuit; the composite structure may comprise a circuit panel comprising the conductor arrangement comprising a conductor pattern comprising a conductive trace; the conductor arrangement may comprise a conductor pattern comprising the functional circuit; the fiber panel may comprise a circuit panel; the conductor arrangement may comprise a pattern on the fiber panel; the conductor arrangement may comprise a metallic material and/or a metallic trace; the conductor arrangement may comprise a wire and/or an insulated wire; the conductor arrangement may comprise an exposed wire; the conductor arrangement may comprise a generally flat wire; the conductor arrangement may comprise a lead and/or a band; the conductor arrangement may comprise a multi-layer conductor pattern for the fiber panel; the multi-layer conductor pattern may comprise a set of conductive traces providing the functional circuit. The functional circuit may comprise a user interface; the user interface may comprise an input device and/or an output device; the functional circuit may comprise an input device and an output device; the functional circuit may comprise a connection point; the functional circuit may comprise a connector; the functional circuit may comprise a connector configured to connect to a power source and/or at least one vehicle system; the functional circuit may comprise a circuit element; the functional circuit may be configured for connection by an edge connector; the functional circuit may be configured for connection by an internal connector; the functional circuit may be configured for connection by an internal edge connector; the functional circuit may be configured for connection by an edge connector comprising a tab on the composite structure; the functional circuit may be configured for connection by an edge connector comprising a tab on the composite structure configured to fit within a socket; the functional circuit may be configured for operation by a control system; the functional circuit may comprise a controller configured for operation with a control system configured for operation of at least one vehicle system; the functional circuit may comprise a module; the functional circuit may comprise a connection point for a module. The functional circuit may comprise a user interface configured for operation of at least one vehicle system; the functional circuit may comprise a sensor; the functional circuit may comprise a sensor configured to operate as a switch; the functional circuit may comprise at least one of a light, an LED light, a display, an illuminated feature; the functional circuit may comprise an input device; the input device may comprise a switch; the functional circuit may comprise an output device; the output device may comprise a display; the functional circuit may be configured to operate a user interface comprising an input device and an output device. The functional circuit may be configured to operate a mechanism and/or a motor. The component may comprise a connector for the functional circuit; the functional circuit may be configured to be connected to a vehicle system and/or a network and/or a power source. The composite structure may comprise a feature on the fiber panel; the feature may comprise a resin structure; the feature may comprise a molded structure; the feature may comprise a rib; the feature may comprise a resin structure adjacent to the functional circuit; the fiber panel may comprise a conductor pattern comprising a conductive trace and the feature adjacent to the conductive trace; the feature may comprise an ancillary component on the fiber panel; the ancillary component may be molded on the fiber panel over the conductor arrangement; the ancillary component may comprise a structure for functional circuit and/or a support for functional circuit and/or a housing for functional circuit and/or a structure for connection to the functional circuit. The feature may comprise a reinforcement for the fiber panel and/or a reinforcement for the functional circuit; the feature may comprise a structural reinforcement for the composite structure; the conductor arrangement may comprise conductive wire and/or conductive thread; conductive thread may comprise wire; the composite structure may comprise a cover; the composite structure may comprise a foam layer beneath the cover; the composite structure may comprise a cover; the composite structure may comprise an intermediate layer beneath the cover; the conductor arrangement may be configured to be substantially functionally effective; the conductor arrangement may be configured to be substantially visually imperceptible under the cover; the composite structure may be configured so that the functional circuit is substantially visually imperceptible under the cover. The composite structure may comprise a cover; the cover may comprise at least one of (a) leather; (b) synthetic leather; (c) imitation leather; (d) a composite of a plastic layer and textile backing; (e) a coated fabric; (f) polyvinylchloride coated fabric; (g) a woven fabric; (h) a non-woven fabric; (i) an applique; (j) vinyl; (k) a foil; (1) coating on the structural substrate; (m) paint on the structural substrate; (n) the exterior surface of the structural substrate; (o) at least partial concealment for the electrical conductor arrangement. The component may comprise at least one of a trim panel, an instrument panel, a door panel, an overhead panel, a console, an overhead console, a floor console, an interior trim component, pillar trim, an operator control, a steering control, a steering wheel, a trunk, a frunk, a hatch, a car rear compartment, a car front compartment, a visor, a vanity, a glove box, a receptacle in an instrument panel.

The present invention relates to a component for a vehicle interior. The component may comprise a composite structure comprising a substrate and a cover; the substrate may comprise a conductor arrangement; the conductor arrangement may be configured to comprise a functional circuit; the substrate may be formed from a fiber panel; the substrate has a shape. The conductor arrangement may have the shape; the conductor arrangement has a contoured shape conforming to a contoured shape of the substrate; the conductor arrangement may comprise a conductive trace configured to provide the functional circuit; the conductive trace may comprise a layer of electrically conductive traces; the conductive trace may comprise a set of electrically conductive traces; a conductive trace may comprise a set of electrically conductive wires; a conductive trace may comprise a multi-layer set of electrically conductive traces; the conductive trace may comprise a pattern of electrically conductive traces; the conductor arrangement of the composite structure may comprise a conductor pattern in the fiber panel comprising a conductive trace to provide the functional circuit. The functional circuit may comprise a sensor; the sensor may be configured to operate as a switch. The functional circuit may comprise at least one of a light, an LED light, a display, an illuminated feature. The functional circuit may comprise a user interface; the functional circuit may comprise an input device and/or an output device; the functional circuit may comprise an input device and an output device. Th component may comprise a connector for the functional circuit; the functional circuit may be configured to be connected to a control system and/or a vehicle system and/or a network and/or a power source; the functional circuit may be configured to facilitate deployment of an airbag.

The present invention relates to a component for a vehicle interior. The component may comprise a structural substrate; and a conductor arrangement coupled to the structural substrate; the structural substrate may be formed from a panel; the conductor arrangement may be configured to comprise a functional circuit; the panel may comprise a fiber panel; the functional circuit may comprise an electrical circuit. The conductor arrangement may comprise a circuit configured to be powered by a power source. The conductor arrangement may comprise a circuit configured to be connected to at least one vehicle system. The conductor arrangement may comprise a circuit configured to be connected to at least one network. The conductor arrangement may comprise a circuit configured to be connected to at least device. The conductor arrangement may comprise a circuit configured to operate a user interface system. The conductor arrangement may comprise a circuit on a circuit panel. The component may comprise a composite structure comprising the structural substrate and the conductor arrangement; the conductor arrangement may comprise a conductor pattern; the fiber panel may be comprised at least partially of fibers; the electrical conductor arrangement may be provided on the fiber panel; the fiber panel may be comprised at least partially of fibers; the electrical conductor arrangement may be provided in the fiber panel; the fiber panel may be comprised at least partially of fibers; the electrical conductor arrangement may be provided within the fiber panel; the electrical conductor arrangement may be pressed into a surface of the panel during a compression forming process; the structural substrate may comprise a feature molded on the panel; the structural substrate may comprise an ancillary component molded at the conductor arrangement; the structural substrate may comprise at least one of (a) a compression-formed component; (b) a generally rigid fiber mat.

The present invention relates to a process for producing a component for a vehicle interior and the component. The component for a vehicle interior produced in a mold comprising a first surface and a second surface by a process comprising placing a pre-form substrate onto the first surface of the mold; forming a compression-formed structure from the pre-form substrate by compressing the pre-form substrate between the first surface of the mold and the second surface of the mold; applying a cover to the compression-formed structure to form a panel assembly providing a surface effect; the pre-form substrate may comprise an electrical conductor arrangement. The component of claim 125 the pre-form substrate may comprise a fiber panel; the electrical conductor arrangement may be formed into the fiber panel; the pre-form substrate may comprise a fiber panel; the electrical conductor arrangement may be formed onto the fiber panel; the pre-form substrate may comprise a fiber panel; the electrical conductor arrangement may be within the fiber panel; the pre-form substrate may comprise a fiber panel; the electrical conductor arrangement may be stitched into the fiber panel; the pre-form substrate may comprise a fiber panel; the electrical conductor arrangement may be sewn to the fiber panel. The compression-formed structure may comprise a substrate layer and the electrical conductor arrangement. The step of forming the compression-formed structure may comprise forming the substrate layer into a generally rigid form; the step of forming the compression-formed structure may comprise forming the electrical conductor arrangement and the pre-form substrate with a generally continuous surface. The panel assembly may comprise a composite structure with at least partially a shape of the compression-formed structure; the shape may comprise a contour provided by the first surface of the mold and a contour provided by the second surface of the mold; the pre-form substrate may comprise a resin; comprising the step of heating the pre-formed substrate; the pre-formed substrate may be compressed as the pre-formed substrate cools. The process may comprise the step of injecting resin into the mold after the compression-formed structure may be formed to form a feature on the panel assembly. The process may comprise the step of injecting resin into the mold after the compression-formed structure may be formed to form an ancillary component of the panel assembly.

The present invention relates to a component for a vehicle interior. The component may comprise a composite structure comprising (a) a structural substrate formed from a fiber panel; (b) a cover for the structural substrate providing an exterior surface; (c) a conductor arrangement configured to comprise a functional circuit; the structural substrate may comprise the conductor arrangement. The conductor arrangement may comprise a conductor pattern; the conductor pattern may comprise an electrical conductor arrangement; the conductor pattern may be provided on the fiber panel; the conductor pattern may be formed into the structural substrate so that the conductor pattern is not visible at the exterior surface of the cover; the conductor pattern may comprise a set of traces; the set of traces of the conductor pattern is provided at a surface of the fiber panel so that the structural substrate may comprise a generally flat surface for the cover; the set of traces of the conductor pattern is provided at a surface of the fiber panel so that the set of traces is not visible at the exterior surface of the cover of the composite surface; the set of traces of the conductor pattern may be pressed into a surface of the fiber panel so that the structural substrate may comprise a generally flat surface for the cover; the set of traces of the conductor pattern may be pressed into a surface of the fiber panel so that the set of traces is not visible at the exterior surface of the cover of the composite surface; the set of traces for the conductor pattern may comprise an upper set of traces and a lower set of traces; the conductor pattern may comprise a set of traces at least partially formed into the fiber panel of the structural substrate; the conductor pattern may comprise a network of traces in the fiber panel formed into the structural substrate. The component may comprise a feature on the structural substrate; the feature may comprise at least one of (a) a rib; (b) a set of ribs; (c) a reinforcement for the fiber panel; (d) a cover for the electrical conductor; (e) insulation for the electrical conductor; (f) shielding for the electrical conductor; (g) a housing for the electrical connector; (h) a cover for an electrical connector to the electrical conductor; (i) a connection point for the electrical conductor arrangement and a wire; (j) a resin-formed feature; (k) a resin-formed feature molded on the structural substrate. The composite structure may comprise a foam layer beneath the cover; the structural substrate may comprise a compression-formed fiber panel.

The present invention relates to a component for a vehicle interior. The component may comprise a composite structure comprising (a) a structural substrate formed from a fiber panel; (b) a cover for the structural substrate providing an exterior surface; (c) a feature formed from resin on the structural substrate; the structural substrate may comprise an electrical conductor arrangement; the structural substrate may comprise a pattern of traces; the pattern of traces may comprise the electrical conductor arrangement under the exterior surface.

The present invention relates to a process of preparing a component for a vehicle interior and the component. The component for a vehicle interior may be prepared using a mold by a process comprising the steps of (a) providing a pre-form substrate; (b) joining an electrical conductor arrangement to the pre-form substrate; (c) disposing the pre-form substrate with the electrical conductor arrangement into the mold; and (d) compressing the pre-form substrate between the first surface of the mold and a second surface of the mold to form the pre-form substrate into a structural substrate having a shape; the shape may correspond to a shape of the first surface and a shape of the second surface; the shape may correspond to a first contour of the first surface and a second contour of the second surface. The step of joining an electrical conductor arrangement to the pre-form substrate may comprise sewing the electrical conductor arrangement to the pre-form substrate; the step of joining an electrical conductor arrangement to the pre-form substrate may comprise piercing an opening in the pre-form substrate and joining the electrical conductor arrangement to a conductor arrangement at the opening.

The present invention relates to a method of manufacturing a component for a vehicle interior and the component. The method of manufacturing a component for a vehicle interior may comprise the steps of (a) providing a pre-form substrate; (b) joining an electrical connector to the pre-form substrate; (c) disposing the pre-form substrate with the electrical conductor arrangement onto a first surface of the mold; and (d) compressing the pre-form substrate between the first surface and a second surface of the mold to form a structural substrate having a shape; the shape may correspond to a first contour of the first surface and a second contour of the second surface; the shape may correspond to a shape of the first surface and a shape of the second surface; the shape may correspond to a first shape of the first surface and a second shape of the second surface.

The present invention relates to a component for a vehicle interior. The component may comprise a composite structure comprising a fiber panel and a cover; the fiber panel may comprise a conductor arrangement; the conductor arrangement may be configured to provide a functional circuit for the composite structure. The conductor arrangement may comprise conductive wire; the conductor arrangement may comprise conductive thread; the conductive thread may comprise a wire; the conductor arrangement may comprise electrically conductive conductors; the conductor arrangement may comprise a pattern of electrically conductive conductors; the conductor arrangement may comprise a set of electrically conductive threads; conductive thread may be within the fiber panel; conductive thread may be stitched within the fiber panel; conductive thread may be stitched into the fiber panel and/or stitched onto the fiber panel; the conductor arrangement may comprise a stitch pattern comprising conductive thread; the conductor arrangement may comprise a stitch pattern comprising the functional circuit; the functional circuit may comprise a user interface; the functional circuit may comprise an input device and/or an output device; the functional circuit may comprise a connection point; the composite structure may comprise a feature on the fiber panel; the feature may comprise a resin structure and/or a resin feature and/or a molded feature and/or a molded structure; the feature may comprise a rib; the feature may comprise a resin structure adjacent to the functional circuit; the fiber panel may comprise a stitch pattern comprising conductive thread; the fiber panel may comprise a stitch pattern comprising non-conductive thread.

The present invention relates to a component for a vehicle interior. The component may comprise a composite structure comprising a fiber panel and a cover; the fiber panel may comprise a conductor arrangement; the conductor arrangement may comprise conductors configured to provide a functional circuit. The functional circuit may comprise circuit elements; the conductors may comprise conductive traces configured to provide a functional circuit; the conductors may comprise conductive leads configured to provide a functional circuit; the conductor arrangement may comprise conductive wires configured to provide a functional circuit; conductors comprise a pattern of electrically conductive threads; the composite structure may comprise a stitch pattern in the fiber panel comprising conductive thread to provide the functional circuit; the functional circuit may comprise a sensor configured to operate as an operator control and/or a switch; the functional circuit may comprise at least one of a light, an LED light, a display, an illuminated feature; the functional circuit may comprise a user interface; the functional circuit may comprise an input device; the input device may comprise a switch; the functional circuit may comprise an output device; the output device may comprise a display; the functional circuit may comprise an input device and an output device; the component may comprise a connector for the functional circuit; the component may comprise a stitch pattern; the stitch pattern may comprise a top stitch and a bottom stitch; the structural substrate may comprise a panel comprised at least partially of fibers; the conductor arrangement may be sewn to the panel; the conductor arrangement may be pressed into a surface of the panel during a compression forming process.

The present invention relates to a process of making a component for a vehicle interior and the component. The component may may be produced in a mold comprising a first surface and a second surface by a process comprising the steps of placing a pre-form substrate onto the first surface of the mold; forming a compression-formed structure from the pre-form substrate by compressing the pre-form substrate between the first surface of the mold and the second surface of the mold; applying a cover to the compression-formed structure to form a panel assembly providing a surface effect; the pre-form substrate may comprise an electrical conductor arrangement. The pre-form substrate may comprise a fiber panel; the electrical conductor arrangement may be sewn to the fiber panel; the compression-formed structure may comprise a substrate layer and the electrical conductor arrangement; the step of forming the compression-formed structure may comprise forming the substrate layer into a generally rigid form; the step of forming the compression-formed structure may comprise forming the electrical conductor arrangement and the pre-form substrate with a generally continuous surface. A generally smooth texture of the panel assembly may be provided by (a) a surface effect of the cover and (b) a surface effect of the pre-form substrate; (c) a surface effect at least partially concealing the electrical conductor arrangement. The panel assembly may comprise a composite structure with at least partially a shape of the compression-formed structure; the shape may comprise a shape provided by a surface of the mold; the pre-form substrate may comprise a resin; the process may comprise the step of heating the pre-formed substrate and the pre-formed substrate may be compressed as the pre-formed substrate cools. The process may comprise the step of injecting resin into the mold after the compression-formed structure may be formed to form an ancillary component of the panel assembly.

The present invention relates to a component for a vehicle interior. The component may comprise a composite structure comprising: (a) a structural substrate formed from a fiber panel; (b) a cover for the structural substrate providing an exterior surface; the structural substrate may comprise a stitch pattern; the stitch pattern may comprise a set of threads; the stitch pattern may comprise an electrical conductor arrangement. The stitch pattern may be provided on the fiber panel; the stitch pattern may be formed into the structural substrate so that the stitch pattern is not visible at the exterior surface of the cover; the set of threads of the stitch pattern may be pressed into a surface of the fiber panel so that the structural substrate may comprise a generally flat surface for the cover; the set of threads of the stitch pattern may be pressed into a surface of the fiber panel so that the set of threads is not visible at the exterior surface of the cover of the composite surface; the stitch pattern may comprise a network of threads in the fiber panel formed into the structural substrate; the set of threads for the stitch pattern may comprise an upper set of threads and a lower set of threads. A feature formed on the fiber panel may comprise at least one of (a) a rib; (b) a set of ribs; (c) a reinforcement for the fiber panel; (d) a cover for the electrical conductor; (e) insulation for the electrical conductor; (f) shielding for the electrical conductor; (g) a housing for the electrical connector; (h) a cover for an electrical connector to the electrical conductor; (i) a connection point for the electrical conductor arrangement and a wire; (j) a resin-formed feature; (k) a resin-formed feature molded on the structural substrate. The composite structure may comprise a foam layer beneath the cover; the structural substrate may comprise a compression-formed fiber panel.

The present invention relates to a component for a vehicle interior. The component may comprise a composite structure comprising (a) a structural substrate formed from a fiber panel; (b) a cover for the structural substrate providing an exterior surface; (c) a feature formed from resin on the structural substrate; the structural substrate may comprise an electrical conductor arrangement; the electrical conductor arrangement may be configured to comprise a functional circuit for the composite structure. The structural substrate may comprise a pattern of conductors; the pattern of conductors may comprise the electrical conductor arrangement.

The present invention relates to a component for a vehicle interior. The component may comprise a fiber panel; and a structure comprising a resin; the fiber panel may comprise a compression-formed component; the compression-formed component may comprise an edge along a periphery and provides a structural substrate having a shape and a thickness along the edge; the structure may comprise a border of the structural substrate along the thickness of the structural substrate provided by the compression-formed component; the fiber panel may comprise a conductor arrangement; the conductor arrangement may be configured to provide a functional circuit.

The present invention relates to a component for a vehicle interior. The component may comprise a fiber panel comprising a compression-formed component; and a structure formed from a molded resin; the structure may comprise at least one molded feature; the compression-formed component may comprise an edge along a periphery and provides a structural substrate having a shape and a thickness along the edge; the structure may comprise a border of the structural substrate along the thickness of the structural substrate provided by the compression-formed component; and the at least one molded feature may comprise a molded feature configured to support the fiber panel; the fiber panel may comprise a conductor arrangement; the conductor arrangement may be configured to provide a functional circuit.

The present invention relates to a component for a vehicle interior. The component may comprise a structural substrate comprising a compression-formed fiber panel and a structure comprising a resin; the compression-formed fiber panel may comprise a thickness along a periphery; the structure may comprise a border of the structural substrate along the thickness of the periphery of the compression-formed fiber panel; the periphery of the fiber panel may comprise an edge; the structure may be formed on the edge; the fiber panel may comprise a conductor arrangement; the conductor arrangement may be configured to provide a functional circuit.

The present invention relates to a component for a vehicle interior. The component may comprise a structural substrate comprising a fiber panel and a structure comprising a resin; the fiber panel may comprise a thickness along a periphery; the structure may comprise a border of the structural substrate along the thickness of the periphery of the fiber panel; the periphery of the fiber panel may comprise an edge; the structure may be formed on the edge; the fiber panel may comprise a conductor arrangement; the conductor arrangement may be configured to provide a functional circuit.

The present invention relates to a component for a vehicle interior. The component may comprise a fiber panel; a structure comprising a resin; and a cover coupled to at least one of (a) the fiber panel, (b) the structure; the fiber panel may comprise a compression formed component; the compression formed component may comprise an edge along a periphery and provides a structural substrate having a shape and a thickness along the edge; the structure may comprise a border of the structural substrate along the thickness of the structural substrate provided by the compression formed component; the fiber panel may comprise a conductor arrangement; the conductor arrangement may be configured to provide a functional circuit.

The present invention relates to a component for a vehicle interior; the component may comprise a composite structure comprising a substrate comprising a fiber panel; the fiber panel may comprise a conductor arrangement; the conductor arrangement may be configured to provide a functional circuit for the composite structure. The composite structure may comprise a structural substrate; the fiber panel may comprise a compression-formed fiber panel. The composite structure may comprise a functional element comprising the conductor arrangement; the functional element may comprise an insert and/or mat and/or a fabric and/or a woven material and/or a formed material and/or a resin material; the conductor arrangement and/or functional circuit may be configured to comprise at least one of: a conductor; a sensor/detector; an input device; an output device; an interactive device; a display; a switch; a light/lighting; a light element; a light guide. The conductor arrangement and/or functional circuit may be configured to comprise at least one of: a light/lighting; a light element; a light guide; an LED; LED lighting; a display; a display panel; an antenna; a camera; a video-recorder; an image display/device; a user interface; an input device; an output device; an input/output device; a sensor; a detector; a switch; a touch sensor; an odor/scent detector; a microphone; a sound detector; a wireless charging device; a wireless connection area; a heating element; an electrified area; other device/technology. The composite structure may comprise a base; the base may comprise a structural substrate; the fiber panel may comprise a compression-formed fiber panel. The vehicle interior component may comprise a composite structure comprising a substrate such as a fiber panel and a cover and a functional element/layer comprising a conductor arrangement and/or functional circuit. The functional element may comprise an insert/layer and/or the conductor arrangement; the functional element may be configured to comprise a functional circuit; the conductor arrangement may be configured to provide a functional circuit. The composite structure may comprise a functional element comprising the conductor arrangement; the functional element may comprise an insert and/or mat and/or a layer and/or a fabric and/or a woven material and/or a formed material and/or a resin material. The component may comprise a trim panel, an instrument panel, a door panel, an overhead panel, a console, an overhead console, a floor console, an armrest, an interior trim component, pillar trim, an operator control, a steering control, a steering wheel, etc.

The present invention relates to a vehicle interior component comprising a composite structure configured to provide a circuit element.

The present invention relates to a vehicle interior component comprising a composite structure configured to provide an arrangement of conductors for a circuit element.

The present invention relates to a vehicle interior component comprising a composite structure configured to provide an arrangement of conductors for a circuit element to provide a functional circuit.

The present invention relates to a vehicle interior component comprising a composite structure comprising a fiber panel configured to provide an arrangement of conductors for a circuit element to provide a functional circuit.

The present invention relates to component for a vehicle interior comprising a composite structure comprising a structural substrate comprising a compression-formed fiber panel and a conductor arrangement; the compression-formed fiber panel may be formed by compression-forming of a fiber panel with the conductor arrangement; the conductor arrangement may be configured to provide a functional circuit and a connection point; the composite structure may comprise a feature for the connection point; the connection point may comprise a connector such as a projection, flange, tab, block, plug-socket, angled tab, resin structure; the connector may comprise an internal connector, external connector, edge connector; the connector may be provided at/within a perimeter of the structural substrate and on/within the fiber panel; the compression-formed fiber panel may be formed with the conductor arrangement and/or connection point/connector; the composite structure may comprise a feature for the connection point to provide a connector; the connector may comprise a conductive trace, multi-layer pattern, insulated lead/band and/or conductive wire and/or conductive thread. The functional circuit with connector for the composite structure may compromise a user interface, input device, output device, sensor, detector, transducer, display, circuit board, charger, etc. The connector may connect to a power source and/or at least one vehicle system and/or network.

### FIGURES

FIG. 1A is a schematic perspective view of a vehicle according to an exemplary embodiment.

FIGS. 1B and 1C are schematic perspective views of a vehicle interior according to an exemplary embodiment.

FIG. 2 is a schematic perspective view of a vehicle interior comprising a component comprising a functional circuit according to an exemplary embodiment.

FIGS. 2A through 2H are schematic block diagrams of a functional circuit/element for composite structure of a component according to an exemplary embodiment.

FIG. 3 is a schematic perspective view of a vehicle interior component shown as an instrument panel with a composite structure comprising a functional circuit according to an exemplary embodiment.

FIG. 4 is a schematic perspective view of a vehicle interior component shown as an overhead panel with a composite structure comprising a functional circuit according to an exemplary embodiment.

FIG. 5 is a schematic perspective view of a vehicle interior component shown as a floor console with a composite structure comprising a functional circuit according to an exemplary embodiment.

FIG. 6 is a schematic perspective view of a vehicle interior component shown as an armrest with a composite structure comprising a functional circuit according to an exemplary embodiment.

FIG. 7 is a schematic perspective view of a vehicle interior component shown as a center console with a composite structure comprising a functional circuit according to an exemplary embodiment.

FIG. 8 is a schematic perspective view of a vehicle interior component shown as a steering wheel assembly with a composite structure comprising a functional circuit according to an exemplary embodiment.

FIG. 9 is a schematic perspective view of a vehicle interior component shown as a door panel with a composite structure comprising a functional circuit according to an exemplary embodiment.

FIG. 10 is a schematic perspective view of a vehicle component shown as a front storage area with a composite structure comprising a functional circuit according to an exemplary embodiment.

FIG. 11 is a schematic perspective view of a vehicle component shown as a rear storage area with a composite structure comprising a functional circuit according to an exemplary embodiment.

FIG. 12 is a schematic perspective view of a vehicle interior component shown as a visor with a composite structure comprising a functional circuit according to an exemplary embodiment.

FIG. 13 is a schematic perspective view of a vehicle interior component shown as a receptacle in an instrument panel with a composite structure comprising a functional circuit according to an exemplary embodiment.

FIG. 14 is a schematic perspective view of a vehicle interior component shown as a seat assembly with a composite structure comprising a functional circuit according to an exemplary embodiment.

FIG. 15 is a schematic perspective view of a component with a composite structure comprising a functional circuit according to an exemplary embodiment.

FIG. 16 is a schematic perspective view of a component with a composite structure comprising a functional circuit according to an exemplary embodiment.

FIGS. 17A and 17B are a schematic block diagrams of a functional circuit for a component with a composite structure comprising a functional circuit according to an exemplary embodiment.

FIG. 18A is a schematic perspective view of a component with a composite structure comprising a functional circuit according to an exemplary embodiment.

FIG. 18B is a schematic exploded perspective view of a component with a composite structure comprising a functional circuit according to an exemplary embodiment.

FIG. 18C is a schematic section view of a component with a composite structure comprising a functional circuit according to an exemplary embodiment.

FIG. 19A is a schematic perspective view of a component with a composite structure comprising a functional circuit according to an exemplary embodiment.

FIG. 19B is a schematic exploded perspective view of a component with a composite structure comprising a functional circuit according to an exemplary embodiment.

FIG. 20A is a schematic section view of a component with a composite structure comprising a functional circuit according to an exemplary embodiment.

FIG. 20B is a schematic exploded section view of a component with a composite structure comprising a functional circuit according to an exemplary embodiment.

FIG. 20C is a schematic perspective view of a component with a composite structure comprising a functional circuit according to an exemplary embodiment.

FIG. 20D is a schematic exploded perspective view of a component with a composite structure comprising a functional circuit according to an exemplary embodiment.

FIG. 21A is a schematic section view of a component with a composite structure comprising a functional circuit according to an exemplary embodiment.

FIG. 21B is a schematic exploded section view of a component with a composite structure comprising a functional circuit according to an exemplary embodiment.

FIG. 21C is a schematic perspective view of a component with a composite structure comprising a functional circuit according to an exemplary embodiment.

FIG. 21D is a schematic exploded perspective view of a component with a composite structure comprising a functional circuit according to an exemplary embodiment.

FIG. 22A is a schematic perspective view of a component with a composite structure comprising a functional circuit according to an exemplary embodiment.

FIG. 22B is a schematic exploded perspective view of a component with a composite structure comprising a functional circuit according to an exemplary embodiment.

FIG. 22C is a schematic section view of a component with a composite structure comprising a functional circuit according to an exemplary embodiment.

FIG. 23A is a schematic perspective view of a component with a composite structure comprising a functional circuit according to an exemplary embodiment.

FIG. 23B is a schematic exploded perspective view of a component with a composite structure comprising a functional circuit according to an exemplary embodiment.

FIG. 24A is a schematic perspective view of a component with a composite structure comprising a functional circuit according to an exemplary embodiment.

FIG. 24B is a schematic exploded perspective view of a component with a composite structure comprising a functional circuit according to an exemplary embodiment.

FIGS. 25A and 25B are schematic perspective views of a component with a composite structure comprising a functional circuit with connector according to an exemplary embodiment.

FIG. 26A is a schematic perspective view of a component with a composite structure comprising a functional circuit with connector according to an exemplary embodiment.

FIGS. 26B and 26C are schematic section views of a component with a composite structure comprising a functional circuit with connector according to an exemplary embodiment.

FIGS. 27A and 27B are schematic perspective views of a component with a composite structure comprising a functional circuit according to an exemplary embodiment.

FIG. 27C is a schematic exploded perspective view of a component with a composite structure comprising a functional circuit according to an exemplary embodiment.

FIG. 28 is a schematic plan view of a component shown as an overhead panel with a composite structure comprising a functional circuit according to an exemplary embodiment.

FIG. 29 is a schematic plan view of a component shown as an overhead panel with a composite structure comprising a functional circuit according to an exemplary embodiment.

FIGS. 30A and 30B are schematic plan views of a component shown as an overhead panel with a composite structure comprising a functional circuit according to an exemplary embodiment.

FIG. 31A is a schematic perspective view of a component shown as a steering wheel assembly with a composite structure comprising a functional circuit according to an exemplary embodiment.

FIG. 31B is a schematic exploded perspective view of a component shown as a steering wheel assembly with a composite structure comprising a functional circuit according to an exemplary embodiment.

FIG. 31C is a schematic perspective view of a composite structure for a component shown as a steering wheel assembly comprising a functional circuit according to an exemplary embodiment.

FIG. 31D is a schematic exploded perspective view of a component shown as a steering wheel assembly with a composite structure comprising a functional circuit according to an exemplary embodiment.

FIG. 31E is a schematic detail perspective view of functional circuit of a composite structure of a component shown as a steering wheel assembly according to an exemplary embodiment.

FIG. 32A is a schematic perspective view of a composite structure for a component shown as a steering wheel assembly comprising a functional circuit according to an exemplary embodiment.

FIG. 32B is a schematic exploded perspective view of a component shown as a steering wheel assembly with a composite structure comprising a functional circuit according to an exemplary embodiment.

FIG. 33A is a schematic perspective view of a composite structure for a component shown as a steering wheel assembly comprising a functional circuit according to an exemplary embodiment.

FIG. 33B is a schematic exploded perspective view of a component shown as a steering wheel assembly with a composite structure comprising a functional circuit according to an exemplary embodiment.

FIGS. 34A through 34C are schematic perspective views of a steering wheel with a composite structure comprising a functional circuit according to an exemplary embodiment.

FIG. 35A is a schematic perspective view of a component shown as an instrument panel with a composite structure comprising a functional circuit according to an exemplary embodiment.

FIG. 35B is a schematic exploded perspective view of a component shown as an instrument panel with a composite structure comprising a functional circuit according to an exemplary embodiment.

FIG. 35C is a schematic perspective view of a component shown as an instrument panel with a composite structure comprising a functional circuit according to an exemplary embodiment.

FIG. 36A is a schematic perspective view of a component shown as a door panel with a composite structure comprising a functional circuit according to an exemplary embodiment.

FIG. 36B is a schematic exploded perspective view of a component shown as a door panel with a composite structure comprising a functional circuit according to an exemplary embodiment.

FIGS. 36C and 36D are schematic perspective views of a composite structure for a component shown as a door panel comprising a functional circuit according to an exemplary embodiment.

FIG. 37A is a schematic perspective view of a component shown as a floor console with a composite structure comprising a functional circuit according to an exemplary embodiment.

FIG. 37B is a schematic exploded perspective view of a component shown as a floor console with a composite structure comprising a functional circuit according to an exemplary embodiment.

FIG. 37C is a schematic perspective view of a composite structure for a component shown as a floor console panel comprising a functional circuit according to an exemplary embodiment.

FIG. 38A is a schematic perspective view of a component shown as a compartment with a composite structure comprising a functional circuit according to an exemplary embodiment.

FIGS. 38B and 38C are schematic perspective views of a composite structure for a component shown as a compartment comprising a functional circuit according to an exemplary embodiment.

FIG. 39A is a schematic perspective view of a component shown as a compartment with a composite structure comprising a functional circuit according to an exemplary embodiment.

FIGS. 39B and 39C are schematic perspective views of a composite structure for a component shown as a compartment comprising a functional circuit according to an exemplary embodiment.

FIG. 40A is a schematic exploded perspective view of a component shown as a seat assembly with a composite structure comprising a functional circuit according to an exemplary embodiment.

FIG. 40B is a schematic perspective view of a cover of a component shown as a seat assembly with a composite structure comprising a functional circuit according to an exemplary embodiment.

FIG. 41A is a schematic perspective view of a component shown as a visor with a composite structure comprising a functional circuit according to an exemplary embodiment.

FIG. 41B is a schematic front view of a component shown as a visor with a composite structure comprising a functional circuit according to an exemplary embodiment.

FIG. 42A is a schematic exploded perspective view of a component shown as a receptacle for an instrument panel with a composite structure comprising a functional circuit according to an exemplary embodiment.

FIG. 42B is a schematic perspective view of a composite structure for a component shown as a receptacle for an instrument panel comprising a functional circuit according to an exemplary embodiment.

FIG. 42C is a schematic perspective detail view of a composite structure for a component shown as a receptacle for an instrument panel comprising a functional circuit according to an exemplary embodiment.

FIG. 42D is a schematic partial perspective view of a component shown as a receptacle for an instrument panel with a composite structure comprising a functional circuit according to an exemplary embodiment.

FIG. 42E is a schematic partial perspective view of a component shown as a receptacle for an instrument panel with a composite structure comprising a functional circuit according to an exemplary embodiment.

FIGS. 43A through 43D are schematic perspective views of a component with a composite structure comprising a functional circuit according to an exemplary embodiment.

FIGS. 44A through 44F are schematic section views of a component with a composite structure comprising a functional circuit according to an exemplary embodiment.

FIGS. 45A and 45B are schematic perspective views of a component with a composite structure comprising a functional circuit according to an exemplary embodiment.

FIGS. 46A and 46C are schematic perspective views of a component with a composite structure comprising a functional circuit according to an exemplary embodiment.

FIG. 46B is a schematic perspective detail view of a component with a composite structure comprising a functional circuit according to an exemplary embodiment.

FIGS. 47A through 47D are schematic perspective views of a component with a composite structure comprising a functional circuit according to an exemplary embodiment.

FIG. 48A is a schematic perspective view of a component with a composite structure comprising a functional circuit according to an exemplary embodiment.

FIG. 48B is a schematic perspective detail view of a component with a composite structure comprising a functional circuit according to an exemplary embodiment.

FIGS. 49A and 49B are schematic perspective views of a tool to produce a component with a composite structure comprising a functional circuit according to an exemplary embodiment.

FIGS. 49C and 49E are schematic perspective views of a component shown as an instrument panel with a composite structure comprising a functional circuit according to an exemplary embodiment.

FIG. 49D is a schematic exploded perspective view of a component shown as an instrument panel with a composite structure comprising a functional circuit according to an exemplary embodiment.

FIGS. 50A and 50B are schematic perspective views of a tool to produce a component with a composite structure comprising a functional circuit according to an exemplary embodiment.

FIGS. 50C and 50E are schematic perspective views of a component shown as an instrument panel with a composite structure comprising a functional circuit according to an exemplary embodiment.

FIG. 50D is a schematic exploded perspective view of a component shown as an instrument panel with a composite structure comprising a functional circuit according to an exemplary embodiment.

FIGS. 51A through 51D are schematic perspective views of a composite structure for a component comprising a functional circuit according to an exemplary embodiment.

FIG. 51E is a schematic perspective detail view of a composite structure for a component comprising a functional circuit according to an exemplary embodiment.

FIG. 51F is a schematic perspective view of a composite structure for a component comprising a functional circuit according to an exemplary embodiment.

FIGS. 52A and 52B are schematic perspective views of a tool to produce a component with a composite structure comprising a functional circuit according to an exemplary embodiment.

FIG. 53A is a schematic perspective view of a composite structure for a component comprising a functional circuit according to an exemplary embodiment.

FIG. 53B is a schematic exploded perspective view of a component with a composite structure comprising a functional circuit according to an exemplary embodiment.

FIG. 53C is a schematic perspective detail view of a component with a composite structure comprising a functional circuit according to an exemplary embodiment.

FIGS. 54A and 54B are schematic plan views of a component shown as an overhead panel with a composite structure comprising a functional circuit according to an exemplary embodiment.

FIG. 55A is a schematic perspective view of a composite structure for a component comprising a functional circuit according to an exemplary embodiment.

FIG. 55B is a schematic exploded perspective view of a component with a composite structure comprising a functional circuit according to an exemplary embodiment.

FIG. 55C is a schematic perspective detail view of a component with a composite structure comprising a functional circuit according to an exemplary embodiment.

FIG. 56A is a schematic perspective view of a composite structure for a component comprising a functional circuit according to an exemplary embodiment.

FIG. 56B is a schematic perspective view of a component shown as an instrument panel with a composite structure comprising a functional circuit according to an exemplary embodiment.

FIG. 57A is a schematic perspective view of a component shown as a door panel with a composite structure comprising a functional circuit according to an exemplary embodiment.

FIGS. 57B and 57C are schematic perspective views of a composite structure for a component shown as a door panel comprising a functional circuit according to an exemplary embodiment.

FIGS. 58A and 58B are schematic perspective views of a component shown as an instrument panel with a composite structure comprising a functional circuit according to an exemplary embodiment.

FIGS. 59A through 59C are schematic perspective view of a component with a composite structure comprising a functional circuit according to an exemplary embodiment.

FIG. 59D is a schematic perspective detail view of a component with a composite structure comprising a functional circuit according to an exemplary embodiment.

FIGS. 60A through 60E are schematic perspective views of a component shown as an instrument panel with a composite structure comprising a functional circuit according to an exemplary embodiment.

FIG. 61 is a schematic perspective view of a vehicle interior comprising a component comprising a functional circuit according to an exemplary embodiment.

FIG. 62 is a schematic perspective view of a vehicle interior comprising a component comprising a functional circuit according to an exemplary embodiment.

FIG. 63 is a schematic perspective view of a vehicle interior comprising a component comprising a functional circuit according to an exemplary embodiment.

FIGS. 64A and 64B are schematic perspective views of a component shown as an instrument panel with a composite structure comprising a functional circuit according to an exemplary embodiment.

FIGS. 65A and 65B are schematic perspective view of a component with a composite structure comprising a functional circuit according to an exemplary embodiment.

FIGS. 66A and 66B are schematic perspective view of a component with a composite structure comprising a functional circuit according to an exemplary embodiment.

FIG. 67A is a schematic perspective view of a component with a composite structure comprising a functional circuit according to an exemplary embodiment.

FIG. 67B is a schematic detail view of a component with a composite structure comprising a functional circuit according to an exemplary embodiment.

FIG. 68 is a schematic perspective view of a component with a composite structure comprising a functional circuit according to an exemplary embodiment.

FIGS. 69A and 69B are schematic perspective views of a component with a composite structure comprising a functional circuit according to an exemplary embodiment.

FIG. 70 is a schematic perspective view of a component with a composite structure comprising a functional circuit according to an exemplary embodiment.

FIGS. 71A and 71B are schematic perspective views of a component with a composite structure comprising a functional circuit according to an exemplary embodiment.

FIG. 72A is a schematic section view of a component with a composite structure comprising a functional circuit according to an exemplary embodiment.

FIG. 72B is a schematic exploded section view of a component with a composite structure comprising a functional circuit according to an exemplary embodiment.

FIG. 72C is a schematic perspective view of a component with a composite structure comprising a functional circuit according to an exemplary embodiment.

FIG. 72D is a schematic exploded perspective view of a component with a composite structure comprising a functional circuit according to an exemplary embodiment.

FIG. 73A is a schematic section view of a component with a composite structure comprising a functional circuit according to an exemplary embodiment.

FIG. 73B is a schematic exploded section view of a component with a composite structure comprising a functional circuit according to an exemplary embodiment.

FIG. 73C is a schematic perspective view of a component with a composite structure comprising a functional circuit according to an exemplary embodiment.

FIG. 73D is a schematic exploded perspective view of a component with a composite structure comprising a functional circuit according to an exemplary embodiment.

FIGS. 74A and 74B are schematic perspective views of a component with a composite structure comprising a functional circuit according to an exemplary embodiment.

FIG. 74C is a schematic exploded perspective view of a component with a composite structure comprising a functional circuit according to an exemplary embodiment.

FIG. 75A is a schematic perspective view of a component shown as a steering wheel assembly with a composite structure comprising a functional circuit according to an exemplary embodiment.

FIG. 75B is a schematic exploded perspective view of a component shown as a steering wheel assembly with a composite structure comprising a functional circuit according to an exemplary embodiment.

FIG. 75C is a schematic perspective view of a composite structure for a component shown as a steering wheel assembly comprising a functional circuit according to an exemplary embodiment.

FIG. 75D is a schematic exploded perspective view of a component shown as a steering wheel assembly with a composite structure comprising a functional circuit according to an exemplary embodiment.

FIG. 76A is a schematic perspective view of a composite structure for a component shown as a steering wheel assembly comprising a functional circuit according to an exemplary embodiment.

FIG. 76B is a schematic exploded perspective view of a component shown as a steering wheel assembly with a composite structure comprising a functional circuit according to an exemplary embodiment.

FIG. 77A is a schematic perspective view of a composite structure for a component shown as a steering wheel assembly comprising a functional circuit according to an exemplary embodiment.

FIG. 77B is a schematic exploded perspective view of a component shown as a steering wheel assembly with a composite structure comprising a functional circuit according to an exemplary embodiment.

FIGS. 78A through 78C are schematic perspective views of a steering wheel with a composite structure comprising a functional circuit according to an exemplary embodiment.

FIGS. 79A and 79B are schematic perspective views of a component with a composite structure comprising a functional circuit according to an exemplary embodiment.

FIGS. 79C and 79D are schematic perspective views of production of a component with a composite structure comprising a functional circuit according to an exemplary embodiment.

FIGS. 80A and 80B are schematic perspective views of a component with a composite structure comprising a functional circuit according to an exemplary embodiment.

FIGS. 81A and 81B are schematic perspective views of a component with a composite structure comprising a functional circuit according to an exemplary embodiment.

FIGS. 81C and 81D are schematic perspective views of production of a component with a composite structure comprising a functional circuit according to an exemplary embodiment.

FIG. 81E is a schematic perspective detail view of a component with a composite structure comprising a functional circuit according to an exemplary embodiment.

FIGS. 82A and 82B are schematic perspective views of a tool to produce a component with a composite structure comprising a functional circuit according to an exemplary embodiment.

FIGS. 83A and 83C are schematic perspective views of a component shown as an instrument panel with a composite structure comprising a functional circuit according to an exemplary embodiment.

FIG. 83B is a schematic exploded perspective view of a component shown as an instrument panel with a composite structure comprising a functional circuit according to an exemplary embodiment.

FIGS. 84A through 84C are schematic elevation views of a composite structure for a component comprising a functional circuit according to an exemplary embodiment.

FIG. 84D is a schematic perspective views a component with a composite structure comprising a functional circuit according to an exemplary embodiment.

FIGS. 84E and 84F are schematic perspective views of production of a component with a composite structure comprising a functional circuit according to an exemplary embodiment.

FIGS. 85A and 85B are schematic perspective views of a component with a composite structure comprising a functional circuit according to an exemplary embodiment.

FIGS. 85C and 85D are schematic perspective views of production of a component with a composite structure comprising a functional circuit according to an exemplary embodiment.

FIGS. 86A and 86B are schematic perspective views of a tool to produce a component with a composite structure comprising a functional circuit according to an exemplary embodiment.

FIG. 86C is a schematic perspective view of a composite structure for a component comprising a functional circuit according to an exemplary embodiment.

FIG. 86D is a schematic exploded perspective view of a component with a composite structure comprising a functional circuit according to an exemplary embodiment.

FIG. 87A is a schematic perspective view of a composite structure for a component comprising a functional circuit according to an exemplary embodiment.

FIG. 87B is a schematic exploded perspective view of a component with a composite structure comprising a functional circuit according to an exemplary embodiment.

FIG. 88A is a schematic perspective view of a composite structure for a component comprising a functional circuit according to an exemplary embodiment.

FIG. 88B is a schematic perspective view of a component shown as an instrument panel with a composite structure comprising a functional circuit according to an exemplary embodiment.

FIG. 89A is a schematic perspective view of a component shown as a door panel with a composite structure comprising a functional circuit according to an exemplary embodiment.

FIGS. 89B and 89C are schematic perspective views of a composite structure for a component shown as a door panel comprising a functional circuit according to an exemplary embodiment.

FIGS. 90A and 90B are schematic perspective views of a component shown as an instrument panel with a composite structure comprising a functional circuit according to an exemplary embodiment.

FIGS. 91A and 91B are schematic perspective view of a component with a composite structure comprising a functional circuit according to an exemplary embodiment.

FIGS. 92A and 92B are schematic perspective view of a component with a composite structure comprising a functional circuit according to an exemplary embodiment.

FIGS. 93A and 93B are schematic perspective view of a component with a composite structure comprising a functional circuit according to an exemplary embodiment.

FIG. 94 is a schematic perspective view of a component with a composite structure comprising a functional circuit according to an exemplary embodiment.

FIG. 95 is a schematic perspective view of a component with a composite structure comprising a functional circuit according to an exemplary embodiment.

FIGS. 96A and 96B are schematic perspective views of a component with a composite structure comprising a functional circuit according to an exemplary embodiment.

FIG. 97 is a schematic perspective view of a component with a composite structure comprising a functional circuit according to an exemplary embodiment.

FIGS. 98A and 98B are schematic perspective views of a component with a composite structure comprising a functional circuit according to an exemplary embodiment.

### DESCRIPTION

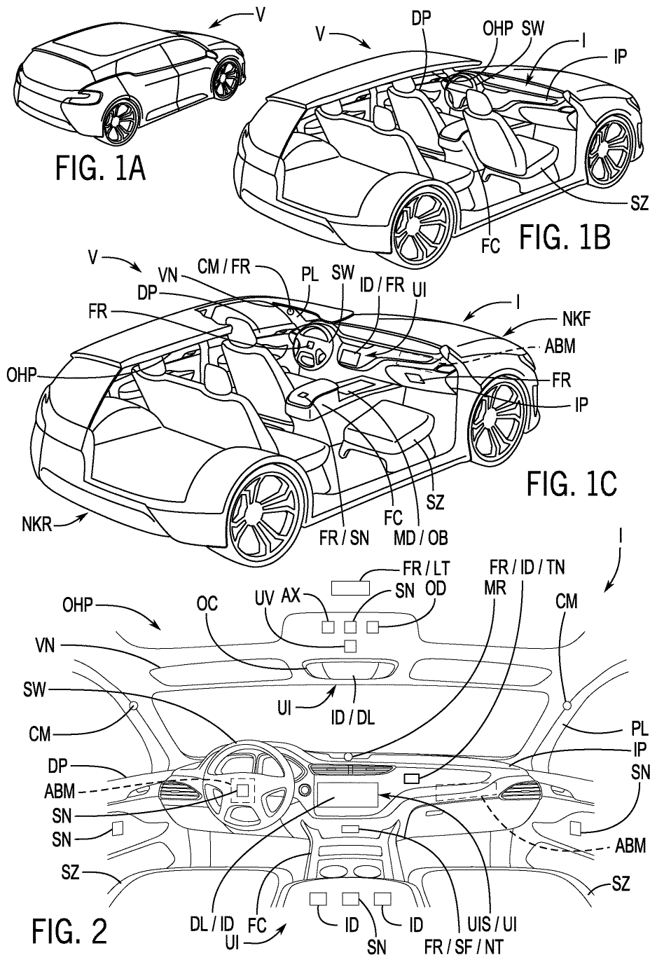

Referring to FIGS. 1A, 1B and 1C, a vehicle Vis shown schematically with an interior I comprising components such as trim components, panels, consoles, etc. As indicated schematically according to an exemplary embodiment in the FIGURES, the component may comprise at least one of a trim panel, an instrument panel, a door panel, an overhead panel, a console, an overhead console, a floor console, an interior trim component, pillar trim, an operator control, a steering control, a steering wheel, a trunk, a frunk, a hatch, a car rear compartment, a car front compartment, a visor, a vanity, a glove box, a receptacle in an instrument panel, etc.

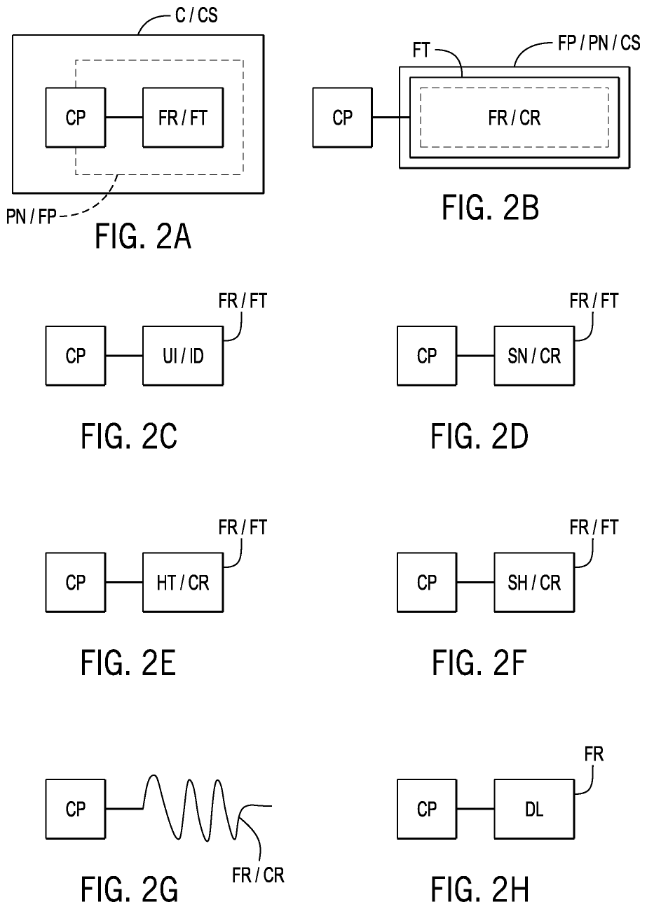

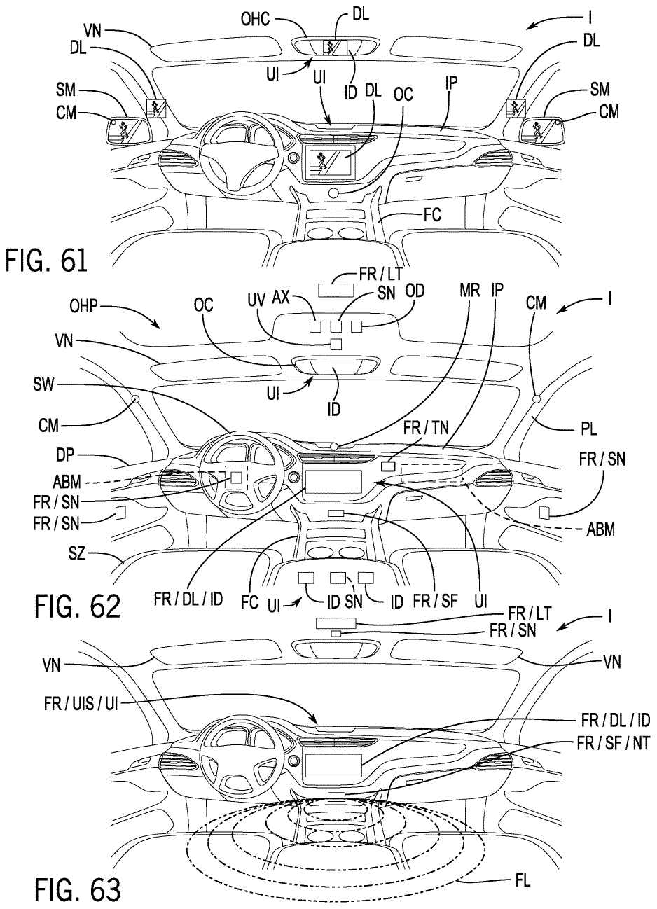

As shown schematically according to an exemplary embodiment in FIGS. 2, 2A-2H, 3, 4, 5, 6, 7, 8, 9, 10, 11, 12, 13, 14, 61, 62 and 63, components C for a vehicle interior may comprise a composite structure configured to provide systems/devices configured to provide functional systems/circuits FR/FT configured to be integrated with components C; as indicated schematically according to an exemplary embodiment, devices/systems provided by functional circuits FR/FT and/or circuit elements CR may be configured and/or combined with components C to provide features/functionality such as a user interface UI (e.g. input device and/or output device), user interface system UIS, illumination such as light LT (provided through a display panel, lamp, etc.) and light guide LG, LED arrangement LED, image display/device ID, sensor/detector arrangements such as a system to generate a sensor field/antenna SF in a field/detection space/area FL or a sensor/detector SN or sensor configured to operate as an input device/switch SH or sensor configured to operate as an occupancy detector OC or ultraviolet sensor UV, odor/scent detector OD, microphone/sound detector MR, camera/video-recorder CM, accelerometer AX, antenna NT, wireless charging/connection area/surface CW (e.g. for mobile devices, etc.), heating element HT, etc.

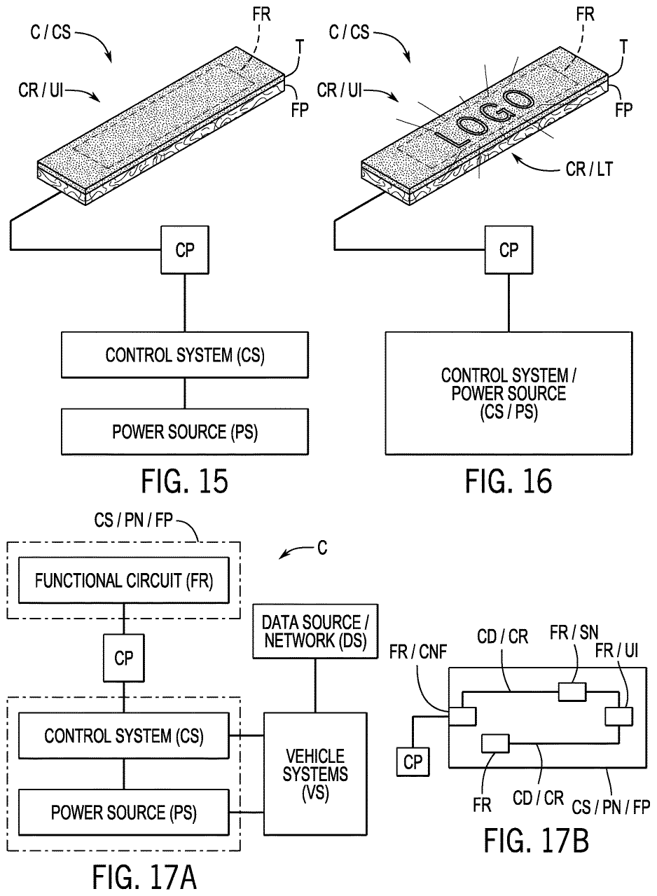

As indicated schematically according to an exemplary embodiment in FIGS. 15, 16 and 17A-17B, the devices/systems provided by functional circuits FR and/or circuit elements CR configured and/or combined with components C to provide features/functionality may be operated by a control system CS and power source PS and connected to vehicle systems VS and/or data sources/networks DS (including the internet, local networks, proprietary networks, etc.); connection may be provided at a connection point such as a plug/connector CP; features/functionality may comprise any of a variety of arrangements within the vehicle interior, including user interface arrangements UI, input/output systems, display panels DL, occupant controls such as switches/buttons SH, entertainment, lighting such as light LT, HVAC/temperature comfort (heating, cooling, etc.), data communications such as at image display ID, monitoring such as by sensors SN, safety systems/detection such as for airbag modules ABM or other vehicle/safety systems, alert/warning systems, occupant interaction/monitoring, interaction/connection with mobile devices MD or other objects OB, etc. See also FIGS. 2, 2A-2H, 3, 4, 5, 6, 7, 8, 9, 10, 11, 12, 13, 14, 61, 62 and 63.

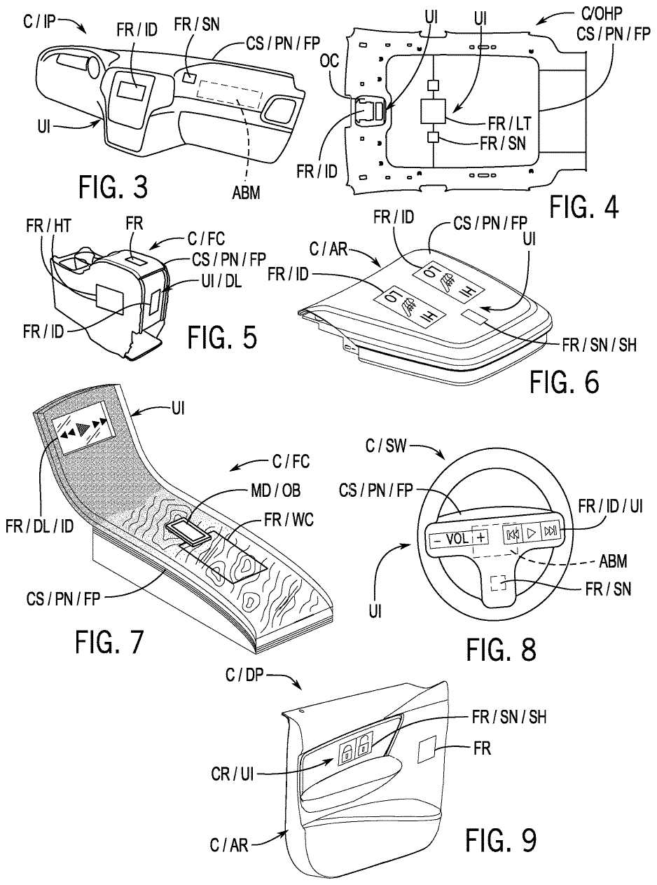

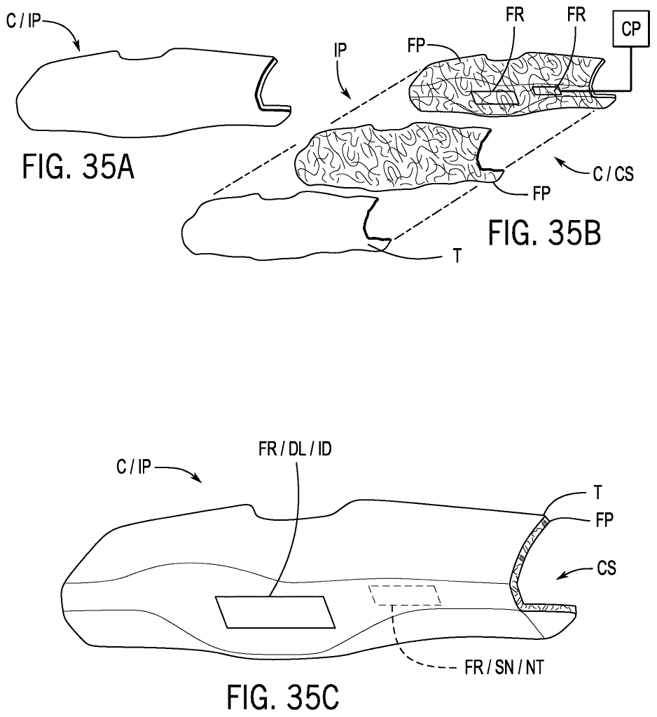

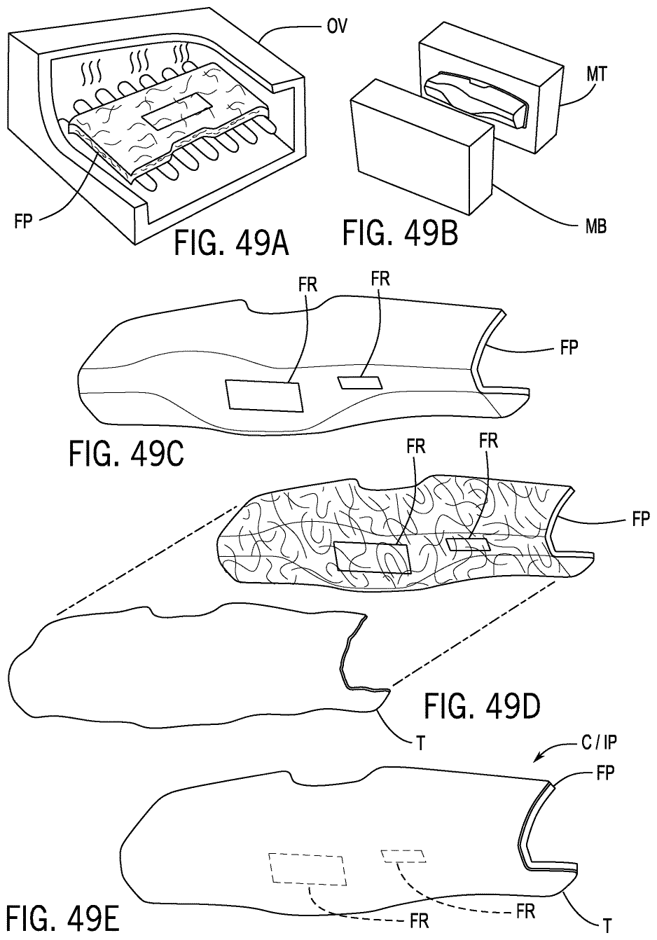

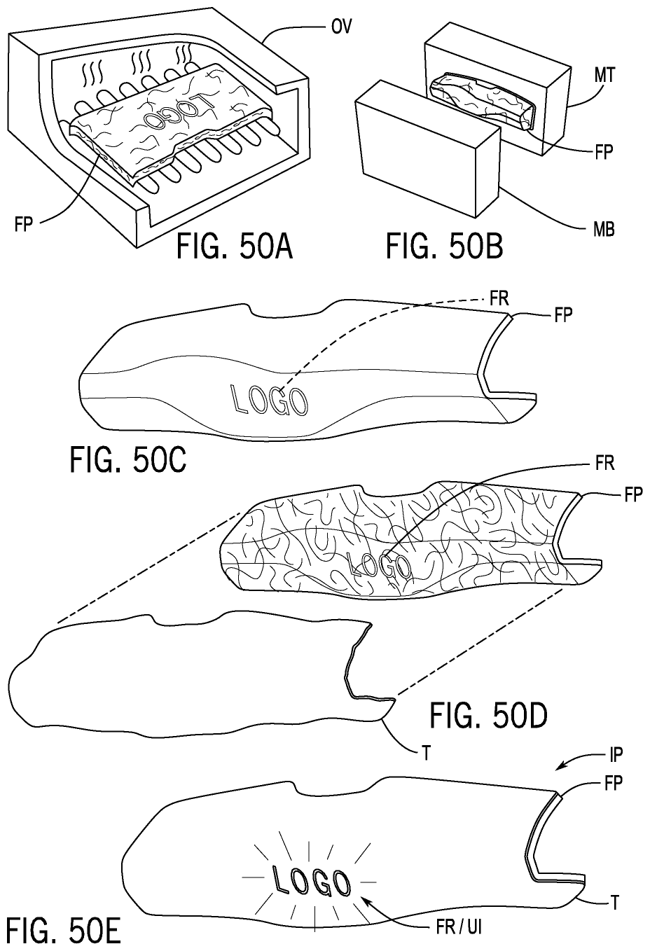

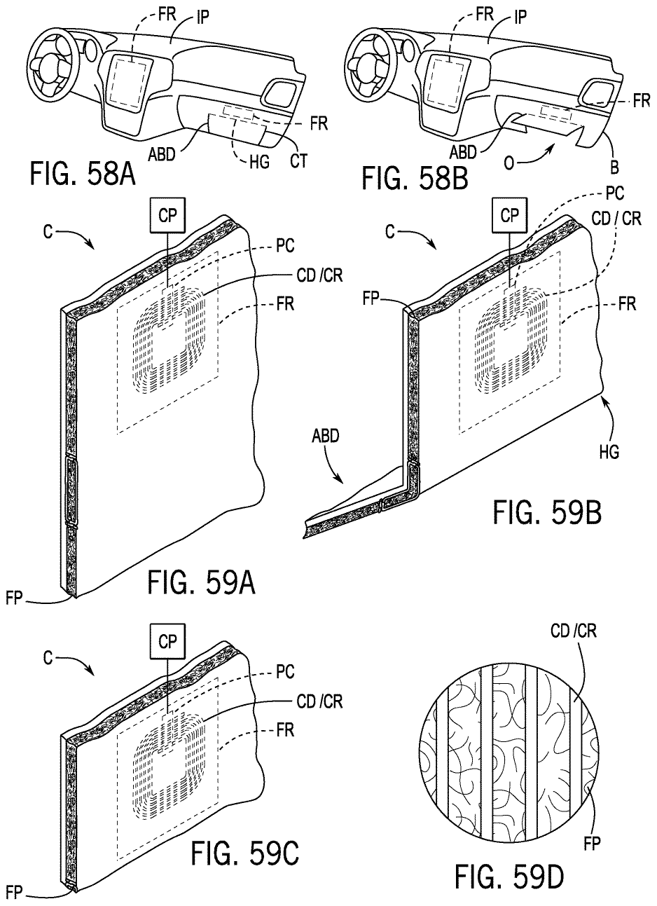

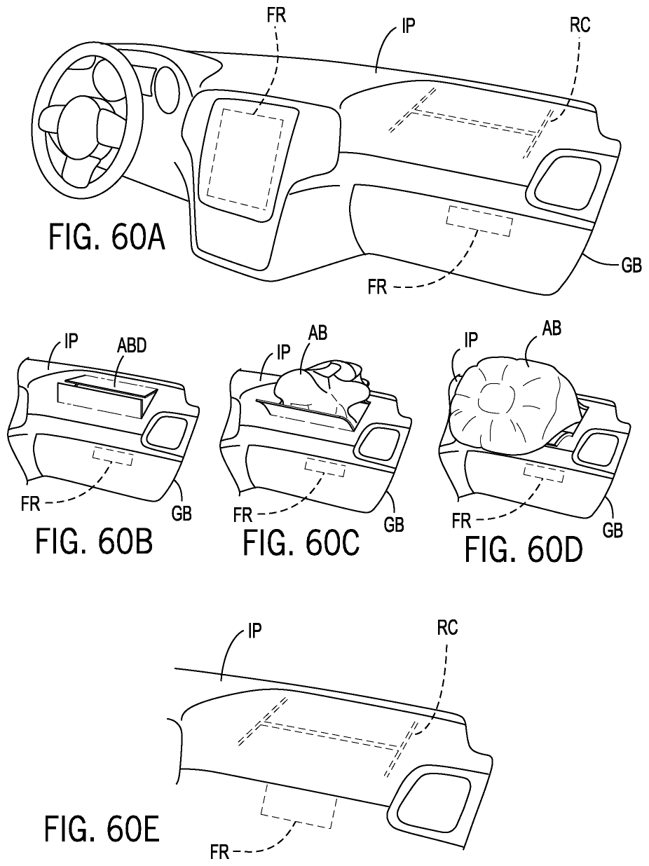

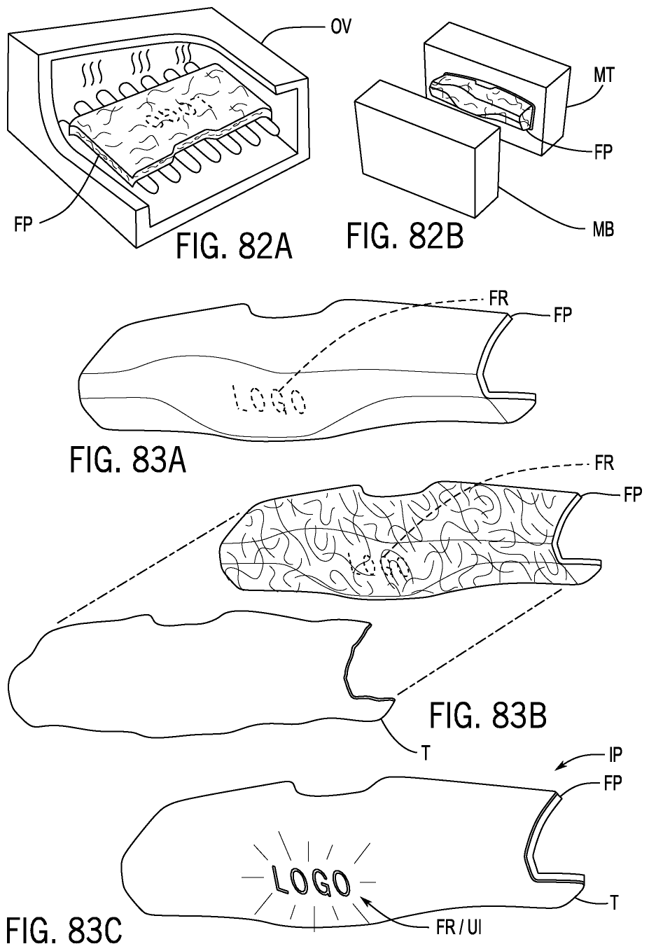

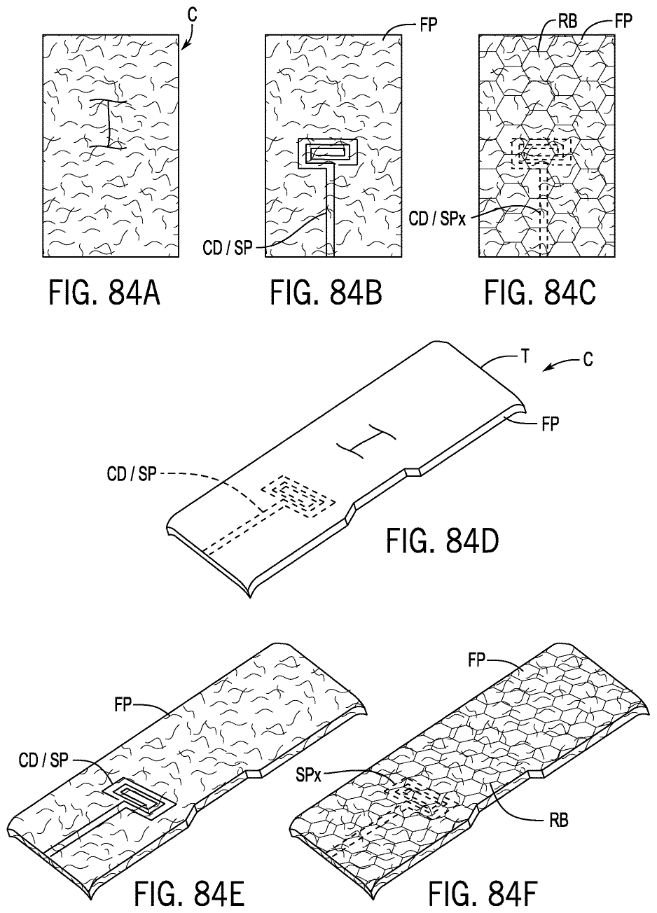

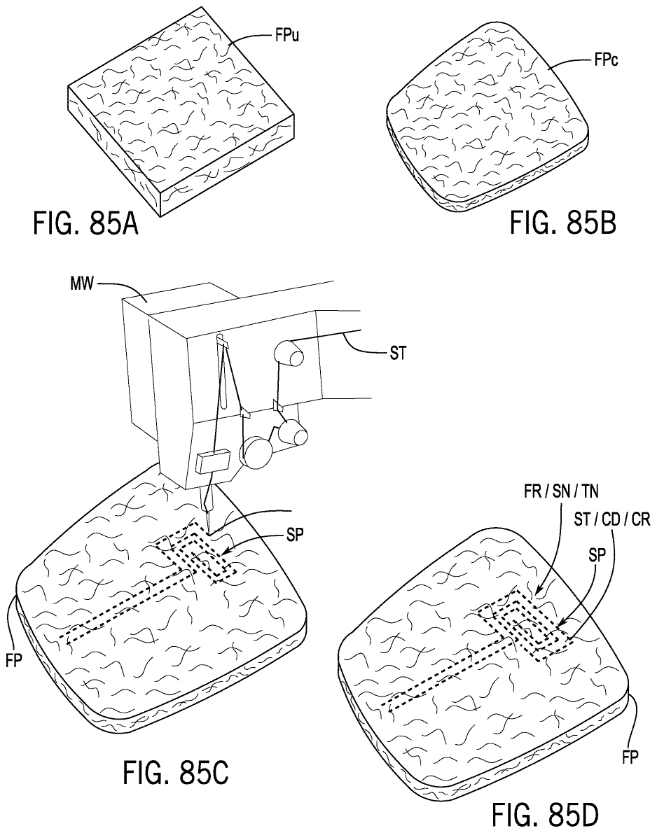

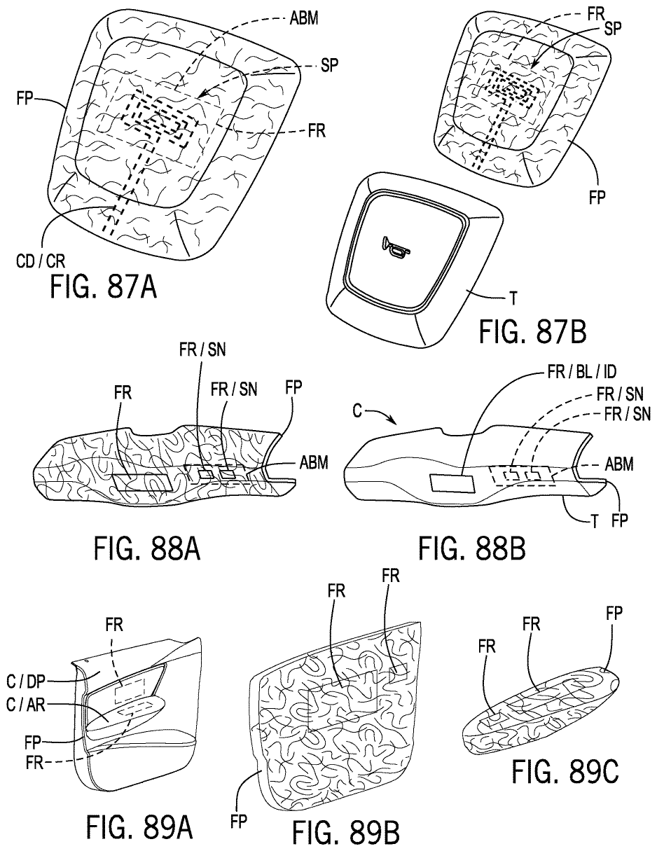

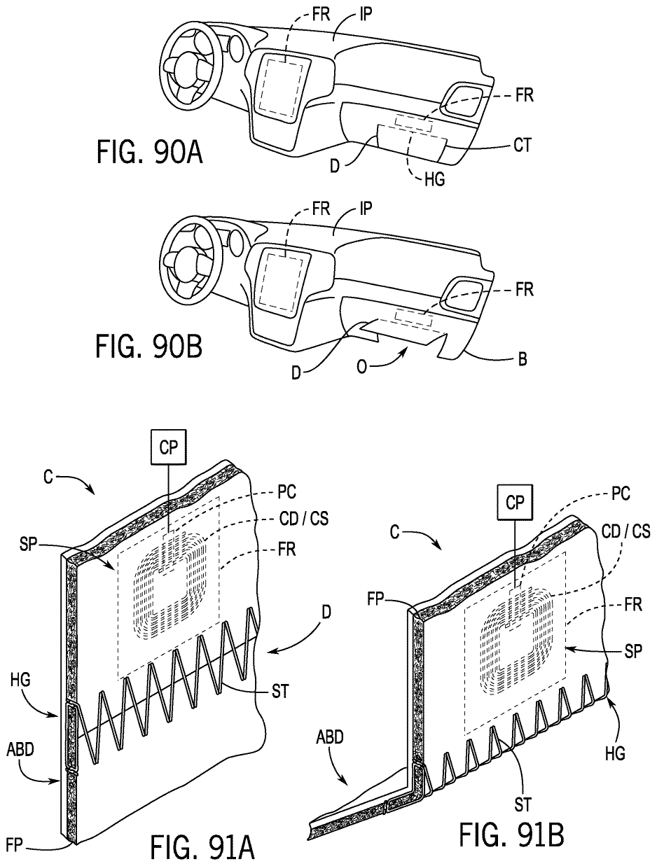

As shown schematically according to an exemplary embodiment in FIGS. 3 and 35A-35C, the component may comprise an instrument panel IP with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B, 26A-26C, 49A-49E, 50A-50E, 56A-56B, 58A-58B, 60A-60E, 64A-64B, 82A-82B, 83A-83B, 88A-88B and 90A-90B.

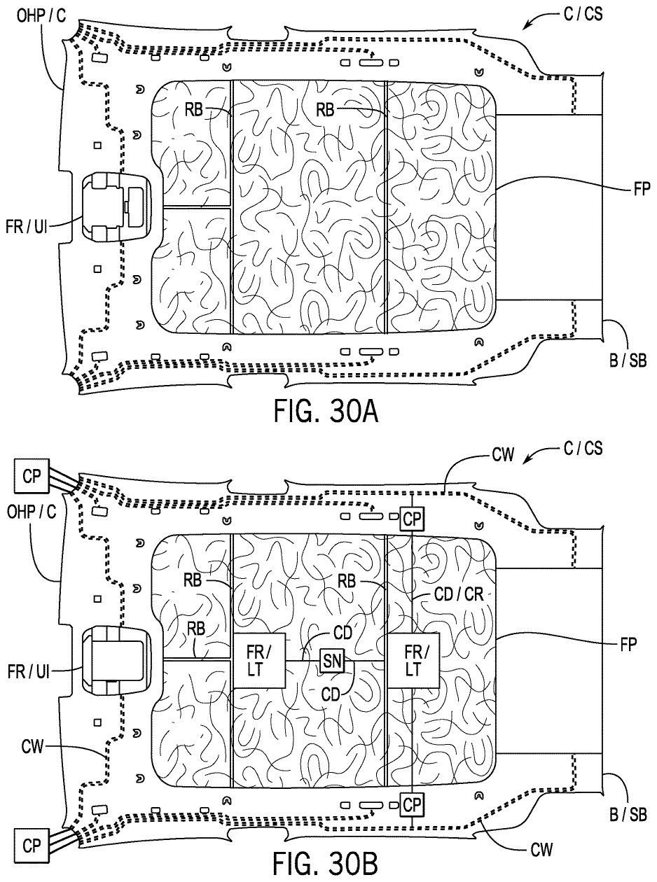

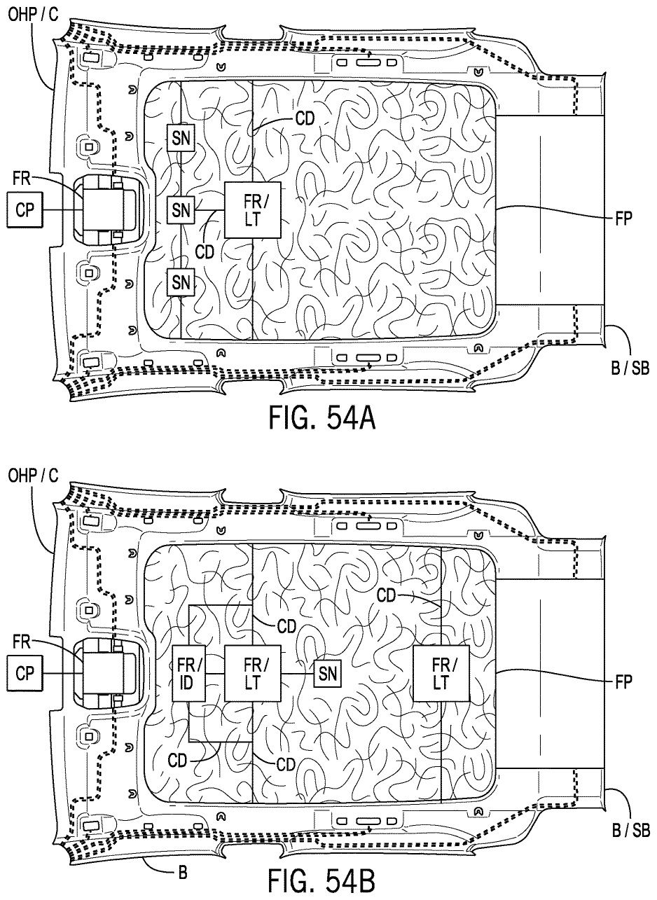

As shown schematically according to an exemplary embodiment in FIGS. 4, 28, 29, 30A-30B and 54A-54B, the component may comprise an overhead panel OHP with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B and 26A-26C.

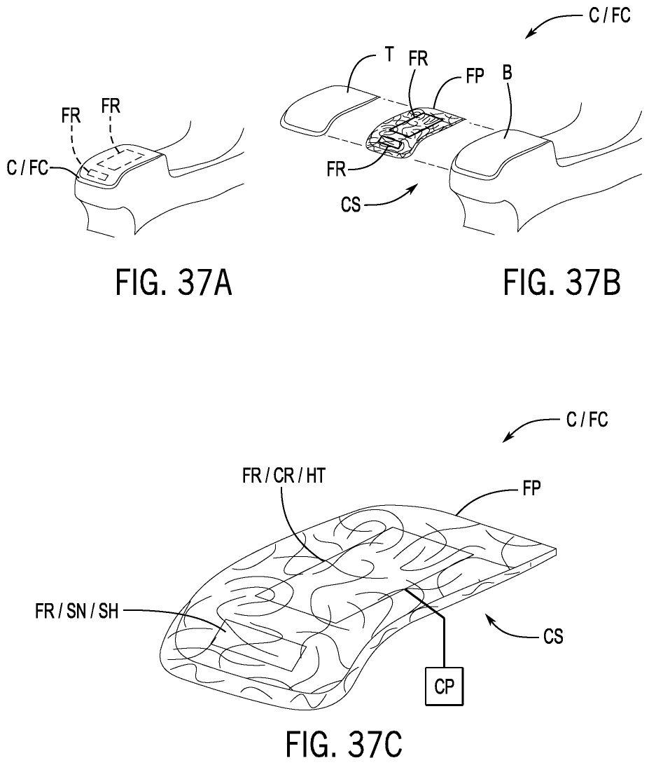

As shown schematically according to an exemplary embodiment in FIGS. 5 and 37A-37C, the component may comprise a floor console FC with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B and 26A-26C.

As shown schematically according to an exemplary embodiment in FIGS. 6, 36A-36D and 37A-37C, the component may comprise an armrest AR with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B, 26A-26C, 57A-57C and 89A-89C.

As shown schematically according to an exemplary embodiment in FIGS. 7 and 37A-37C, the component may comprise a center console FC with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B and 26A-26C.

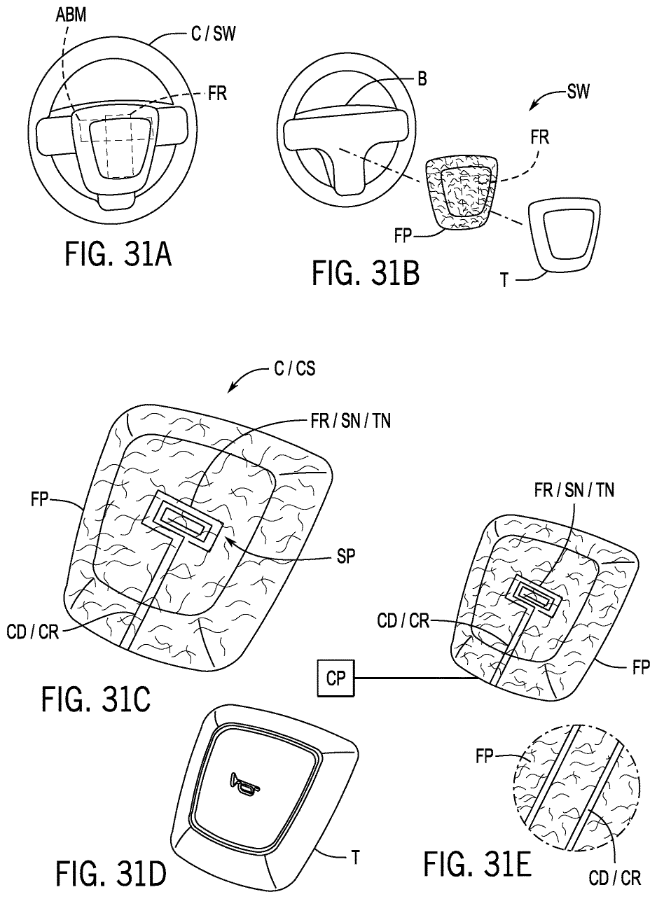

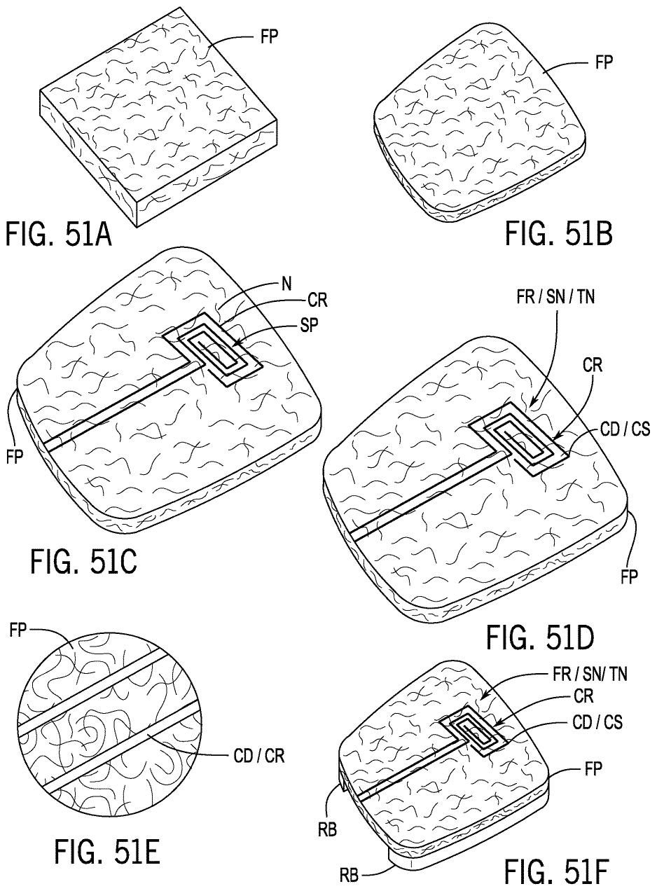

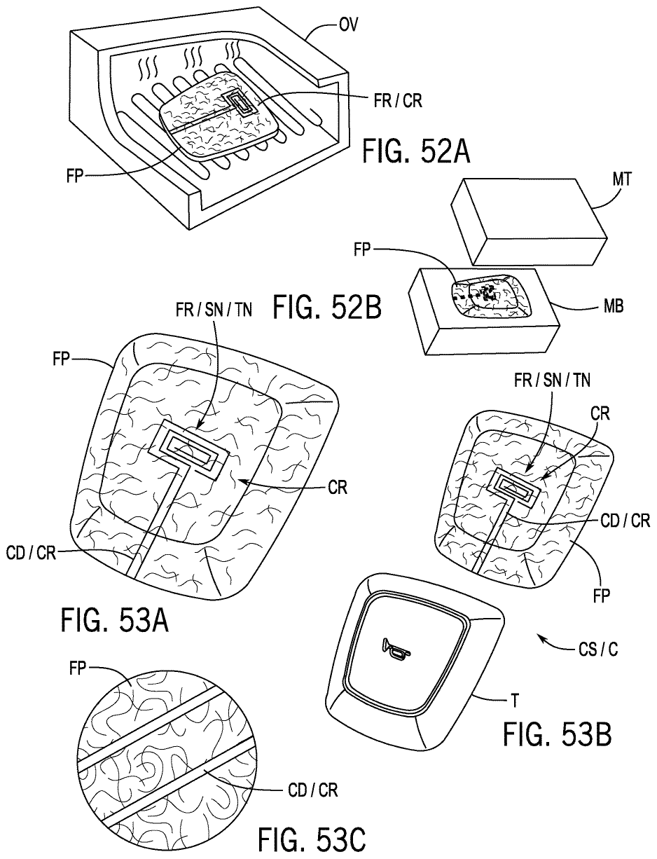

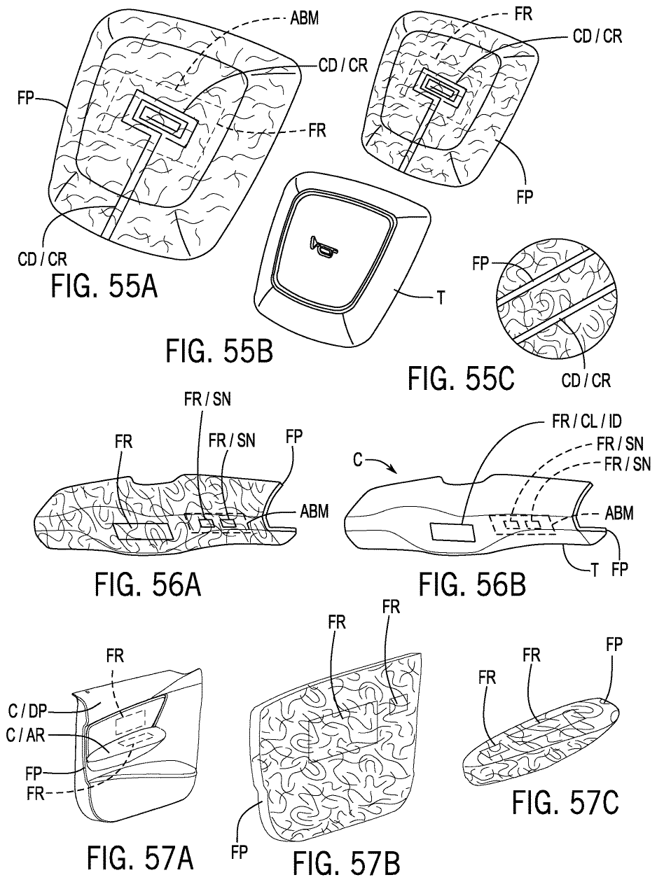

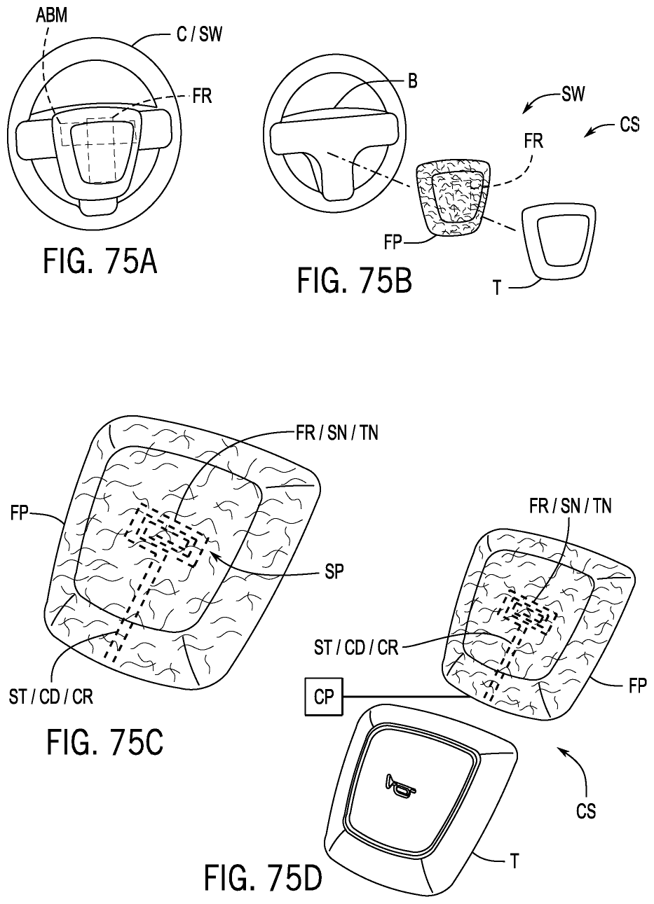

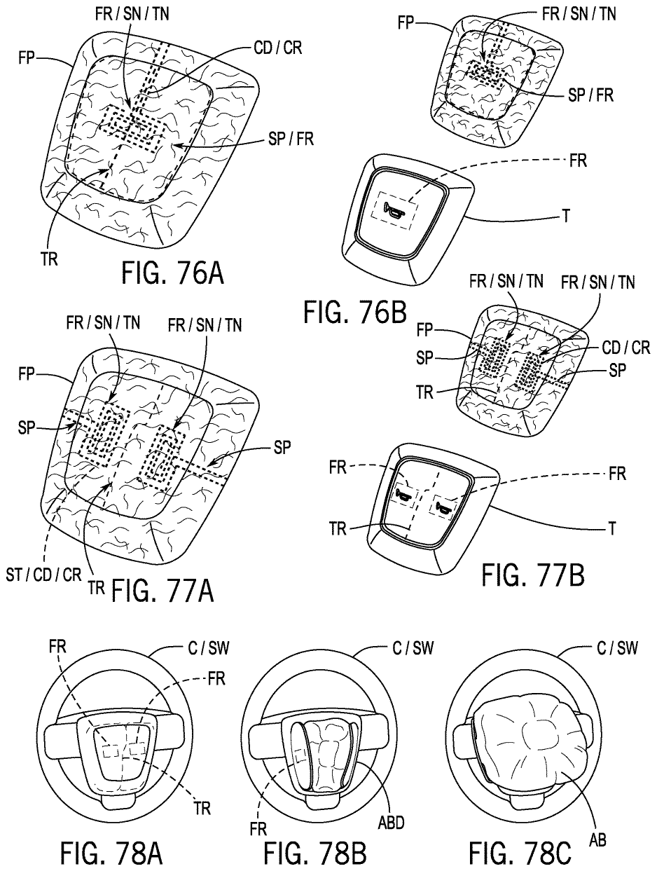

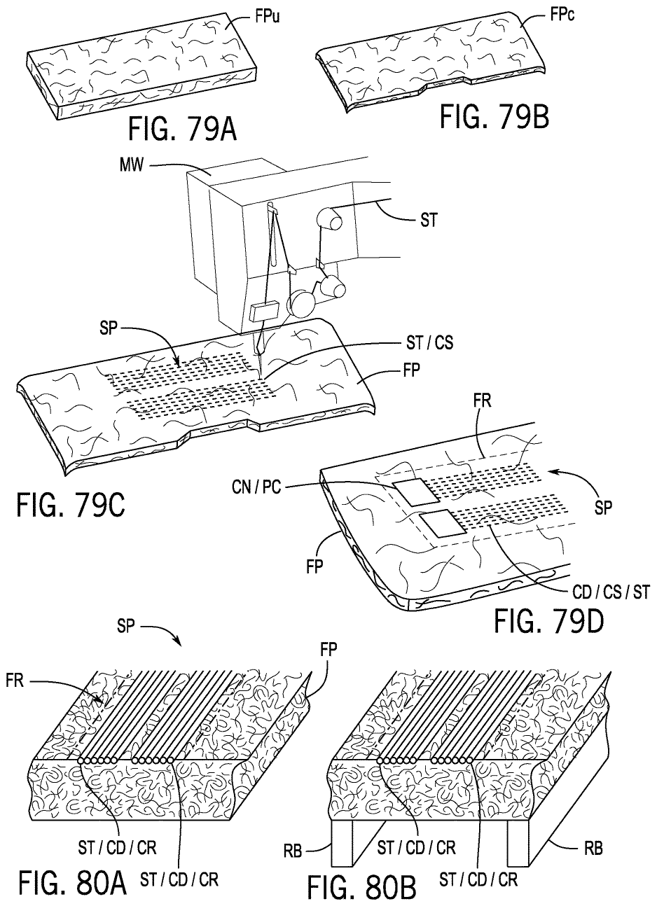

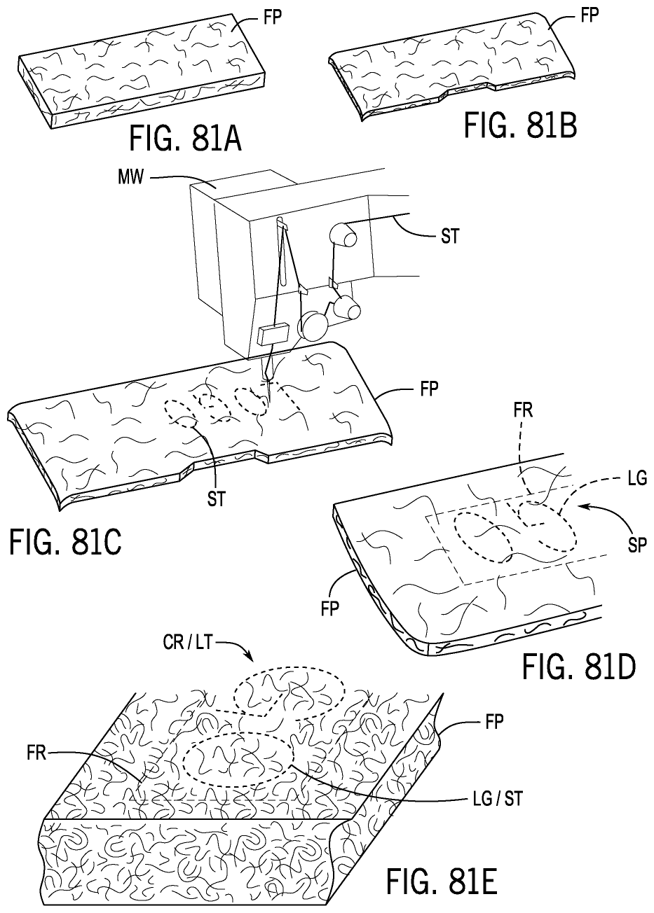

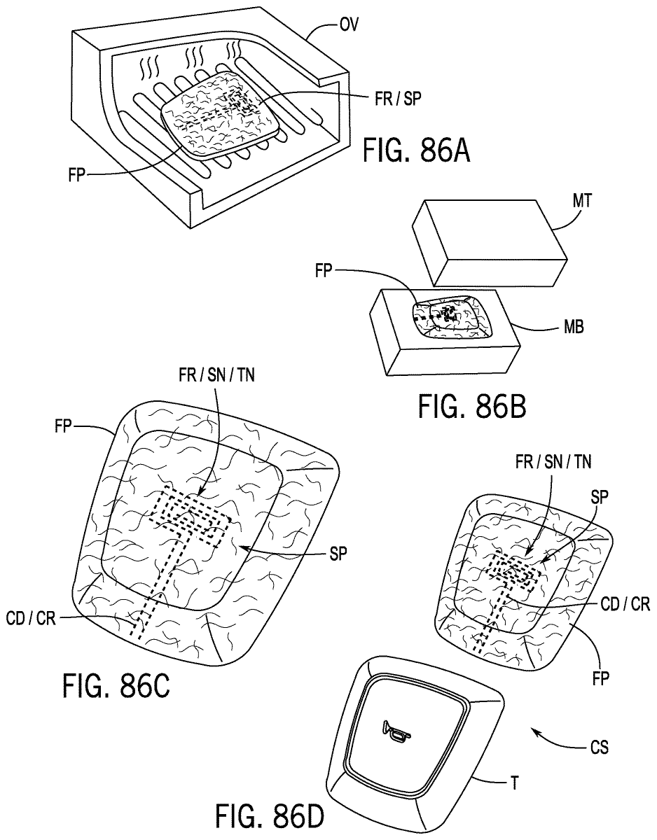

As shown schematically according to an exemplary embodiment in FIGS. 8, 31A-31E, 32A-32E, 33A-33B, 51A-51F, 75A-75D, 76A-76B and 77A-77B, the component may comprise a steering wheel assembly SW with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B, 26A-26C, 34A-34C, 52A-52B, 53A-53C, 55A-55C, 78A-78C, 86A-86D and 87A-87B.

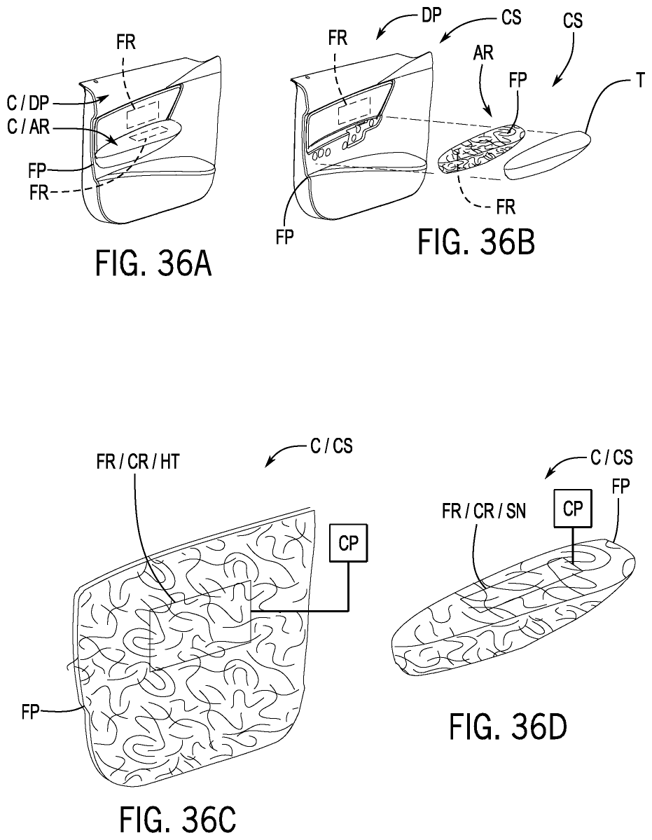

As shown schematically according to an exemplary embodiment in FIGS. 9 and 36A-36D, the component may comprise a door panel DP with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B, 26A-26C, 57A-57C and 89A-89C.

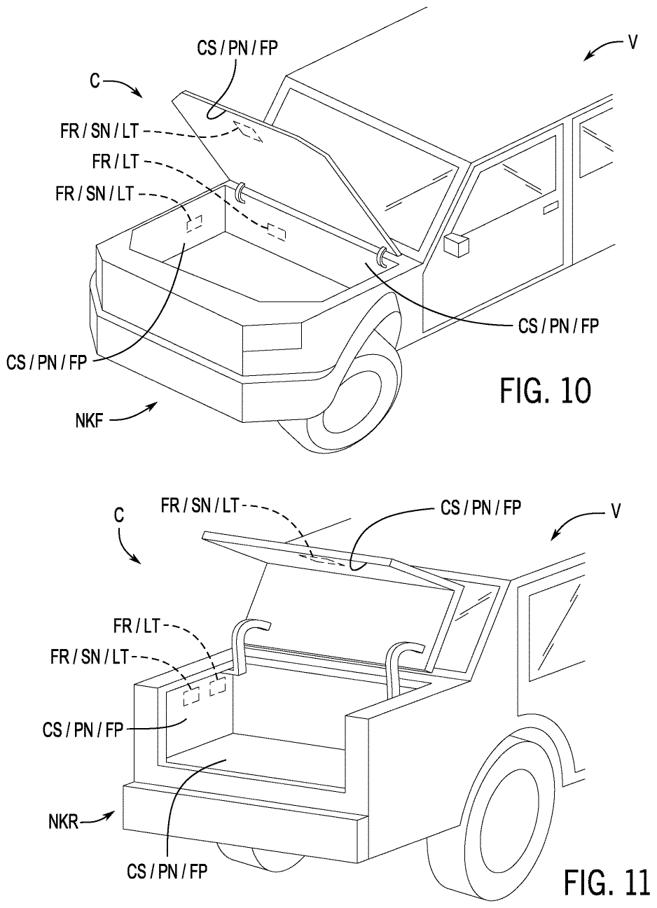

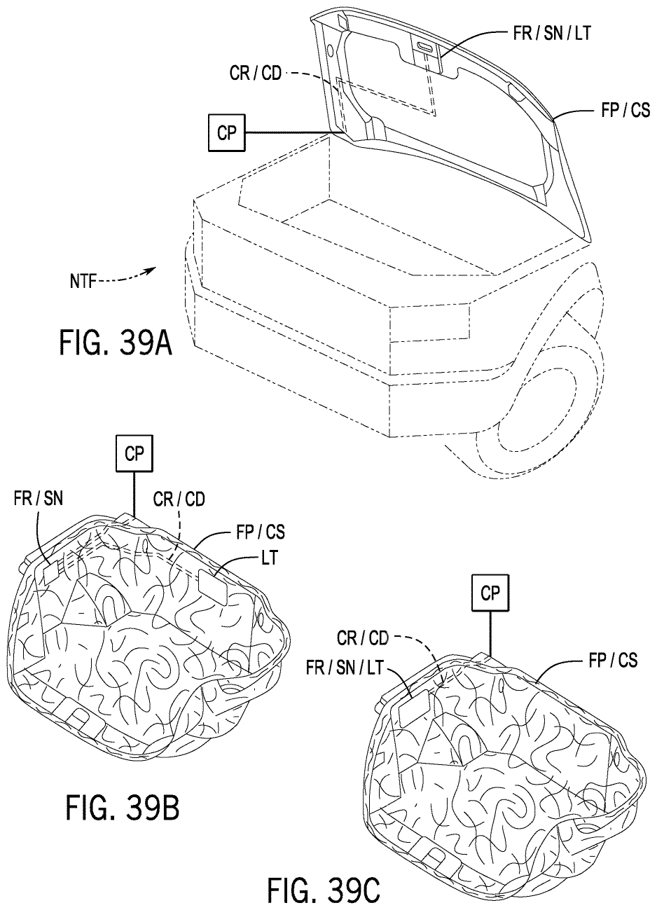

As shown schematically according to an exemplary embodiment in FIGS. 10 and 39A-39C, the component may comprise a front vehicle storage area/frunk NTF with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B and 26A-26C.

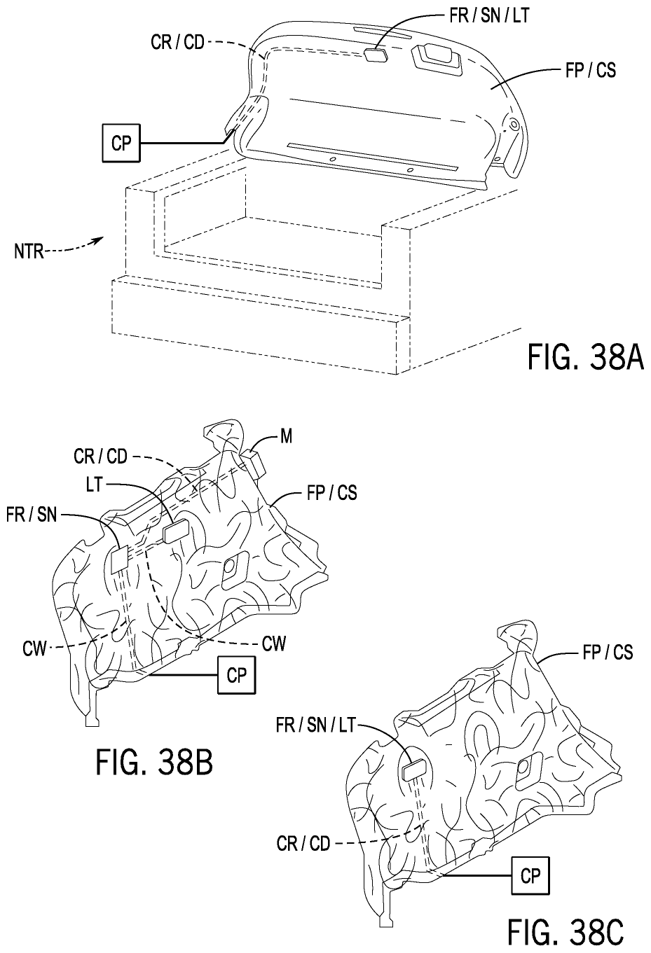

As shown schematically according to an exemplary embodiment in FIGS. 11 and 38A-38C, the component may comprise a rear vehicle storage area/trunk/hatch NTR with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B and 26A-26C.

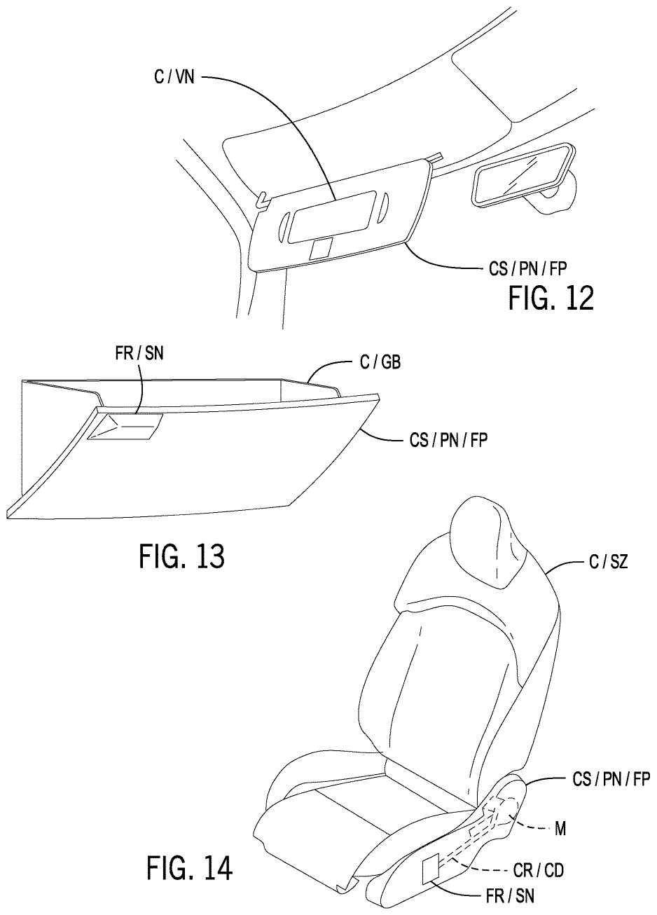

As shown schematically according to an exemplary embodiment in FIGS. 12 and 41A-41B, the component may comprise a visor/vanity assembly VN with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B and 26A-26C.

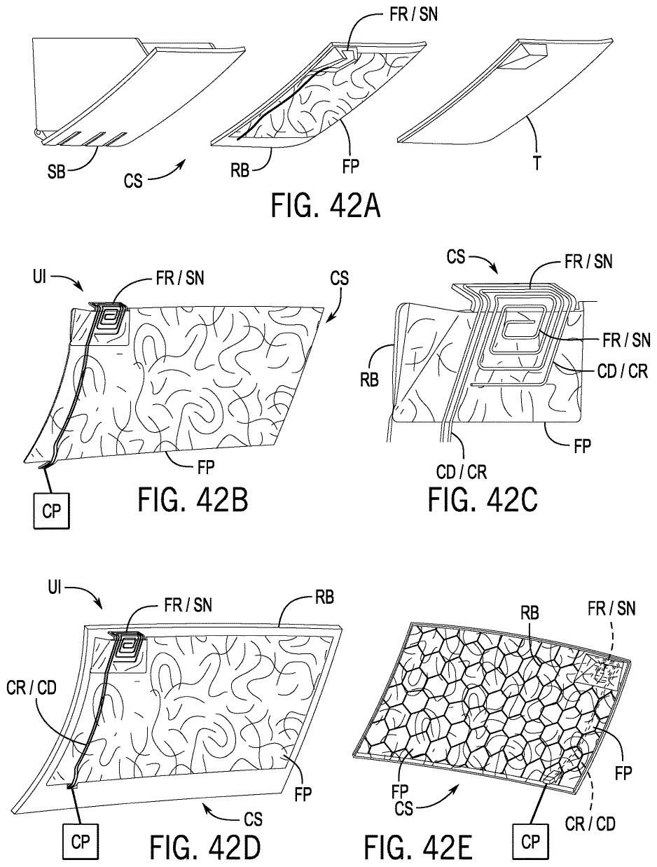

As shown schematically according to an exemplary embodiment in FIGS. 13 and 42A-42E, the component may comprise a receptacle/compartment GB (e.g. glove box/compartment) in an instrument panel IP with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B and 26A-26C.

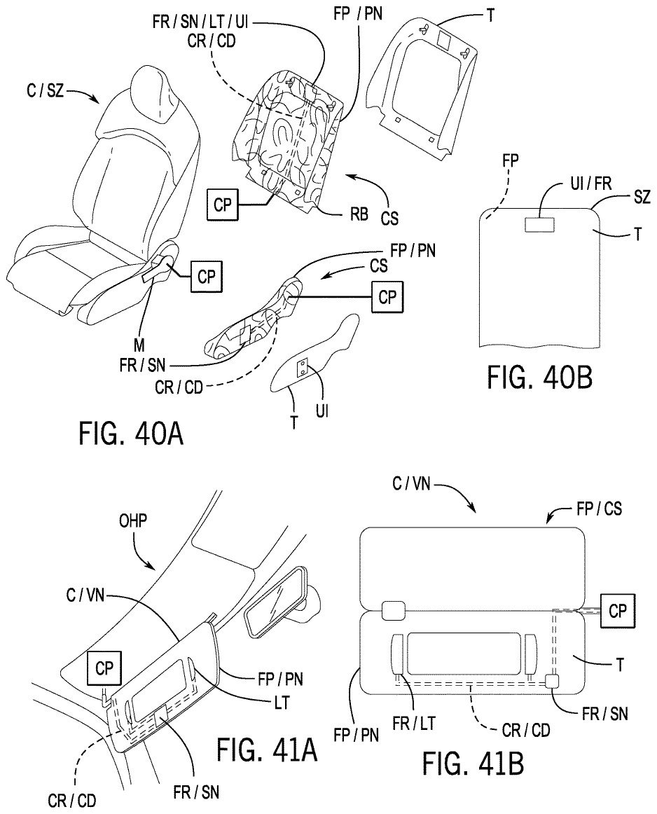

As shown schematically according to an exemplary embodiment in FIGS. 14 and 40A-40B, the component may comprise a seat assembly SZ with a composite structure CS comprising a fiber panel FP comprising a functional circuit FR with a conductor arrangement CD/CR configured for use/operation and/or connectivity with vehicle systems and/or networks and/or devices including through a connection point CP. See also FIGS. 2, 2A-2H, 15, 16, 17A-17B, 25A-25B and 26A-26C.

As shown schematically according to an exemplary embodiment in FIGS. 2A-2H, 15, 16, 17A-17B, 25A-25B and 26A-26C, the fiber panel FP of the composite structure CS of the component C may comprise a plug CNF for the connection point CP; a connector block may comprise a socket CNP for the plug CNF for the connection point; the plug may engage the socket to secure the connection of the functional circuit to vehicle systems, etc.

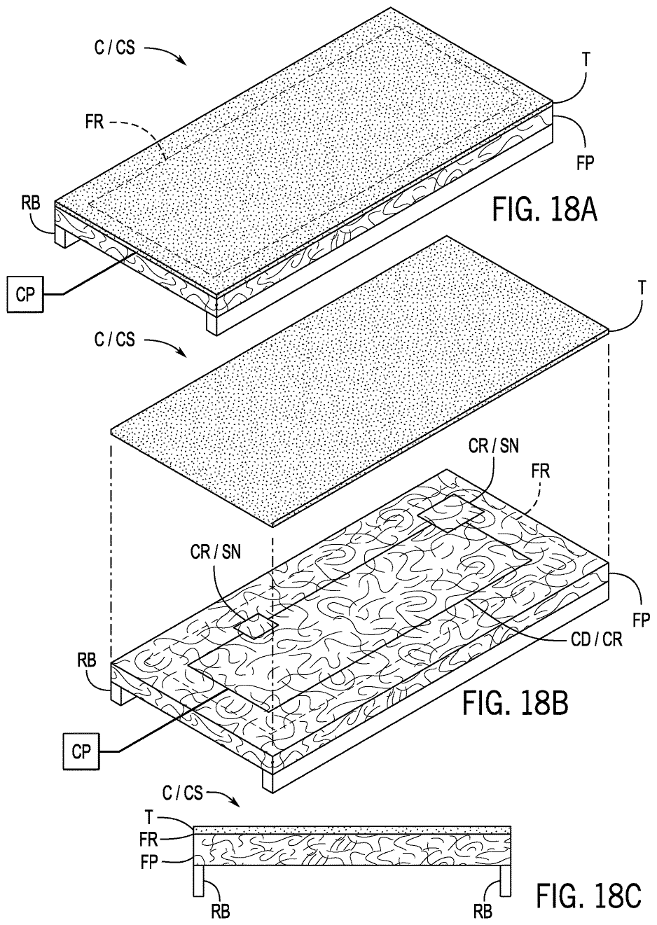

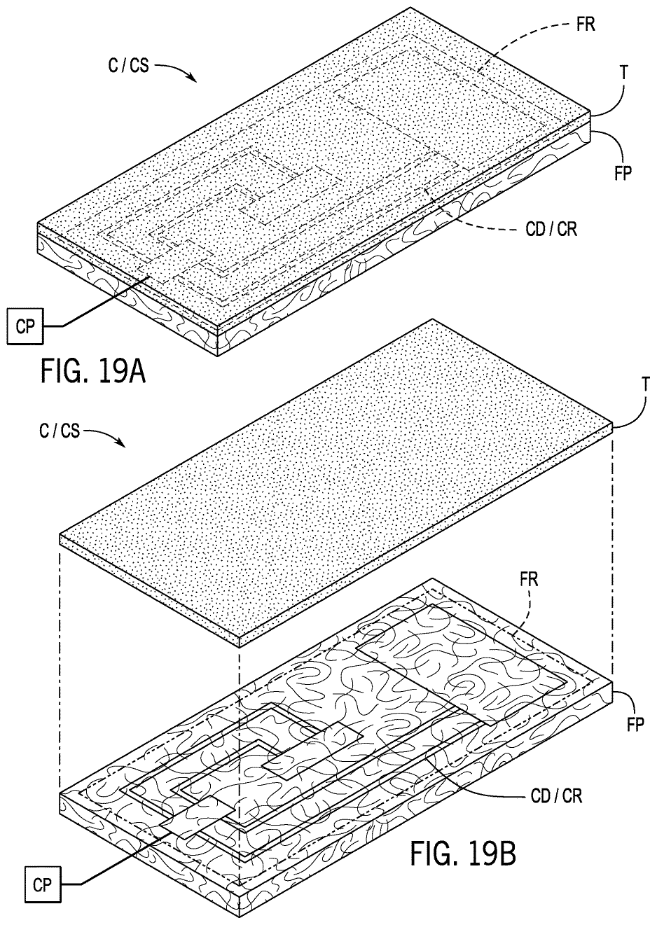

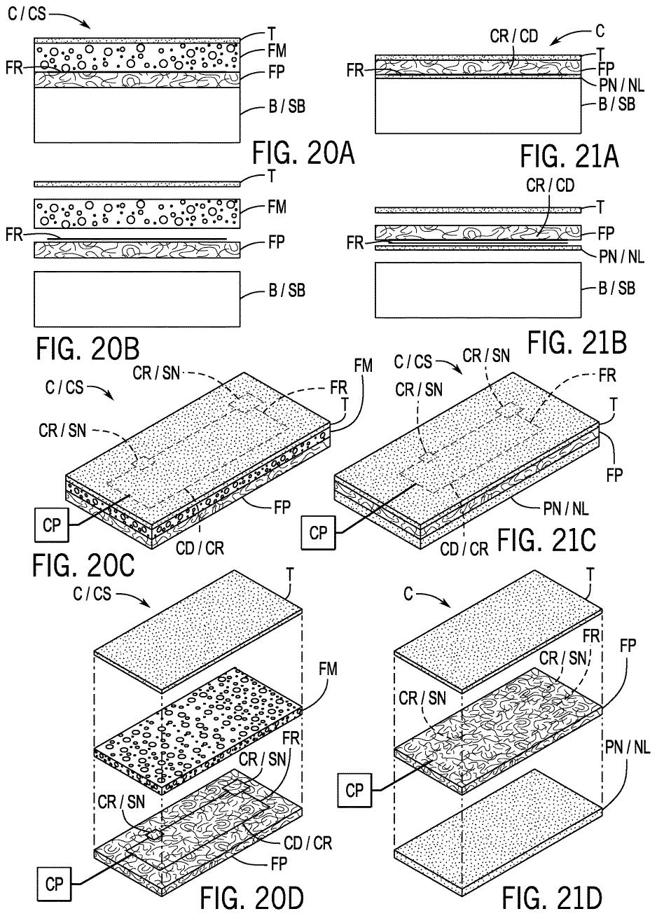

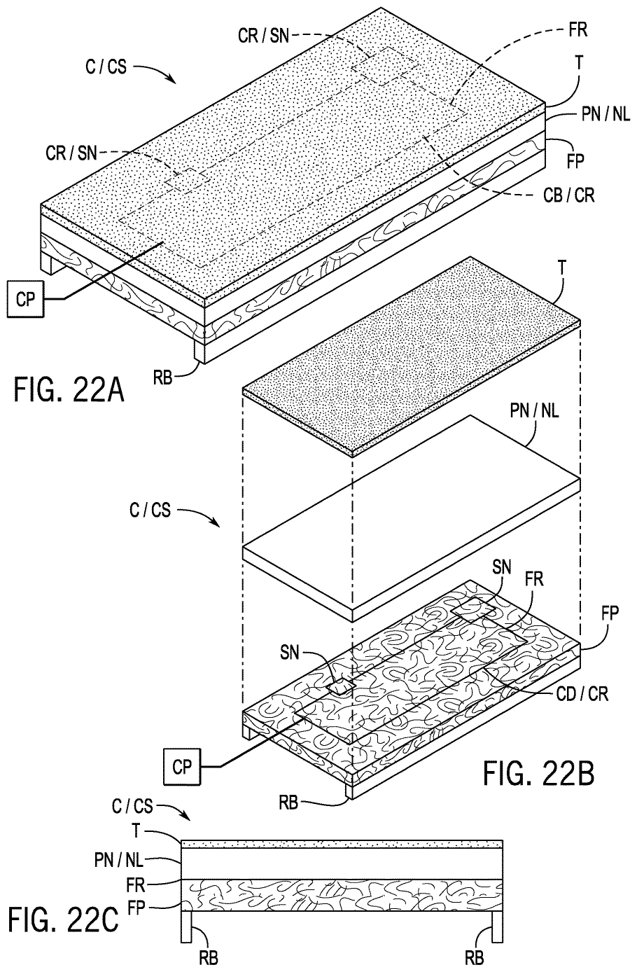

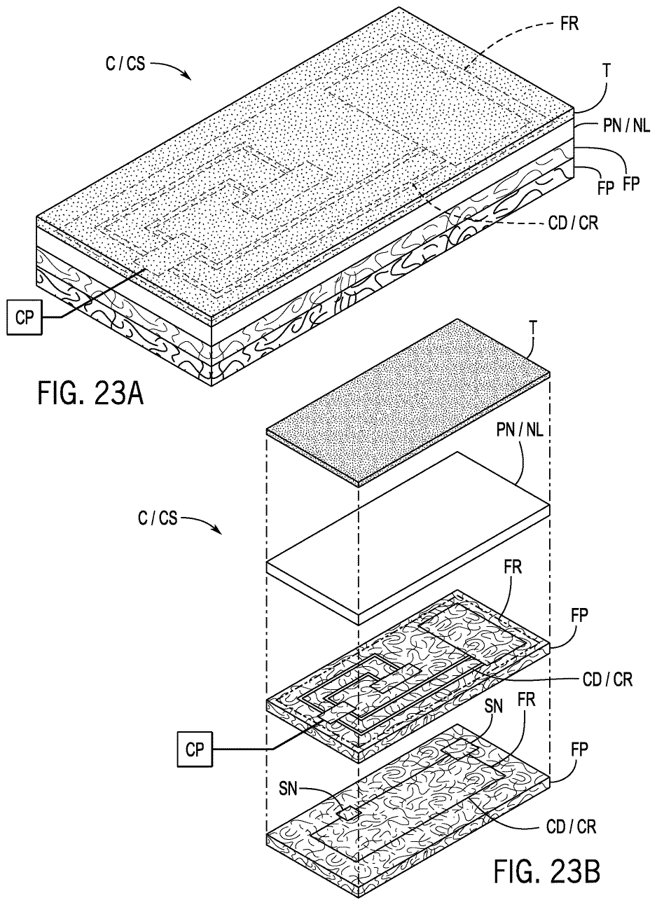

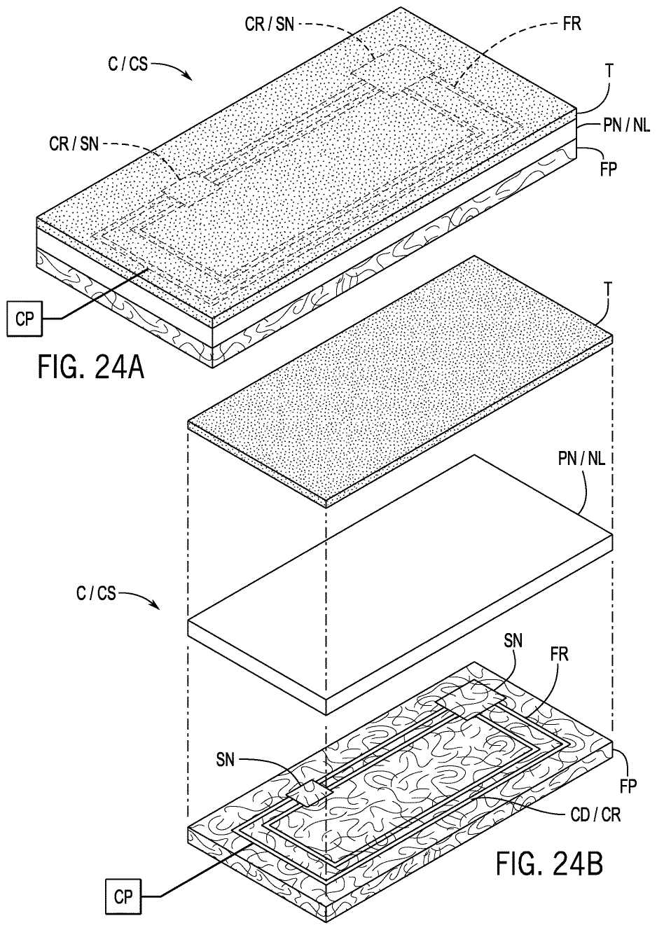

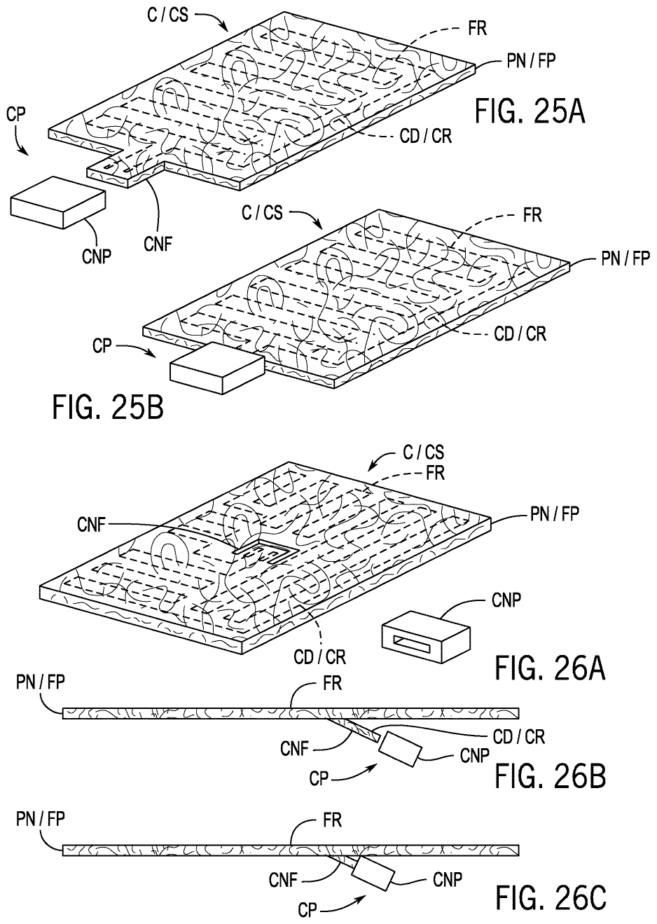

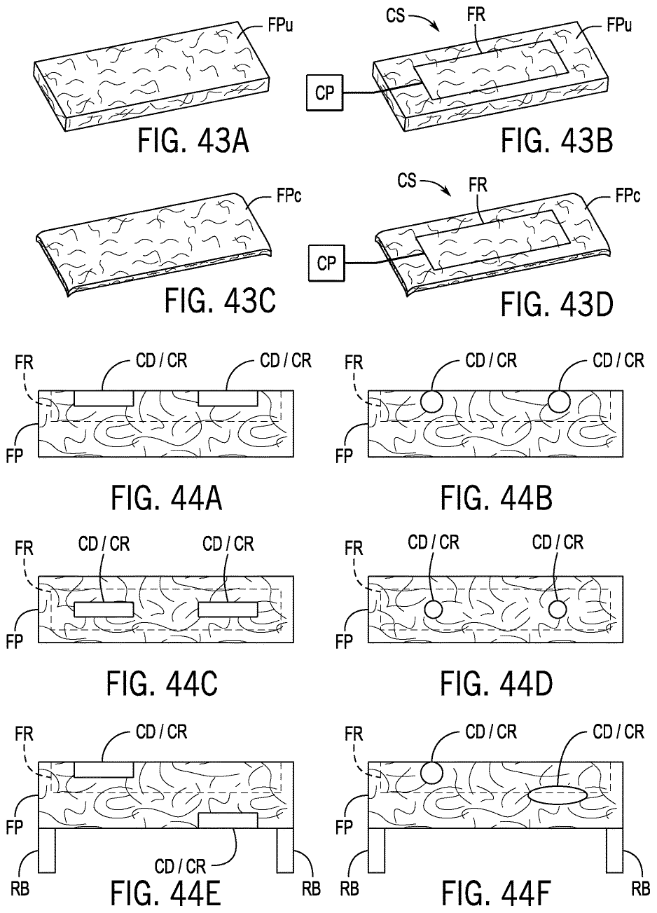

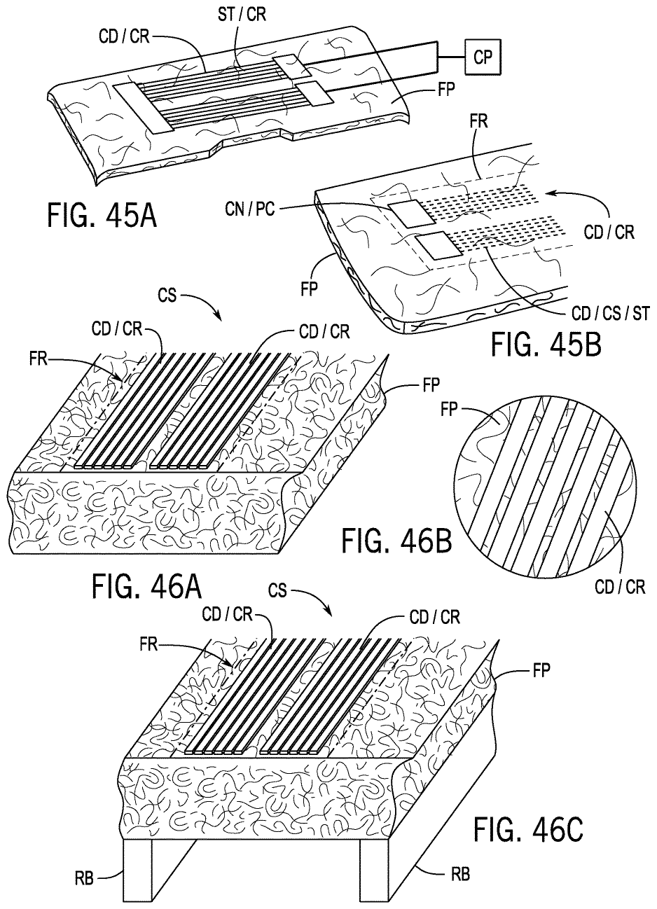

As indicated schematically according to an exemplary embodiment in FIGS. 18A-18B, 19A-19B, 20A-20D, 21A-21B, 22A-22C, 23A-23B, 24A-24B, the devices/systems provided by functional circuits FR and/or circuit elements CR may be configured and/or combined with components C with composite structure CS comprising fiber panel FP as a structural substrate to provide features/functionality for integration in the vehicle and/or with vehicle systems, networks, devices, etc.; the conductor arrangement CD/CR providing the functional circuit/element FT/FR may be integrated on and/or within the panel shown as fiber panel FP of the composite structure CS; the conductor arrangement CD/CR on the panel shown as fiber panel FP may be concealed under a cover T; component C may comprise the composite structure CS of the fiber panel FP with the functional circuit FR and cover T on or with a base/substrate B/SB. As indicated schematically in FIGS. 43A-43B, 44A-44F, 45A-45B and 46A-46C, the conductor arrangement CD/CR of the fiber panel FP may comprise a conductor wire or traces or thread on or in or under the fiber panel FP; conductor arrangement CD/CR may be integrated with the fiber panel FP to provide the functional circuit FR for the composite structure CS and to connect at a connection point CP. See also FIGS. 25A-25B and 26A-26C.

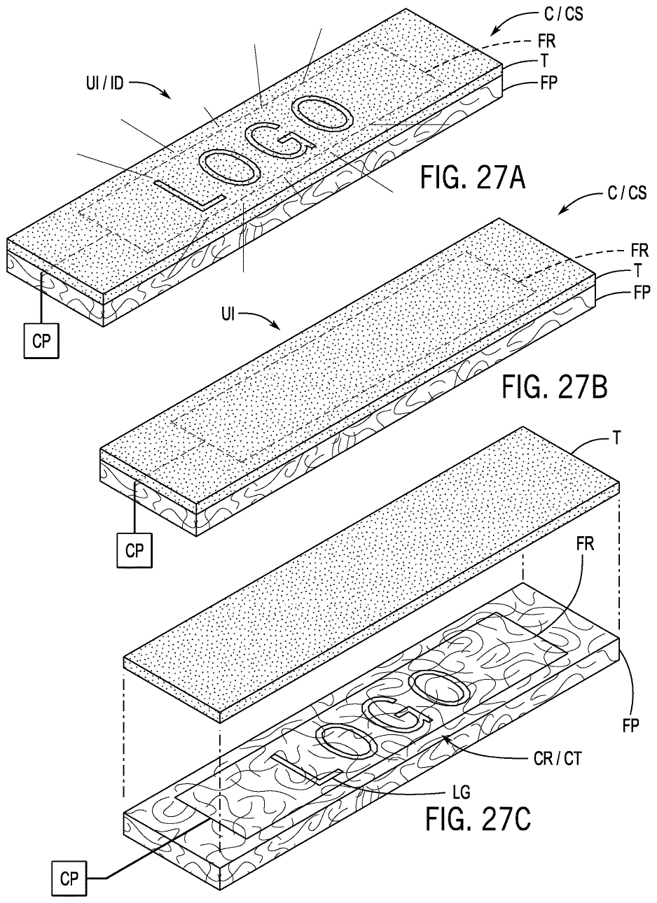

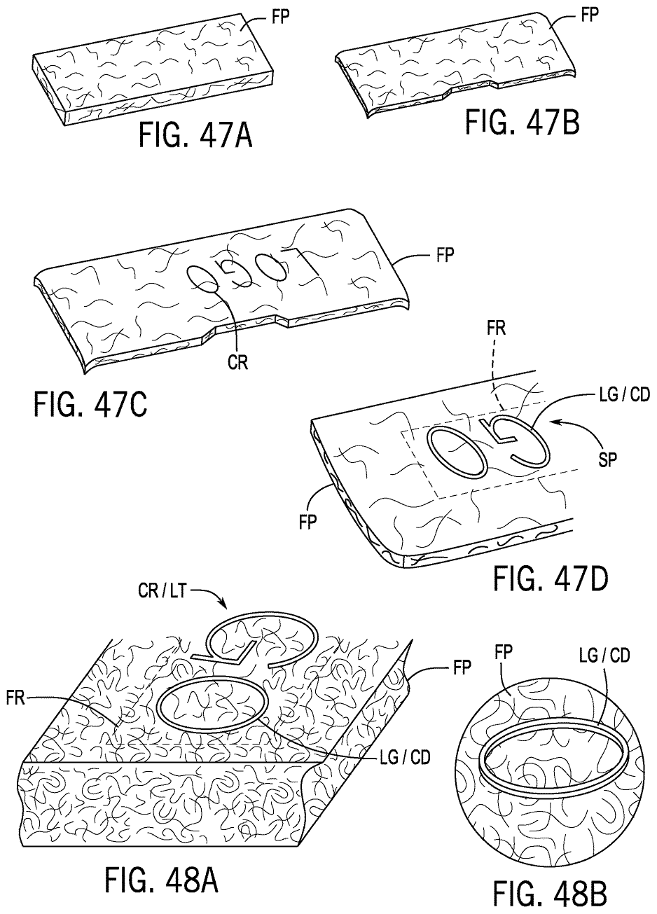

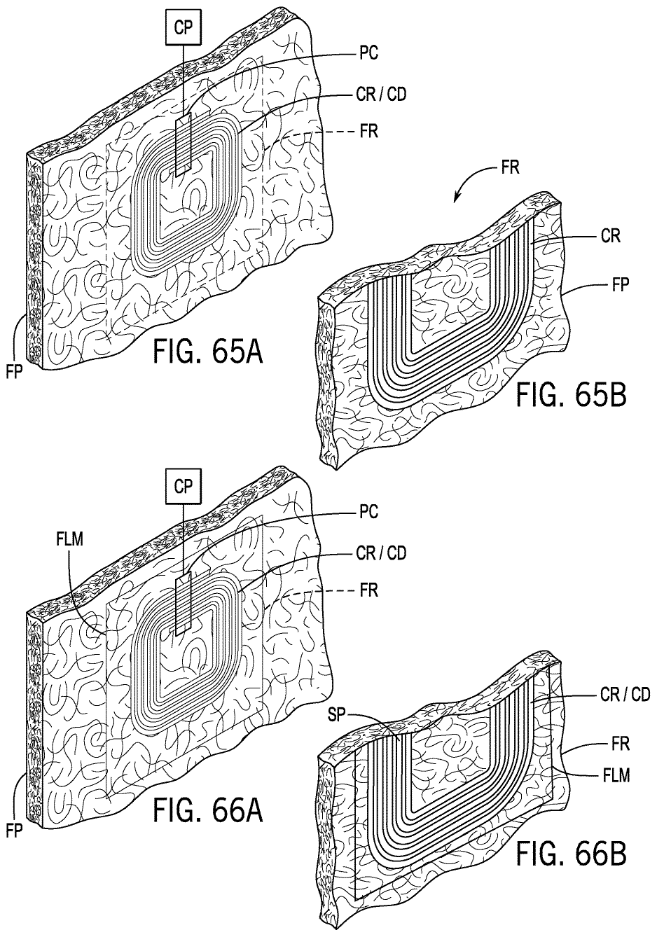

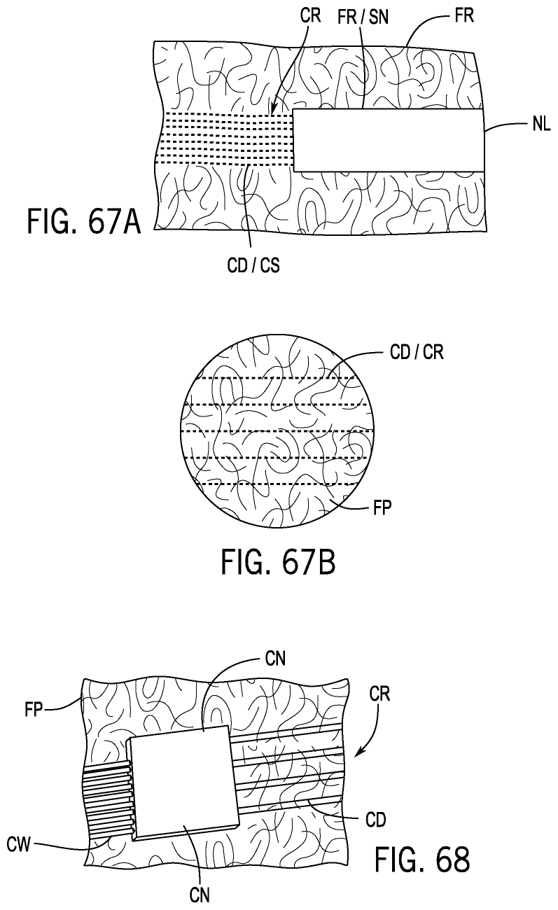

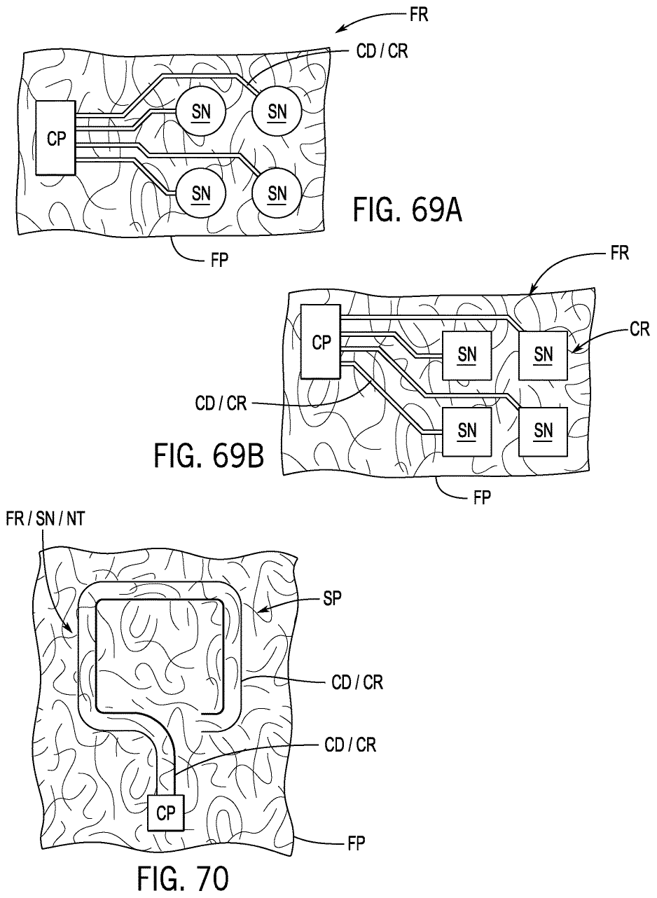

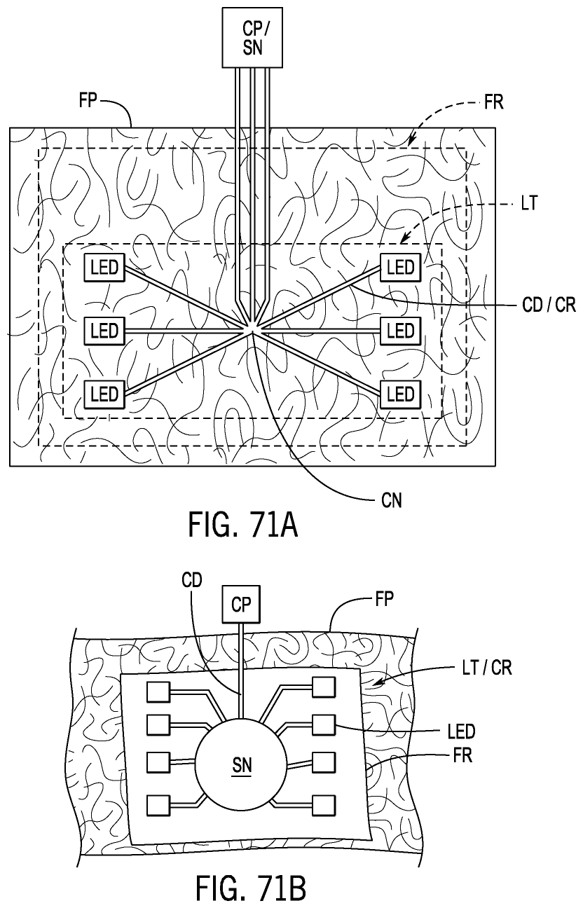

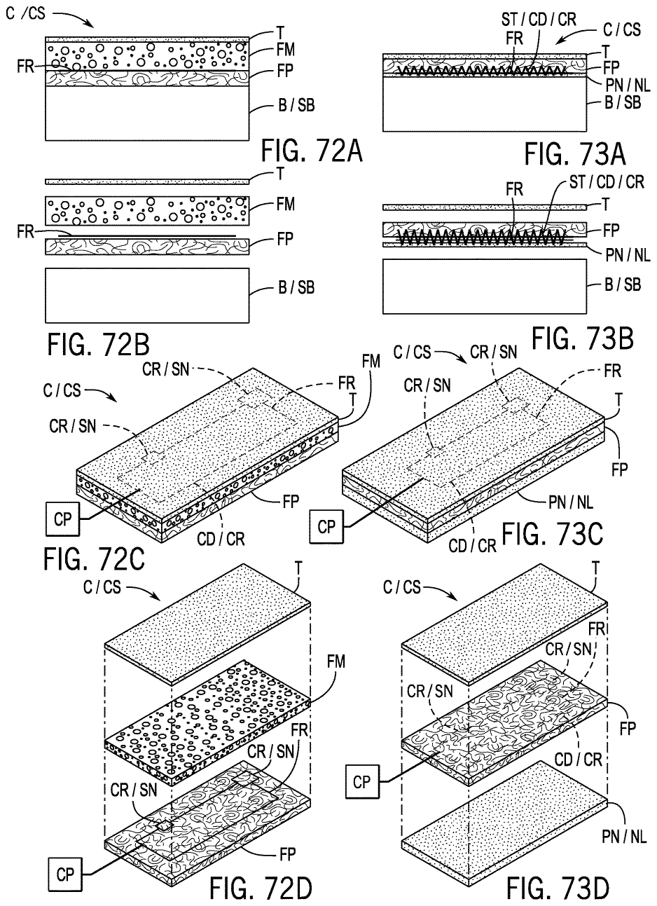

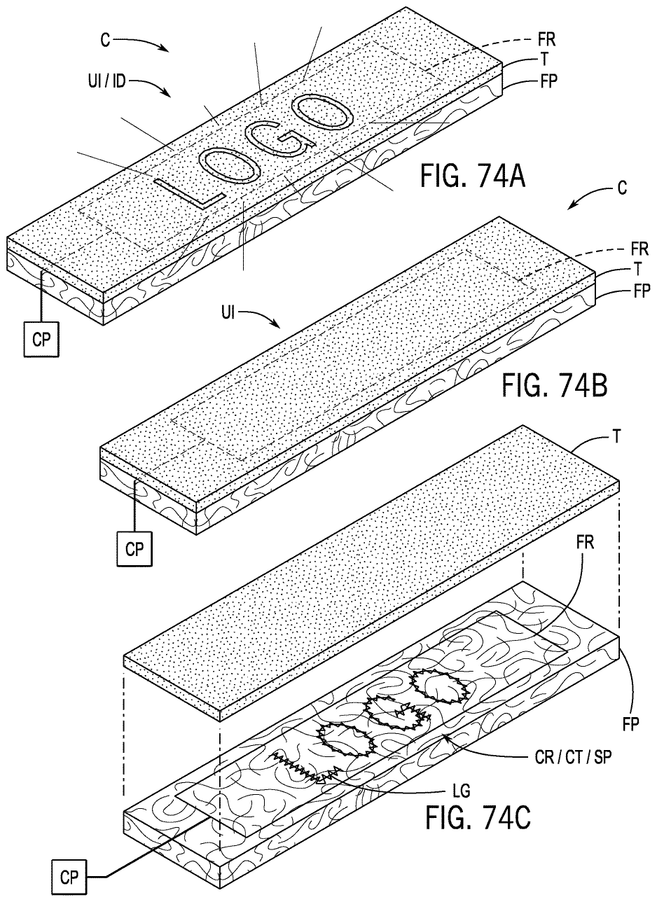

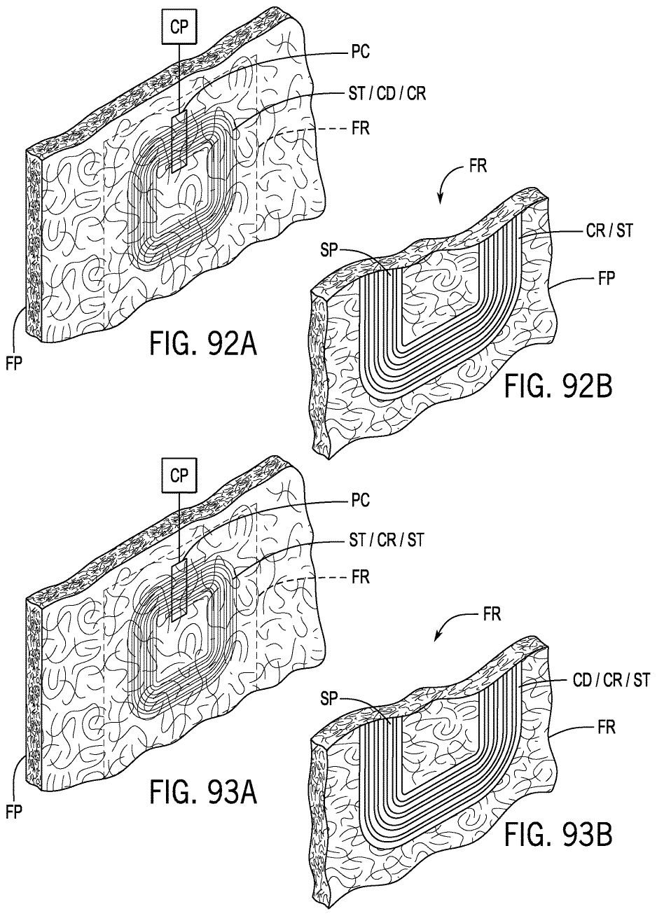

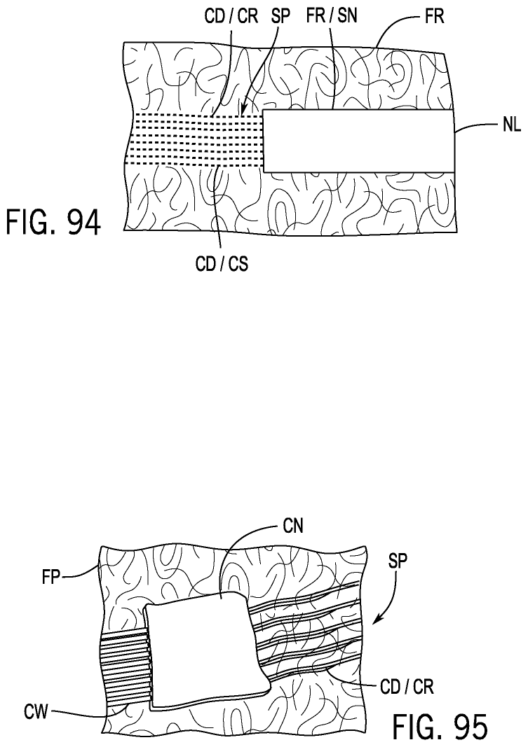

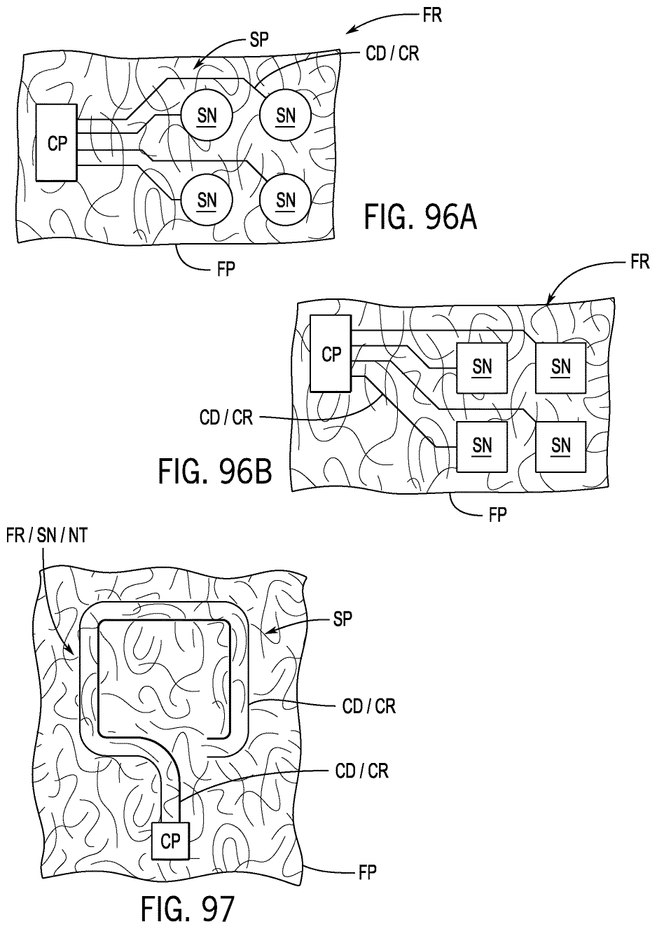

As indicated schematically according to an exemplary embodiment in FIGS. 18A-18B, 19A-19B, 20A-20D, 21A-21B, 22A-22C, 23A-23B, 24A-24B, the devices/systems provided by functional circuits FR and/or circuit elements CR configured and/or combined with components C to provide features/functionality may be provided in a composite structure CS comprising a panel shown as fiber panel FP and a cover T; component C may comprise the composite structure of panel and cover on or with a base/substrate B/SB; the fiber panel FP may comprise a conductor CD; the conductor may provide the functional circuit FR for the composite structure. As indicated schematically according to an exemplary embodiment in FIGS. 2, 2A-2H, 61, 62 and 63, the systems/devices provided by functional circuit FR may be configured with the conductor arrangement CD/CR such as wiring/traces CW and/or a pattern of conductive thread/stitch CR/ST/SP to provide a wide variety of features/functions and to integrate/connect with conventional systems/devices for a vehicle interior, including sensors SN, connection points CP, LED lighting, light guide LG, display DL, user interface UI (input and/or output), etc. See generally FIGS. 27A-27C, 47A-47D, 48A-48, 59A-59D, 64A-64B, 65A-65B, 66A-66B, 67A-67B, 68, 69A-69B, 70, 71A-71B, 91A-91B, 92A-92B, 93A-93B, 94, 95, 96A-96B, 97, 98A-98B and TABLE A.

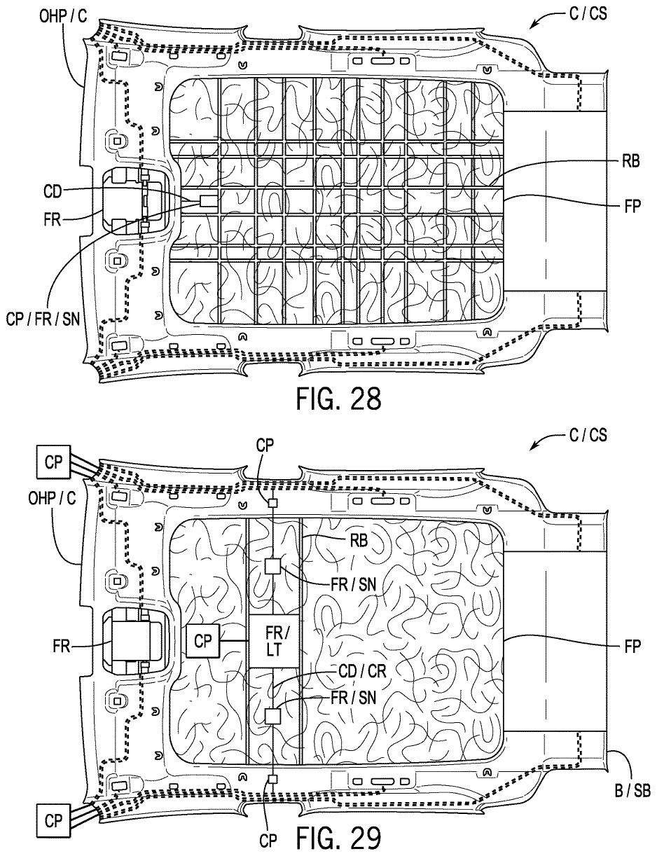

As indicated schematically according to an exemplary embodiment in FIGS. 18A-18B, 22A-22C and 42D-42E, the component C may comprise a composite structure CS comprising a substrate comprising a fiber panel FP with a formed feature shown as resin structure RB as a border, reinforcement, rib, attachment point, ancillary feature, module, housing, etc. See also FIGS. 28, 29, 30A-30B, 44E-44F, 46C and 54A-54B.

As indicated schematically according to an exemplary embodiment in FIGS. 28, 29, 30A-30B and 54A-54B, the component C comprising composite structure CS may comprise an overhead system/panel assembly OHP comprising a base B/SB and a fiber panel FP with an arrangement of conductors CD for functional circuits FR such as lighting LT, sensors/switches SN, etc. connected to vehicle systems at connection points CP; the composite structure of the overhead system/panel OHP/C may comprise structural elements such as ribs RB formed on/for the fiber panel FP; the overhead system/panel OHP/C may be configured to facilitate formation of a moon/sun roof. As indicated schematically according to an exemplary embodiment in FIGURES *, the component C may comprise any of a variety of interior components comprising in any of a variety of forms a composite structure with a cover T and a fiber panel FP with an arrangement of conductors CD for a variety of functional circuits FR such as lighting LT, sensors/switches SN, etc.; as indicated schematically, the composite structure may comprise other structures such as reinforcement/rigidifying elements shown as molded/resin ribs, etc. for the fiber panel comprising the functional circuit.

As indicated schematically according to an exemplary embodiment in FIGS. 18A-18B, 19A-19B, 20A-20D, 21A-21B, 22A-22C, 23A-23B, 24A-24B, the systems/devices provided by functional circuit FR for component C may be configured to integrate/connect with the composite structure CS comprising fiber panel FP. See also FIGS. 2, 2A-2H, 3, 4, 5, 6, 7, 8, 9, 10, 11, 12, 13, 14, 61, 62 and 63.

As indicated schematically in FIGS. 18A-18B, 19A-19B, 20A-20D, 21A-21B, 22A-22C, 23A-23B, 24A-24B, the functional circuit FR with circuit elements CR such as sensor elements SN, lighting elements LG/LT, etc. may be formed with and/or on the fiber panel FP of the composite structure CS; as indicated schematically, the component with composite structure CS may comprise a base/substrate B/SB; as indicated schematically, the composite structure CS may comprise an intermediate layer such as shown by foam layer FM; as indicated schematically, the composite structure CS may comprise an insulation layer/panel such as shown by layer PN/NL; as indicated schematically, the composite structure may comprise a conductor arrangement CD/CR such as wires/traces or a stitch ST. See generally FIGS. 27A-27C, 47A-47D, 48A-48, 59A-59D, 64A-64B, 65A-65B, 66A-66B, 67A-67B, 68, 69A-69B, 70, 71A-71B, 91A-91B, 92A-92B, 93A-93B, 94, 95, 96A-96B, 97, 98A-98B and TABLE A. As indicated schematically, the composite structure may comprise a fiber panel FP with a functional circuit FR comprising a lighting arrangement comprising light guide LG.

As indicated schematically according to an exemplary embodiment in FIGS. 18A-18B, 19A-19B, 20A-20D, 21A-21B, 22A-22C, 23A-23B, 24A-24B, the systems/devices provided by functional circuit FR for component C may be configured to be formed with and within the composite structure comprising fiber panel FP; the conductor CD for functional circuit FR may comprise a pattern of electrically conductive threads CR/ST; conductive thread may comprise a stitch arrangement ST shown as a stitch pattern SP within the fiber panel FP; conductive thread may be stitched into/onto the fiber panel. As indicated schematically, the conductor CD may comprise wires/traces and/or a stitch pattern SP comprising conductive thread CR/ST comprising the functional circuit FR. As indicated schematically, the composite structure may comprise a structure shown as resin structure RB for the fiber panel FP; the resin structure RB may be formed on the fiber panel FP at or adjacent to the functional circuit FR. As indicated schematically in FIGS. 18A-18B, 19A-19B, 20A-20D, 21A-21B, 22A-22C, 23A-23B, 24A-24B, the component C with composite structure may comprise a fiber panel FP configured to provide an arrangement of conductors CD shown as conductive threads CS for functional circuit FR or circuit element CR and/or an arrangement of non-conductive threads ST such as for reinforcement of a hinge HG for an airbag door ABD or for a decorative feature, etc. See generally FIGS. 27A-27C, 47A-47D, 48A-48, 59A-59D, 64A-64B, 65A-65B, 66A-66B, 67A-67B, 68, 69A-69B, 70, 71A-71B, 91A-91B, 92A-92B, 93A-93B, 94, 95, 96A-96B, 97, 98A-98B and TABLE A. As indicated schematically, a stitch pattern SP comprising a conductive thread CS and/or a non-conductive thread ST and/or light guide thread LG may be provided in fiber panel FP by the stitch of a needle N from an apparatus shown as sewing machine MW (e.g. to stitch on, emboss, stitch in, etc. the fiber panel). As indicated schematically according to an exemplary embodiment, the systems/devices provided by functional circuit FR for component C may be configured with and within the composite structure CS comprising fiber panel FP as or with a variety of circuit elements CR including with conductors CD of conductive thread CR/ST provided in a stitch pattern SP and cables/wires CW and with connection points CN and insulation/layer NL and connector/pad PC and light arrangement LT with light guide LG and/or LED elements and sensor/switch SN and sensor/detector arrangement SN and antenna NT and etc.

As indicated schematically in FIGS. 2, 2A-2H, 3, 4, 5, 6, 7, 8, 9, 10, 11, 12, 13 and 14, the functional circuit FR and circuit elements CR provided with the fiber panel FP of the composite structure CS of the component C may be designed/configured to provide a wide variety of features/functions and systems/devices within the vehicle interior. See generally FIGS. 15, 16, 17A-17B, 18A-18B, 19A-19B, 20A-20D, 21A-21B, 22A-22C, 23A-23B, 24A-24B. 27A-27C, 47A-47D, 48A-48, 59A-59D, 64A-64B, 65A-65B, 66A-66B, 67A-67B, 68, 69A-69B, 70, 71A-71B, 91A-91B, 92A-92B, 93A-93B, 94, 95, 96A-96B, 97, 98A-98B and TABLE A.

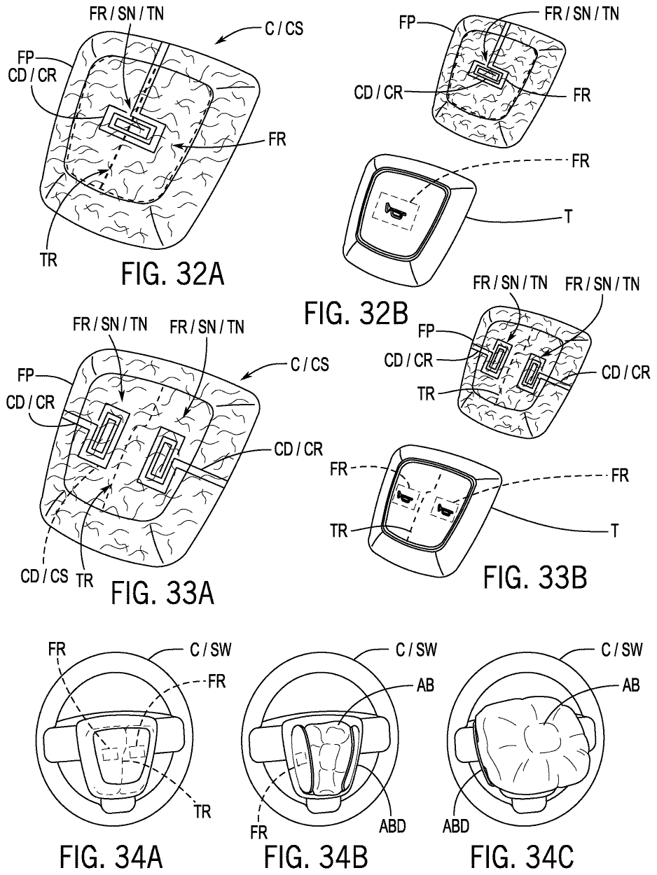

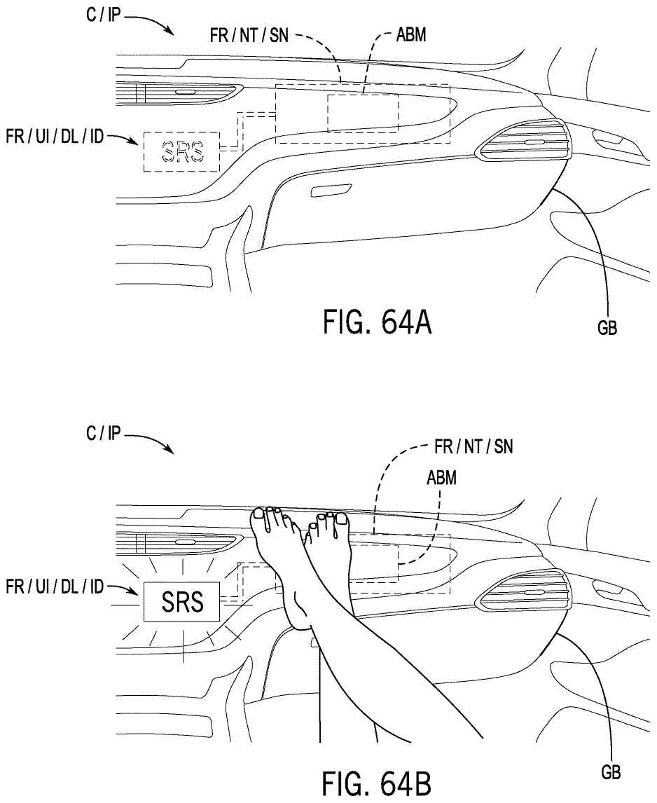

As indicated schematically in FIGS. 32A-32B, 33A-33B, 34A-34C, 60A-60B, 76A-76B, 77A-77B and 78A-78C, the functional circuit FR of the fiber panel FP of the composite structure CS may be configured to be formed and to integrate within the component and with other features/systems such as an airbag module ABM configured to deploy an airbag AB through an opening formed by an airbag door ABD at a tear line/seam TR in the component C; the functional circuit FR may be on the tear line/seam TR to facilitate deployment of the airbag AB, the functional circuit FR may be adjacent to the tear line/seam TR to facilitate deployment of the airbag AB at the airbag door ABD. As indicated schematically in FIGS. 64A-64B, the functional circuit FR may comprise a sensor SN/NT configured to detect the presence/touch of an occupant and provide a signal to a vehicle system such as a safety system SRS shown as comprising an airbag module ABM; as indicated schematically, the functional circuit FR of the component C may be integrated with other systems of the component such as the airbag module ABM.

As indicated schematically according to an exemplary embodiment in the FIGURES, the component may comprise a composite structure CS comprising a substrate comprising a fiber panel; the fiber panel may comprise a conductor arrangement; the conductor arrangement may be configured to provide a functional circuit for the composite structure. The substrate may comprise a structural substrate; the fiber panel may comprise a compression-formed fiber panel. The functional circuit/element may comprise the conductor arrangement; the conductor arrangement and/or functional circuit may be configured to comprise at least one of: a conductor, a sensor/detector, an input device, an output device, an interactive device, a display; a switch, a light/lighting, a light element, a light guide, etc. The conductor arrangement and/or functional circuit may be configured to comprise at least one of a light/lighting, a light element, a light guide; an LED/LED lighting, a display, a display panel, an antenna, a camera, a video-recorder; an image display/device, a user interface, an input device, an output device, an input/output device; a sensor, a detector, a switch, a touch sensor; an odor/scent detector, a microphone, a sound detector, a wireless charging device, a wireless connection area, a heating element, an electrified area, other device/technology, etc. The fiber panel with functional circuit may be configured for connection by an edge connector. The composite structure may comprise a feature on the fiber panel; the feature may comprise a resin/molded structure. The feature may comprise a border/reinforcement for the fiber panel; the feature may comprise a structural reinforcement for the composite structure. The fiber panel may comprise a conductor pattern comprising a conductive trace; the conductor arrangement may comprise conductive wire and/or conductive thread.

As indicated schematically in the FIGURES, the component may comprise a trim panel, an instrument panel, a door panel, an overhead panel, a console, an overhead console, a floor console, an armrest, an interior trim component, pillar trim, an operator control, a steering control, a steering wheel, a trunk, a frunk, a hatch, a car rear compartment, a car front compartment, a visor, a vanity, a glove box, a receptacle in an instrument panel, a receptacle in a trim panel, etc.

### Exemplary Embodiments—A

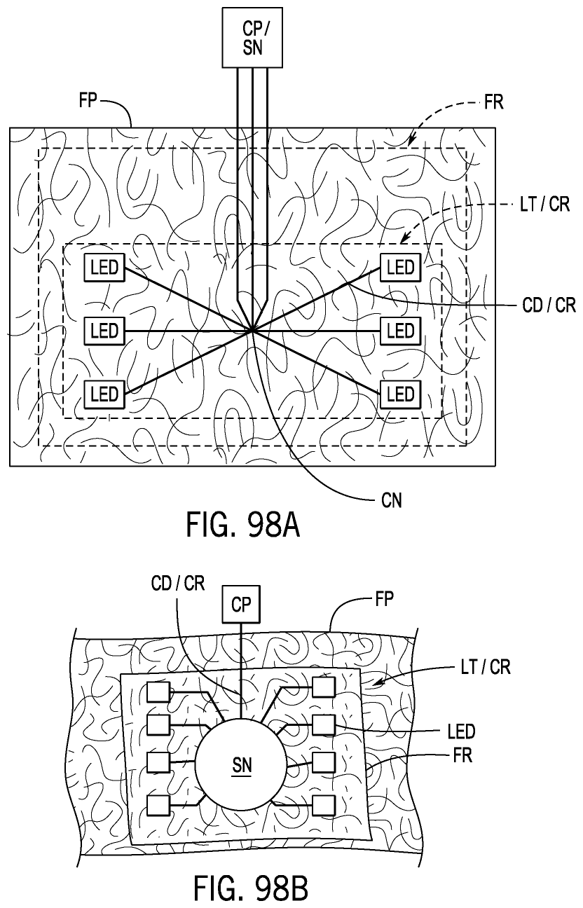

According to an exemplary embodiment shown schematically in FIGS. 1 through 98A-98B, a component for a vehicle interior may comprise a composite structure comprising a structural substrate comprising a compression-formed fiber panel and a conductor arrangement; the compression-formed fiber panel may be formed by compression-forming of a fiber panel with the conductor arrangement; the conductor arrangement may be configured to provide a functional circuit and a connection point; the composite structure may comprise a feature for the connection point; the connection point may comprise a connector for the functional circuit; the connector may comprise a projection and/or a flange and/or a tab; the connector may comprise a connector block; the connector may comprise an internal connector; the connector may comprise an external connector; the connector may comprise an edge connector; the connector may comprise an internal edge connector and/or an external edge connector; the edge connector may comprise a tab on the composite structure configured to fit within a socket; the structural substrate may comprise a generally flat form; the tab may be provided at a perimeter of the structural substrate and/or within a perimeter of the structural substrate; the tab may be provided at an angle relative to the structural substrate; the connector may be integrated on and/or within the compression-formed fiber panel; the connector may be configured to connect to the functional circuit at the connection point; the connector may comprise a conductive trace and/or a pattern of conductive traces and/or a set of electrically conductive traces and/or a multi-layer conductor pattern and/or a set of conductive traces and/or a wire and/or an insulated wire and/or an exposed wire and/or a generally flat trace and/or a generally flat wire and/or a lead and/or a band and/or conductive wire and/or conductive thread; the connector may be provided within the fiber panel and/or provided on the fiber panel and/or provided into the fiber panel and/or provided onto the fiber panel; the connector may be formed into the compression-formed fiber panel; the connector of the composite structure may comprise a plug for the connection point; the connector may comprise a socket and a plug at the connection point; the plug may engage the socket to secure the connection of the functional circuit to vehicle systems; the feature may comprise a formed feature and/or a resin feature and/or a formed resin feature and/or a molded resin feature and/or a formed structure and/or a molded structure and/or a molded resin structure and/or an injection-molded structure and/or a structure configured to provide support for the connector and/or a module for the connector and/or a resin structure and/or a molded structure and/or a reinforcement and/or a rib; the feature may comprise a structure for the connector and/or a support for the connector and/or a housing for the connector; the feature may comprise a reinforcement for the fiber panel and/or a reinforcement for the functional circuit and/or a structural reinforcement for the composite structure; the feature may comprise at least one of a housing for an electrical connector and a cover for an electrical connector to the conductor arrangement and/or a connection point for the conductor arrangement and/or a wire; the connector may be configured to connect to a power source and/or at least one vehicle system.

According to an exemplary embodiment shown schematically in FIGS. 1 through 98A-98B, a component may comprise a composite structure comprising a substrate comprising a fiber panel; the fiber panel may comprise a conductor arrangement; the conductor arrangement may be configured to provide a functional circuit for the composite structure; the substrate may comprise a structural substrate; the structural substrate may comprise a compression-formed fiber panel. The conductor arrangement and/or functional circuit may be configured to comprise at least one of: a conductor; a sensor/detector; an input device; an output device; an interactive device; a display; a switch; a light/lighting; a light element; a light guide. The conductor arrangement and/or functional circuit may be configured to comprise at least one of a light/lighting; a light element; a light guide; an LED; LED lighting; a display; a display panel; an antenna; a camera; a video-recorder; an image display/device; a user interface; an input device; an output device; an input/output device; a sensor; a detector; a switch; a touch sensor; an odor/scent detector; a microphone; a sound detector; a wireless charging device; a wireless connection area; a heating element; an electrified area; other device/technology. The composite structure may comprise a base; the base may comprise a structural substrate; the fiber panel may comprise a compression-formed fiber panel. The substrate may comprise a feature; the feature may comprise a formed feature; the feature may comprise a molded resin feature; the feature may comprise at least one of a molded resin structure and/or a molded resin border and/or a molded resin reinforcement; the conductor arrangement may comprise a formed circuit comprising the functional circuit. The composite structure may comprise a fiber panel with a circuit panel comprising the functional circuit; the composite structure may comprise the fiber panel and a circuit matrix; the composite structure may comprise a cover. The conductor arrangement may comprise a conductor; a conductor may be within the fiber panel; a conductor may be on the fiber panel. The conductor arrangement may comprise a conductive trace; the conductive trace may comprise a conductor; the conductor arrangement may comprise a pattern of electrically conductive traces; the conductor arrangement may comprise a set of electrically conductive traces; a conductive trace may be within the fiber panel and/or on the fiber panel; a conductive trace may be provided into the fiber panel and/or onto the fiber panel. The fiber panel may comprise a mixture of fibers and plastic; the fibers may comprise natural fibers; the fibers comprise at least one of synthetic fibers, glass fibers, carbon fibers and/or polymeric fibers; the fiber panel may comprise a substantially rigid panel; the fiber panel may comprise a plurality of fibers and a resin configured to bind the fibers; the resin may comprise thermoplastic resin; the fiber panel may be configured to provide structural properties comprising rigidity and strength; the fiber panel may comprise a generally rigid panel formed from a fiber mat; the fiber panel may comprise a contoured fiber panel. The composite structure may comprise a feature on the fiber panel; the feature may be configured to provide a connection point for the functional circuit; the feature may comprise a molded resin structure; the feature may comprise a structure configured to provide support for a module for the functional circuit. The composite structure may comprise a flexible circuit formed on and/or in and/or with the fiber panel; the fiber panel may comprise the circuit board comprising the functional circuit; the composite structure may comprise a circuit panel comprising the conductor arrangement comprising a conductor pattern comprising a conductive trace; the conductor arrangement may comprise a conductor pattern comprising the functional circuit; the fiber panel may comprise a circuit panel; the conductor arrangement may comprise a pattern on the fiber panel; the conductor arrangement may comprise a metallic material and/or a metallic trace; the conductor arrangement may comprise a wire and/or an insulated wire; the conductor arrangement may comprise an exposed wire; the conductor arrangement may comprise a generally flat wire; the conductor arrangement may comprise a lead and/or a band; the conductor arrangement may comprise a multi-layer conductor pattern for the fiber panel; the multi-layer conductor pattern may comprise a set of conductive traces providing the functional circuit. The functional circuit may comprise a user interface; the user interface may comprise an input device and/or an output device; the functional circuit may comprise an input device and an output device; the functional circuit may comprise a connection point; the functional circuit may comprise a connector; the functional circuit may comprise a connector configured to connect to a power source and/or at least one vehicle system; the functional circuit may comprise a circuit element; the functional circuit may be configured for connection by an edge connector; the functional circuit may be configured for connection by an internal connector; the functional circuit may be configured for connection by an internal edge connector; the functional circuit may be configured for connection by an edge connector comprising a tab on the composite structure; the functional circuit may be configured for connection by an edge connector comprising a tab on the composite structure configured to fit within a socket; the functional circuit may be configured for operation by a control system; the functional circuit may comprise a controller configured for operation with a control system configured for operation of at least one vehicle system; the functional circuit may comprise a module; the functional circuit may comprise a connection point for a module. The functional circuit may comprise a user interface configured for operation of at least one vehicle system; the functional circuit may comprise a sensor; the functional circuit may comprise a sensor configured to operate as a switch; the functional circuit may comprise at least one of a light, an LED light, a display, an illuminated feature; the functional circuit may comprise an input device; the input device may comprise a switch; the functional circuit may comprise an output device; the output device may comprise a display; the functional circuit may be configured to operate a user interface comprising an input device and an output device. The functional circuit may be configured to operate a mechanism and/or a motor. The component may comprise a connector for the functional circuit; the functional circuit may be configured to be connected to a vehicle system and/or a network and/or a power source. The composite structure may comprise a feature on the fiber panel; the feature may comprise a resin structure; the feature may comprise a molded structure; the feature may comprise a rib; the feature may comprise a resin structure adjacent to the functional circuit; the fiber panel may comprise a conductor pattern comprising a conductive trace and the feature adjacent to the conductive trace; the feature may comprise an ancillary component on the fiber panel; the ancillary component may be molded on the fiber panel over the conductor arrangement; the ancillary component may comprise a structure for functional circuit and/or a support for functional circuit and/or a housing for functional circuit and/or a structure for connection to the functional circuit. The feature may comprise a reinforcement for the fiber panel and/or a reinforcement for the functional circuit; the feature may comprise a structural reinforcement for the composite structure; the conductor arrangement may comprise conductive wire and/or conductive thread; conductive thread may comprise wire; the composite structure may comprise a cover; the composite structure may comprise a foam layer beneath the cover; the composite structure may comprise a cover; the composite structure may comprise an intermediate layer beneath the cover; the conductor arrangement may be configured to be substantially functionally effective; the conductor arrangement may be configured to be substantially visually imperceptible under the cover; the composite structure may be configured so that the functional circuit is substantially visually imperceptible under the cover. The composite structure may comprise a cover; the cover may comprise at least one of (a) leather; (b) synthetic leather; (c) imitation leather; (d) a composite of a plastic layer and textile backing; (e) a coated fabric; (f) polyvinylchloride coated fabric; (g) a woven fabric; (h) a non-woven fabric; (i) an applique; (j) vinyl; (k) a foil; (1) coating on the structural substrate; (m) paint on the structural substrate; (n) the exterior surface of the structural substrate; (o) at least partial concealment for the electrical conductor arrangement. The component may comprise at least one of a trim panel, an instrument panel, a door panel, an overhead panel, a console, an overhead console, a floor console, an interior trim component, pillar trim, an operator control, a steering control, a steering wheel, a trunk, a frunk, a hatch, a car rear compartment, a car front compartment, a visor, a vanity, a glove box, a receptacle in an instrument panel.

According to an exemplary embodiment shown schematically in FIGS. 1 through 98A-98B, a component may comprise a composite structure comprising a substrate and a cover; the substrate may comprise a conductor arrangement; the conductor arrangement may be configured to comprise a functional circuit; the substrate may be formed from a fiber panel; the substrate has a shape. The conductor arrangement may have the shape; the conductor arrangement has a contoured shape conforming to a contoured shape of the substrate; the conductor arrangement may comprise a conductive trace configured to provide the functional circuit; the conductive trace may comprise a layer of electrically conductive traces; the conductive trace may comprise a set of electrically conductive traces; a conductive trace may comprise a set of electrically conductive wires; a conductive trace may comprise a multi-layer set of electrically conductive traces; the conductive trace may comprise a pattern of electrically conductive traces; the conductor arrangement of the composite structure may comprise a conductor pattern in the fiber panel comprising a conductive trace to provide the functional circuit. The functional circuit may comprise a sensor; the sensor may be configured to operate as a switch. The functional circuit may comprise at least one of a light, an LED light, a display, an illuminated feature. The functional circuit may comprise a user interface; the functional circuit may comprise an input device and/or an output device; the functional circuit may comprise an input device and an output device. The component may comprise a connector for the functional circuit; the functional circuit may be configured to be connected to a control system and/or a vehicle system and/or a network and/or a power source; the functional circuit may be configured to facilitate deployment of an airbag.

According to an exemplary embodiment shown schematically in FIGS. 1 through 98A-98B, a component may comprise a structural substrate; and a conductor arrangement coupled to the structural substrate; the structural substrate may be formed from a panel; the conductor arrangement may be configured to comprise a functional circuit; the panel may comprise a fiber panel; the functional circuit may comprise an electrical circuit. The conductor arrangement may comprise a circuit configured to be powered by a power source. The conductor arrangement may comprise a circuit configured to be connected to at least one vehicle system. The conductor arrangement may comprise a circuit configured to be connected to at least one network. The conductor arrangement may comprise a circuit configured to be connected to at least device. The conductor arrangement may comprise a circuit configured to operate a user interface system. The conductor arrangement may comprise a circuit on a circuit panel. The component may comprise a composite structure comprising the structural substrate and the conductor arrangement; the conductor arrangement may comprise a conductor pattern; the fiber panel may be comprised at least partially of fibers; the electrical conductor arrangement may be provided on the fiber panel; the fiber panel may be comprised at least partially of fibers; the electrical conductor arrangement may be provided in the fiber panel; the fiber panel may be comprised at least partially of fibers; the electrical conductor arrangement may be provided within the fiber panel; the electrical conductor arrangement may be pressed into a surface of the panel during a compression forming process; the structural substrate may comprise a feature molded on the panel; the structural substrate may comprise an ancillary component molded at the conductor arrangement; the structural substrate may comprise at least one of (a) a compression-formed component; (b) a generally rigid fiber mat.

According to an exemplary embodiment shown schematically in FIGS. 1 through 98A-98B, a process for producing a component for a vehicle interior and the component may be provided. The component for a vehicle interior produced in a mold comprising a first surface and a second surface by a process comprising placing a pre-form substrate onto the first surface of the mold; forming a compression-formed structure from the pre-form substrate by compressing the pre-form substrate between the first surface of the mold and the second surface of the mold; applying a cover to the compression-formed structure to form a panel assembly providing a surface effect; the pre-form substrate may comprise an electrical conductor arrangement. The pre-form substrate may comprise a fiber panel; the electrical conductor arrangement may be formed into the fiber panel; the pre-form substrate may comprise a fiber panel; the electrical conductor arrangement may be formed onto the fiber panel; the pre-form substrate may comprise a fiber panel; the electrical conductor arrangement may be within the fiber panel; the pre-form substrate may comprise a fiber panel; the electrical conductor arrangement may be stitched into the fiber panel; the pre-form substrate may comprise a fiber panel; the electrical conductor arrangement may be sewn to the fiber panel. The compression-formed structure may comprise a substrate layer and the electrical conductor arrangement. The step of forming the compression-formed structure may comprise forming the substrate layer into a generally rigid form; the step of forming the compression-formed structure may comprise forming the electrical conductor arrangement and the pre-form substrate with a generally continuous surface. The panel assembly may comprise a composite structure with at least partially a shape of the compression-formed structure; the shape may comprise a contour provided by the first surface of the mold and a contour provided by the second surface of the mold; the pre-form substrate may comprise a resin; comprising the step of heating the pre-formed substrate; the pre-formed substrate may be compressed as the pre-formed substrate cools. The process may comprise the step of injecting resin into the mold after the compression-formed structure may be formed to form a feature on the panel assembly. The process may comprise the step of injecting resin into the mold after the compression-formed structure may be formed to form an ancillary component of the panel assembly.

According to an exemplary embodiment shown schematically in FIGS. 1 through 98A-98B, a component may comprise a composite structure comprising (a) a structural substrate formed from a fiber panel; (b) a cover for the structural substrate providing an exterior surface; (c) a conductor arrangement configured to comprise a functional circuit; the structural substrate may comprise the conductor arrangement. The conductor arrangement may comprise a conductor pattern; the conductor pattern may comprise an electrical conductor arrangement; the conductor pattern may be provided on the fiber panel; the conductor pattern may be formed into the structural substrate so that the conductor pattern is not visible at the exterior surface of the cover; the conductor pattern may comprise a set of traces; the set of traces of the conductor pattern is provided at a surface of the fiber panel so that the structural substrate may comprise a generally flat surface for the cover; the set of traces of the conductor pattern is provided at a surface of the fiber panel so that the set of traces is not visible at the exterior surface of the cover of the composite surface; the set of traces of the conductor pattern may be pressed into a surface of the fiber panel so that the structural substrate may comprise a generally flat surface for the cover; the set of traces of the conductor pattern may be pressed into a surface of the fiber panel so that the set of traces is not visible at the exterior surface of the cover of the composite surface; the set of traces for the conductor pattern may comprise an upper set of traces and a lower set of traces; the conductor pattern may comprise a set of traces at least partially formed into the fiber panel of the structural substrate; the conductor pattern may comprise a network of traces in the fiber panel formed into the structural substrate. The component may comprise a feature on the structural substrate; the feature may comprise at least one of (a) a rib; (b) a set of ribs; (c) a reinforcement for the fiber panel; (d) a cover for the electrical conductor; (e) insulation for the electrical conductor; (f) shielding for the electrical conductor; (g) a housing for the electrical connector; (h) a cover for an electrical connector to the electrical conductor; (i) a connection point for the electrical conductor arrangement and a wire; (j) a resin-formed feature; (k) a resin-formed feature molded on the structural substrate. The composite structure may comprise a foam layer beneath the cover; the structural substrate may comprise a compression-formed fiber panel.

According to an exemplary embodiment shown schematically in FIGS. 1 through 98A-98B, a component may comprise a composite structure comprising (a) a structural substrate formed from a fiber panel; (b) a cover for the structural substrate providing an exterior surface; (c) a feature formed from resin on the structural substrate; the structural substrate may comprise an electrical conductor arrangement; the structural substrate may comprise a pattern of traces; the pattern of traces may comprise the electrical conductor arrangement under the exterior surface.

According to an exemplary embodiment shown schematically in FIGS. 1 through 98A-98B, a process of preparing a component for a vehicle interior and the component may be provided. The component for a vehicle interior may be prepared using a mold by a process comprising the steps of (a) providing a pre-form substrate; (b) joining an electrical conductor arrangement to the pre-form substrate; (c) disposing the pre-form substrate with the electrical conductor arrangement into the mold; and (d) compressing the pre-form substrate between the first surface of the mold and a second surface of the mold to form the pre-form substrate into a structural substrate having a shape; the shape may correspond to a shape of the first surface and a shape of the second surface; the shape may correspond to a first contour of the first surface and a second contour of the second surface. The step of joining an electrical conductor arrangement to the pre-form substrate may comprise sewing the electrical conductor arrangement to the pre-form substrate; the step of joining an electrical conductor arrangement to the pre-form substrate may comprise piercing an opening in the pre-form substrate and joining the electrical conductor arrangement to a conductor arrangement at the opening.

According to an exemplary embodiment shown schematically in FIGS. 1 through 98A-98B, a method of manufacturing a component for a vehicle interior and the component may be provided. The method of manufacturing a component for a vehicle interior may comprise the steps of (a) providing a pre-form substrate; (b) joining an electrical connector to the pre-form substrate; (c) disposing the pre-form substrate with the electrical conductor arrangement onto a first surface of the mold; and (d) compressing the pre-form substrate between the first surface and a second surface of the mold to form a structural substrate having a shape; the shape may correspond to a first contour of the first surface and a second contour of the second surface; the shape may correspond to a shape of the first surface and a shape of the second surface; the shape may correspond to a first shape of the first surface and a second shape of the second surface.

According to an exemplary embodiment shown schematically in FIGS. 1 through 98A-98B, a component may comprise a composite structure comprising a fiber panel and a cover; the fiber panel may comprise a conductor arrangement; the conductor arrangement may be configured to provide a functional circuit for the composite structure. The conductor arrangement may comprise conductive wire; the conductor arrangement may comprise conductive thread; the conductive thread may comprise a wire; the conductor arrangement may comprise electrically conductive conductors; the conductor arrangement may comprise a pattern of electrically conductive conductors; the conductor arrangement may comprise a set of electrically conductive threads; conductive thread may be within the fiber panel; conductive thread may be stitched within the fiber panel; conductive thread may be stitched into the fiber panel and/or stitched onto the fiber panel; the conductor arrangement may comprise a stitch pattern comprising conductive thread; the conductor arrangement may comprise a stitch pattern comprising the functional circuit; the functional circuit may comprise a user interface; the functional circuit may comprise an input device and/or an output device; the functional circuit may comprise a connection point; the composite structure may comprise a feature on the fiber panel; the feature may comprise a resin structure and/or a resin feature and/or a molded feature and/or a molded structure; the feature may comprise a rib; the feature may comprise a resin structure adjacent to the functional circuit; the fiber panel may comprise a stitch pattern comprising conductive thread; the fiber panel may comprise a stitch pattern comprising non-conductive thread.

According to an exemplary embodiment shown schematically in FIGS. 1 through 98A-98B, a component may comprise a composite structure comprising a fiber panel and a cover; the fiber panel may comprise a conductor arrangement; the conductor arrangement may comprise conductors configured to provide a functional circuit. The functional circuit may comprise circuit elements; the conductors may comprise conductive traces configured to provide a functional circuit; the conductors may comprise conductive leads configured to provide a functional circuit; the conductor arrangement may comprise conductive wires configured to provide a functional circuit; conductors comprise a pattern of electrically conductive threads; the composite structure may comprise a stitch pattern in the fiber panel comprising conductive thread to provide the functional circuit; the functional circuit may comprise a sensor configured to operate as an operator control and/or a switch; the functional circuit may comprise at least one of a light, an LED light, a display, an illuminated feature; the functional circuit may comprise a user interface; the functional circuit may comprise an input device; the input device may comprise a switch; the functional circuit may comprise an output device; the output device may comprise a display; the functional circuit may comprise an input device and an output device; the component may comprise a connector for the functional circuit; the component may comprise a stitch pattern; the stitch pattern may comprise a top stitch and a bottom stitch; the structural substrate may comprise a panel comprised at least partially of fibers; the conductor arrangement may be sewn to the panel; the conductor arrangement may be pressed into a surface of the panel during a compression forming process.

According to an exemplary embodiment shown schematically in FIGS. 1 through 98A-98B, a process of making a component for a vehicle interior and the component may be provided. The component may may be produced in a mold comprising a first surface and a second surface by a process comprising the steps of placing a pre-form substrate onto the first surface of the mold; forming a compression-formed structure from the pre-form substrate by compressing the pre-form substrate between the first surface of the mold and the second surface of the mold; applying a cover to the compression-formed structure to form a panel assembly providing a surface effect; the pre-form substrate may comprise an electrical conductor arrangement. The pre-form substrate may comprise a fiber panel; the electrical conductor arrangement may be sewn to the fiber panel; the compression-formed structure may comprise a substrate layer and the electrical conductor arrangement; the step of forming the compression-formed structure may comprise forming the substrate layer into a generally rigid form; the step of forming the compression-formed structure may comprise forming the electrical conductor arrangement and the pre-form substrate with a generally continuous surface. A generally smooth texture of the panel assembly may be provided by (a) a surface effect of the cover and (b) a surface effect of the pre-form substrate; (c) a surface effect at least partially concealing the electrical conductor arrangement. The panel assembly may comprise a composite structure with at least partially a shape of the compression-formed structure; the shape may comprise a shape provided by a surface of the mold; the pre-form substrate may comprise a resin; the process may comprise the step of heating the pre-formed substrate and the pre-formed substrate may be compressed as the pre-formed substrate cools. The process may comprise the step of injecting resin into the mold after the compression-formed structure may be formed to form an ancillary component of the panel assembly.

According to an exemplary embodiment shown schematically in FIGS. 1 through 98A-98B, a component may comprise a composite structure comprising: (a) a structural substrate formed from a fiber panel; (b) a cover for the structural substrate providing an exterior surface; the structural substrate may comprise a stitch pattern; the stitch pattern may comprise a set of threads; the stitch pattern may comprise an electrical conductor arrangement. The stitch pattern may be provided on the fiber panel; the stitch pattern may be formed into the structural substrate so that the stitch pattern is not visible at the exterior surface of the cover; the set of threads of the stitch pattern may be pressed into a surface of the fiber panel so that the structural substrate may comprise a generally flat surface for the cover; the set of threads of the stitch pattern may be pressed into a surface of the fiber panel so that the set of threads is not visible at the exterior surface of the cover of the composite surface; the stitch pattern may comprise a network of threads in the fiber panel formed into the structural substrate; the set of threads for the stitch pattern may comprise an upper set of threads and a lower set of threads. A feature formed on the fiber panel may comprise at least one of (a) a rib; (b) a set of ribs; (c) a reinforcement for the fiber panel; (d) a cover for the electrical conductor; (e) insulation for the electrical conductor; (f) shielding for the electrical conductor; (g) a housing for the electrical connector; (h) a cover for an electrical connector to the electrical conductor; (i) a connection point for the electrical conductor arrangement and a wire; (j) a resin-formed feature; (k) a resin-formed feature molded on the structural substrate. The composite structure may comprise a foam layer beneath the cover; the structural substrate may comprise a compression-formed fiber panel.

According to an exemplary embodiment shown schematically in FIGS. 1 through 98A-98B, a component may comprise a composite structure comprising (a) a structural substrate formed from a fiber panel; (b) a cover for the structural substrate providing an exterior surface; (c) a feature formed from resin on the structural substrate; the structural substrate may comprise an electrical conductor arrangement; the electrical conductor arrangement may be configured to comprise a functional circuit for the composite structure. The structural substrate may comprise a pattern of conductors; the pattern of conductors may comprise the electrical conductor arrangement.

According to an exemplary embodiment shown schematically in FIGS. 1 through 98A-98B, a component may comprise a fiber panel; and a structure comprising a resin; the fiber panel may comprise a compression-formed component; the compression-formed component may comprise an edge along a periphery and provides a structural substrate having a shape and a thickness along the edge; the structure may comprise a border of the structural substrate along the thickness of the structural substrate provided by the compression-formed component; the fiber panel may comprise a conductor arrangement; the conductor arrangement may be configured to provide a functional circuit.

According to an exemplary embodiment shown schematically in FIGS. 1 through 98A-98B, a component may comprise a fiber panel comprising a compression-formed component; and a structure formed from a molded resin; the structure may comprise at least one molded feature; the compression-formed component may comprise an edge along a periphery and provides a structural substrate having a shape and a thickness along the edge; the structure may comprise a border of the structural substrate along the thickness of the structural substrate provided by the compression-formed component; and the at least one molded feature may comprise a molded feature configured to support the fiber panel; the fiber panel may comprise a conductor arrangement; the conductor arrangement may be configured to provide a functional circuit.

According to an exemplary embodiment shown schematically in FIGS. 1 through 98A-98B, a component may comprise a structural substrate comprising a compression-formed fiber panel and a structure comprising a resin; the compression-formed fiber panel may comprise a thickness along a periphery; the structure may comprise a border of the structural substrate along the thickness of the periphery of the compression-formed fiber panel; the periphery of the fiber panel may comprise an edge; the structure may be formed on the edge; the fiber panel may comprise a conductor arrangement; the conductor arrangement may be configured to provide a functional circuit.

According to an exemplary embodiment shown schematically in FIGS. 1 through 98A-98B, a component may comprise a structural substrate comprising a fiber panel and a structure comprising a resin; the fiber panel may comprise a thickness along a periphery; the structure may comprise a border of the structural substrate along the thickness of the periphery of the fiber panel; the periphery of the fiber panel may comprise an edge; the structure may be formed on the edge; the fiber panel may comprise a conductor arrangement; the conductor arrangement may be configured to provide a functional circuit.

According to an exemplary embodiment shown schematically in FIGS. 1 through 98A-98B, a component may comprise a fiber panel; a structure comprising a resin; and a cover coupled to at least one of (a) the fiber panel, (b) the structure; the fiber panel may comprise a compression formed component; the compression formed component may comprise an edge along a periphery and provides a structural substrate having a shape and a thickness along the edge; the structure may comprise a border of the structural substrate along the thickness of the structural substrate provided by the compression formed component; the fiber panel may comprise a conductor arrangement; the conductor arrangement may be configured to provide a functional circuit.

### Exemplary Embodiments—C

According to an exemplary embodiment as shown schematically in FIGS. 1 through 98A-98B, a component for a vehicle interior may comprise a composite structure comprising a substrate comprising a fiber panel; the fiber panel may comprise a conductor arrangement; the conductor arrangement may be configured to provide a functional circuit for the composite structure. The substrate of the composite structure may comprise a structural substrate; the fiber panel may comprise a compression-formed fiber panel. The composite structure may comprise a functional element comprising the conductor arrangement; the functional element may comprise an insert and/or mat and/or a fabric and/or a woven material and/or a formed material and/or a resin material; the conductor arrangement and/or functional circuit may be configured to comprise at least one of: a conductor; a sensor/detector; an input device; an output device; an interactive device; a display; a switch; a light/lighting; a light element; a light guide. The conductor arrangement and/or functional circuit may be configured to comprise at least one of: a light/lighting; a light element; a light guide; an LED; LED lighting; a display; a display panel; an antenna; a camera; a video-recorder; an image display/device; a user interface; an input device; an output device; an input/output device; a sensor; a detector; a switch; a touch sensor; an odor/scent detector; a microphone; a sound detector; a wireless charging device; a wireless connection area; a heating element; an electrified area; other device/technology. The composite structure may comprise a base; the base may comprise a structural substrate; the fiber panel may comprise a compression-formed fiber panel. The vehicle interior component may comprise a composite structure comprising a substrate such as a fiber panel and a cover and a functional element/layer comprising a conductor arrangement and/or functional circuit. The functional element may comprise an insert/layer and/or the conductor arrangement; the functional element may be configured to comprise a functional circuit; the conductor arrangement may be configured to provide a functional circuit. The composite structure may comprise a functional element comprising the conductor arrangement; the functional element may comprise an insert and/or mat and/or a layer and/or a fabric and/or a woven material and/or a formed material and/or a resin material.

As indicated schematically according to an exemplary embodiment in the FIGURES, the composite structure with conductor arrangement is configured to be substantially functionally effective; the conductor arrangement and/or functional circuit is configured to be substantially functionally effective. As indicated schematically according to an exemplary embodiment, the composite structure is configured so that the conductor arrangement and/or the functional element is substantially visually imperceptible under the cover; the conductor arrangement is configured to be substantially visually imperceptible under the cover; the functional element is configured to be substantially visually imperceptible under the cover.

As indicated schematically according to an exemplary embodiment in the FIGURES, the component may comprise a trim panel, an instrument panel, a door panel, an overhead panel, a console, an overhead console, a floor console, an armrest, an interior trim component, pillar trim, an operator control, a steering control, a steering wheel, etc.

### Exemplary Embodiments—D

As shown schematically according to an exemplary embodiment in FIGS. 1 through 98A-98B, a vehicle interior component may comprise a composite structure comprising a substrate such as a structural substrate comprising a fiber panel and a functional element/layer (such as an insert, mat, conductors, traces, wires, circuit elements, etc.) comprising a conductor arrangement and/or functional circuit. The component may comprise a composite structure comprising a substrate such as a fiber panel and a cover and a functional element comprising a conductor arrangement and/or functional circuit; the functional element may comprise an insert/layer; the functional element may comprise a conductor arrangement; the functional element may be configured to comprise a functional circuit; the conductor arrangement may be configured to provide a functional circuit. The composite structure may comprise a structural substrate; the composite structure may comprise a functional element comprising the conductor arrangement; the functional element may comprise an insert and/or mat and/or a layer and/or a fabric and/or a woven material and/or a formed material and/or a resin material, The conductor arrangement and/or functional circuit may be configured to comprise at least one of: a conductor; a sensor/detector; an input device; an output device; an interactive device; a display; a switch; a light/lighting; a light element; a light guide. The functional element/layer (such as an insert, mat, etc.) may be configured to comprise at least one of: a light/lighting; a light element; a light guide; an LED; LED lighting; a display; a display panel; an antenna; a camera; a video-recorder; an image display/device; a user interface; an input device; an output device; an input/output device; a sensor; a detector; a switch; a touch sensor; an odor/scent detector; a microphone; a sound detector; a wireless charging device; a wireless connection area; a heating element; an electrified area; other device/technology. As indicated schematically in the FIGURES, for the component, the conductor arrangement and/or functional element/layer is configured to be substantially functionally effective; as indicated schematically, the conductor arrangement and/or functional element/layer is configured to be substantially visually imperceptible under the cover. The component may comprise a trim panel, an instrument panel, a door panel, an overhead panel, a console, an overhead console, a floor console, an armrest, an interior trim component, pillar trim, an operator control, a steering control, a steering wheel, etc.

According to an exemplary embodiment as indicated schematically in FIGS. 1 through 98A-98B, a component for a vehicle interior may comprise a composite structure comprising a substrate and a cover; the substrate may comprise a conductor arrangement; the conductor arrangement may be configured to comprise a functional circuit; the substrate may be formed from a fiber panel.

According to an exemplary embodiment as indicated schematically in FIGS. 1 through 98A-98B, a component for a vehicle interior may comprise a composite structure comprising a substrate comprising a fiber panel and a conductor arrangement coupled to the structural substrate; the structural substrate may be formed from a panel; the conductor arrangement may be configured to comprise a functional circuit; the panel may comprise a fiber panel; the functional circuit may comprise an electrical circuit.

According to an exemplary embodiment as indicated schematically in FIGS. 1 through 98A-98B, a component for a vehicle interior may comprise a composite structure comprising a substrate comprising a fiber panel and a cover; the fiber panel may comprise a conductor arrangement; the conductor arrangement may comprise conductors configured to provide a functional circuit.

According to an exemplary embodiment as indicated schematically in FIGS. 1 through 98A-98B, a component for a vehicle interior may comprise a composite structure comprising a substrate and an electrical conductor arrangement coupled to the structural substrate; the structural substrate may comprise a fiber panel.

According to an exemplary embodiment as indicated schematically in FIGS. 1 through 98A-98B, a component for a vehicle interior may comprise a composite structure comprising a structural substrate formed from a fiber panel and a cover for the structural substrate providing an exterior surface; a feature formed from resin may be provided on the structural substrate; the structural substrate may comprise an electrical conductor arrangement.

According to an exemplary embodiment as indicated schematically in FIGS. 1 through 98A-98B, a trim component for a vehicle interior may comprise a fiber panel and a structure comprising a resin; the fiber panel may comprise a compression-formed component; the compression-formed component may comprise an edge along a periphery and provides a structural substrate having a shape and a thickness along the edge; the structure may comprise a border of the structural substrate along the thickness of the structural substrate provided by the compression-formed component; the fiber panel may comprise a conductor arrangement; the conductor arrangement may be configured to provide a functional circuit.

According to an exemplary embodiment as indicated schematically in FIGS. 1 through 98A-98B, a trim component for a vehicle interior may comprise a fiber panel comprising a compression-formed component and a structure formed from a molded resin; the structure may comprise at least one molded feature; the compression-formed component may comprise an edge along a periphery and provides a structural substrate having a shape and a thickness along the edge; the structure may comprise a border of the structural substrate along the thickness of the structural substrate provided by the compression-formed component; and the at least one molded feature may comprise a molded feature configured to support the fiber panel; the fiber panel may comprise a conductor arrangement; the conductor arrangement may be configured to provide a functional circuit.

According to an exemplary embodiment as indicated schematically in FIGS. 1 through 98A-98B, a trim component for a vehicle interior may comprise a structural substrate comprising a compression-formed fiber panel and a structure comprising a resin; the compression-formed fiber panel may comprise a thickness along a periphery; the structure may comprise a border of the structural substrate along the thickness of the periphery of the compression-formed fiber panel; the periphery of the fiber panel may comprise an edge; the structure may be formed on the edge; the fiber panel may comprise a conductor arrangement; the conductor arrangement may be configured to provide a functional circuit.

According to an exemplary embodiment as indicated schematically in FIGS. 1 through 98A-98B, a component for a vehicle interior may comprise a structural substrate comprising a fiber panel and a structure comprising a resin; the fiber panel may comprise a thickness along a periphery; the structure may comprise a border of the structural substrate along the thickness of the periphery of the fiber panel; the periphery of the fiber panel may comprise an edge; the structure is formed on the edge; the fiber panel may comprise a conductor arrangement; the conductor arrangement may be configured to provide a functional circuit.

According to an exemplary embodiment as indicated schematically in FIGS. 1 through 98A-98B, a trim component for a vehicle interior may comprise a fiber panel and a structure comprising a resin and a cover coupled to at least one of the fiber panel or the structure; the fiber panel may comprise a compression formed component; the compression formed component may comprise an edge along a periphery and provides a structural substrate having a shape and a thickness along the edge; the structure may comprise a border of the structural substrate along the thickness of the structural substrate provided by the compression formed component; the fiber panel may comprise a conductor arrangement; the conductor arrangement may be configured to provide a functional circuit.

According to an exemplary embodiment as indicated schematically in FIGS. 1 through 98A-98B, a component for a vehicle interior may comprise a composite structure comprising a substrate comprising a fiber panel and a functional element and a cover; the functional element may be configured to comprise a functional circuit; the fiber panel may comprise a compression formed fiber panel configured to support the functional element; the functional element may comprise a functional layer.

According to an exemplary embodiment as shown schematically in the FIGURES, a method of manufacturing a component for a vehicle interior may comprise the steps of: (a) providing a pre-form substrate; (b) providing an electrical connector arrangement to the pre-form substrate; (c) providing the pre-form substrate with the electrical conductor onto a first surface of the mold; and (d) compressing the pre-form substrate between the first surface and a second surface of the mold to form a structural substrate having a shape. The shape may correspond to a first contour of the first surface and a second contour of the second surface; the electrical connector arrangement is configured to comprise a functional circuit for the structural substrate.

### Exemplary Embodiments—E

Referring to the FIGS. 1A-1C, 2, 2A-2H, 61, 62 and 63, a vehicle Vis shown schematically with an interior I comprising components such as trim components, panels, consoles, etc. As indicated schematically according to an exemplary embodiment in the FIGURES, the vehicle interior may comprise a component such as a trim panel shown as instrument panel IP configured to provide a door such as an airbag door ABD to facilitate deployment of an airbag AB.

Referring to the FIGURES, a vehicle V is shown with an interior I comprising components C including trim components such as an instrument panel IP, door panel DP, pillar PL, floor console FC, overhead panel OHP, operator control shown as steering wheel assembly SW, and seating shown as seats SZ and other vehicle components such as overhead panel/system OHP, trunk NTR, frunk NTF, visor/vanity panel VN, storage shown as glove box GB, floor console FC, etc.; interior I may comprise safety systems such as an airbag module ABM and/or horn/alerting device within components such as instrument panel IP and steering wheel assembly SW and components/devices comprising functional circuits connected to vehicle systems, networks, etc. See FIGS. 2, 2A-2H, 3, 4, 5, 6, 7, 8, 9, 10, 11, 12, 13, 14, 15, 16 and 17A-17B.

As shown schematically according to an exemplary embodiment in the FIGURES, the component may comprise a composite structure CS comprising substrate such as a fiber panel FP/PN formed with a feature such as reinforcement RB and with a functional circuit FR with a connection point FP and an electrical conductor arrangement comprising a conductor CD/CR such as a wire WR and/or a conductive stitch/stitch pattern ST.

As shown schematically according to an exemplary embodiment in the FIGURES, a vehicle interior may comprise systems/devices configured to provide functional systems/circuits FR and configured to be integrated with components C; as indicated schematically according to an exemplary embodiment, devices/systems provided by functional circuits FR and/or circuit elements CR may be configured and/or combined with components C to provide features/functionality such as a user interface UI (e.g. input device and/or output device), user interface system UIS, illumination such as light LT (provided through a display panel, lamp, etc.) and light guide LG, LED arrangement LED, image display/device ID, sensor/detector arrangements such as a system to generate a sensor field/antenna SF in a field/detection space/area FL or a sensor/detector SN or sensor configured to operate as an input device/switch SH or sensor configured to operate as an occupancy detector OC or ultraviolet sensor UV, odor/scent detector OD, microphone/sound detector MR, camera/video-recorder CM, accelerometer AX, antenna NT, wireless charging/connection area/surface CW (e.g. for mobile devices, etc.), heating element HT, etc. As indicated schematically according to an exemplary embodiment in the FIGURES, the devices/systems provided by functional circuits FR and/or circuit elements CR configured and/or combined with components C to provide features/functionality may be operated by a control system CS and power source PS and connected to vehicle systems VS and/or data sources/networks DS (including the internet, local networks, proprietary networks, etc.); connection may be provided at a connection point such as a plug/connector CP; features/functionality may comprise any of a variety of arrangements within the vehicle interior, including user interface arrangements UI, input/output systems, display panels DL, occupant controls such as switches/buttons SH, entertainment, lighting such as light LT, HVAC/temperature comfort (heating, cooling, etc.), data communications such as at image display ID, monitoring such as by sensors SN, safety systems/detection such as for airbag modules ABM or other vehicle/safety systems, alert/warning systems, occupant interaction/monitoring, interaction/connection with mobile devices MD or other objects OB, etc.

As indicated schematically according to an exemplary embodiment in the FIGURES, the devices/systems provided by functional circuits FR and/or circuit elements CR configured and/or combined with components C to provide features/functionality may be provided in a composite structure comprising a panel shown as fiber panel FP and a cover T; component C may comprise the composite structure of panel and cover on or with a base/substrate B/SB; the fiber panel FP may comprise a conductor CD; the conductor may provide the functional circuit FR for the composite structure. As indicated schematically according to an exemplary embodiment in the FIGURES, the systems/devices provided by functional circuit FR may be configured to provide a wide variety of features/functions and to integrate/connect with conventional systems/devices for a vehicle interior.

As indicated schematically according to an exemplary embodiment in the FIGURES, the component C may comprise an overhead system/panel assembly OHP comprising a base B/SB and a fiber panel FP with an arrangement of conductors CD for functional circuits FR such as lighting LT, sensors/switches SN, etc. connected to vehicle systems at connection points CP; the composite structure of the overhead system/panel OHP/C may comprise structural elements such as ribs RB formed on/for the fiber panel FP; the overhead system/panel OHP/C may be configured to facilitate formation of a moon/sun roof. As indicated schematically according to an exemplary embodiment in the FIGURES, the component C may comprise any of a variety of interior components comprising in any of a variety of forms a composite structure with a cover T and a fiber panel FP with an arrangement of conductors CD for a variety of functional circuits FR such as lighting LT, sensors/switches SN, etc.; as indicated schematically, the composite structure may comprise other structures such as reinforcement/rigidifying elements shown as molded/resin ribs, etc. for the fiber panel comprising the functional circuit.

As indicated schematically according to an exemplary embodiment in the FIGURES, the systems/devices provided by functional circuit FR for component C may be configured to integrate/connect with the composite structure comprising fiber panel FP.

As indicated schematically in the FIGURES, the functional circuit FR with circuit elements CR such as sensor elements SN, lighting elements LG/LT, etc. may be formed with and/or on the fiber panel FP of the composite structure; as indicated schematically, the component with composite structure may comprise a base/substrate B/SB; as indicated schematically, the composite structure may comprise an intermediate layer such as shown by foam layer FM; as indicated schematically, the composite structure may comprise an intermediate layer/panel NL/PN such as insulation layer/panel such as shown by layer; as indicated schematically, the composite structure may comprise a conductor arrangement with conductors CD/CR and/or conductive stich ST and/or a non-conductive stitch. As indicated schematically, the composite structure may comprise a fiber panel FP with a functional circuit FR comprising a user interface UI and other functionality and/or lighting arrangement comprising light guide LG. See also TABLE A.

As indicated schematically according to an exemplary embodiment, the systems/devices provided by functional circuit FR for component C may be configured to be formed with and within the composite structure comprising fiber panel FP; the conductor CD for functional circuit FR may comprise a pattern of electrically conductive threads CS; conductive thread may comprise a stitch arrangement ST shown as a stitch pattern SP within the fiber panel FP; conductive thread may be stitched into/onto the fiber panel. As indicated schematically, the conductor CD may comprise a stitch pattern SP comprising conductive thread CS comprising the functional circuit FR. As indicated schematically, the composite structure may comprise a structure shown as resin structure RB for the fiber panel FP; the resin structure RB may be formed on the fiber panel FP at or adjacent to the functional circuit FR. As indicated schematically in the FIGURES, the component C with composite structure may comprise a fiber panel FP configured to provide an arrangement of conductors CD shown as conductive threads CR/ST for functional circuit FR or circuit element CR and/or an arrangement of non-conductive threads such as for reinforcement of a hinge HG for an airbag door ABD or for a decorative feature, etc. As indicated schematically, a stitch pattern SP comprising a conductive thread CR/ST and/or a non-conductive thread and/or light guide thread LG may be provided in fiber panel FP by the stitch of a needle N from an apparatus shown as sewing machine MW (e.g. to stitch on, emboss, stitch in, etc. the fiber panel).

As indicated schematically according to an exemplary embodiment in the FIGURES, the systems/devices provided by functional circuit/element FR/FT for component C may be configured with and within the composite structure comprising fiber panel FP as or with a variety of circuit elements CR including with conductors CD of conductive thread CS provided in a stitch pattern SP and cables/wires CW and with connection points CN and insulation/layer NL and connector/pad PC and light arrangement LT with light guide LG and/or LED elements and sensor/switch SN and sensor/detector arrangement SN and antenna NT and etc. As indicated schematically, the functional circuit FR/FT and/or circuit elements CR provided with the fiber panel FP of the composite structure of the component C may be designed/configured to provide a wide variety of features/functions and systems/devices within the vehicle interior. See also FIGS. 2, 2A-2H, 3, 4, 5, 6, 7, 8, 9, 10, 11, 12, 13, 14, 15, 16, 17A-17B, 61, 62 and 63.

As indicated schematically, the functional circuit/element FR/FT of the fiber panel FP of the composite structure CS may be configured to be formed and to integrate within the component and with other features/systems such as an airbag module ABM configured to deploy an airbag AB through an opening formed by an airbag door ABD at a tear line/seam TR in the component C; as indicated schematically, the functional circuit FR may be on the tear line/seam TR to facilitate deployment of the airbag AB; as indicated schematically, the functional circuit FR is adjacent to the tear line/seam TR or recess RC to facilitate deployment of the airbag AB at the airbag door ABD. As indicated schematically in the FIGURES, the functional circuit FR may comprise a sensor SN/NT configured to detect the presence/touch of an occupant and provide a signal to a vehicle system such as a safety system SRS shown as comprising an airbag module ABM; as indicated schematically, the functional circuit FR of the component C may be integrated with other systems of the component such as the airbag module ABM. See also TABLE A.

Referring to FIGS. 1A-1C and 2, a vehicle V is shown including an interior I with vehicle interior components shown as an instrument panel IP, doors DP and a floor console FC. According to an exemplary embodiment, components of vehicle V such as instrument panel IP and doors DP may include trim components/panels comprised of fiber and plastic. According to an exemplary embodiment, instrument panel IP and doors DP may provide visible surfaces in the vehicle interior of vehicle V. According to an exemplary embodiment, vehicle interior/trim components such as instrument panel IP and/or doors DP may provide at least one airbag behind the visible surfaces; instrument panel IP and/or doors DP may provide a weakened area to aid the airbag in breaking through the trim component/panel during airbag deployment. As shown schematically, a component such as instrument panel IP may provide a weakened shape/zone shown as a recess RC (e.g. a line, score line, cut, notch, groove, discontinuity, interruption, etc.) to facilitate an airbag AB deployment through an airbag door ABD. According to an exemplary embodiment, the weakened shape/zone may comprise at least one of a recess or a score line behind the visible surface of instrument panel IP; as shown schematically, the weakened shape/zone may comprise an “H” shape pattern (e.g. corresponding to a door, double-door, etc. for the airbag to comprise the airbag door in the panel).

According to an exemplary embodiment, top stitch TS may comprise a thread weight and bottom stitch BS may comprise a thread weight; the thread weight of top stitch TS may be generally greater than the thread weight of bottom stitch BS; for example, top stitch TS may comprise 210 Tex thread; bottom stitch BS may comprise 70 Tex thread. As indicated schematically, bottom stitch BS may be configured to separate upon deployment of the airbag to facilitate deployment of the airbag from the airbag module through the opening; top stitch TS may be configured to secure the door to structural substrate SB upon deployment of the airbag. Top stitch TS may be configured to stretch upon deployment of the airbag to secure the door to structural substrate SB. Reinforcement MN may be comprised of bonded nylon thread and/or thread material of at least one of (a) KEVLAR, (b) aramid, (c) nylon, (d) polyester, (e) thread, (f) ceramic fibers, (g) polymeric fibers, (h) synthetic fibers.

As shown schematically according to an exemplary embodiment in the FIGURES, the structural substrate SB of the composite structure CS of the component C may comprise a panel PN/FP comprised at least partially of fibers; structure/reinforcement RB may be a formed feature on the fiber panel FP of the composite structure CS.

According to an exemplary embodiment as shown schematically in FIGS. 2A-2C, 3A-3F, 4A-4F, 5A-5C, 6A-6C, 7A-7F, 8A-8E, 9A-9C, 10A-10D, 11A-11B and 12, a vehicle interior component C may be produced in a mold M comprising a first surface and a second surface by a process comprising: placing a pre-form substrate SB onto the first surface of the mold, forming a compression-formed structure/structural substrate SB from pre-form substrate SB by compressing pre-form substrate SB between the first surface of the mold and the second surface of the mold, and applying a cover T to the compression-formed structure SB to form a panel assembly SB providing a surface effect.

As indicated schematically, the pre-form panel or substrate FP/SB for the composite structure for the component may comprise a reinforced pre-form substrate (e.g. with reinforcement by thread/stitch pattern, webs, strands, links, etc.); as shown schematically, the compression-formed structure FP may comprise a substrate layer and reinforcement/structure RB. The reinforced pre-form substrate/panel may comprise a surface effect comprising a generally smooth texture; the surface effect of the panel assembly may generally comprise the surface effect of the reinforced pre-from substrate; the step of forming the compression-formed structure may comprise forming reinforcement and the pre-form substrate into a generally continuous surface. The substrate layer for the pre-form substrate may comprise a fiber mat; the substrate layer may comprise a generally rigid fiber mat; the step of forming the compression-formed structure may comprise forming the substrate layer into a generally rigid form; the surface effect of the panel assembly may comprise the generally rigid form of the substrate layer of the compression-formed structure. According to an exemplary embodiment, cover T of the panel assembly may comprise at least one of (a) leather; (b) synthetic leather; (c) imitation leather; (d) a composite of a plastic layer and textile backing; (e) a coated fabric; (f) polyvinylchloride coated fabric; (g) a woven fabric; (h) a non-woven fabric; (i) an applique; (j) vinyl; (k) a foil. As indicate schematically, the compression-formed structure shown as panel PN/FP for the composite structure CS may comprise a shape; the panel assembly may comprise at least partially the shape of the compression-formed structure; the shape may comprise a shape provided by the first surface of the mold and a shape provided by the second surface of the mold; the conductor arrangement CD/CR and/or functional circuit/element FT/FR may comprise the shape or shapes of the substrate/panel FP/PN of the composite structure CS. As indicated schematically, the substrate layer for the pre-form substrate may comprise a fiber mat; the process may comprise the step of forming the pre-form substrate from a generally compressible fiber mat. According to an exemplary embodiment, the pre-form substrate may comprise natural fibers and a resin; the resin may comprise polypropylene; the natural fibers may comprise at least one of (a) flax; (b) kenaf. According to an exemplary embodiment, the pre-form substrate may comprise an area weight of between 1000 grams per square meter and 1800 grams per square meter; the pre-form substrate may comprise a thickness of between 1.5 mm and 4 mm; the compression-formed structure may comprise a thickness of between 0.8 mm and 3 mm. The process may comprise the step of heating the pre-formed substrate; the pre-formed substrate may be compressed as the pre-formed substrate cools; the process may comprise the step of injecting resin into the mold after the compression-formed structure is formed to form a feature such as a structure, rib, reinforcement, border, ancillary component, etc. of the composite structure and/or panel assembly; structural substrate SB may comprise a compression-formed component from the fiber panel FP; structural substrate SB may comprise a generally rigid fiber mat. According to an exemplary embodiment, cover T may comprise at least one of (a) leather; (b) synthetic leather; (c) imitation leather; (d) a composite of a plastic layer and textile backing; (e) a coated fabric; (f) polyvinylchloride coated fabric; (g) a woven fabric; (h) a non-woven fabric; (i) an applique; (j) vinyl; (k) a foil; (1) coating on structural substrate SB; (m) paint on structural substrate SB; (n) the exterior surface of structural substrate SB. According to an exemplary embodiment, the component may comprise at least one of an instrument panel; a door panel; a trim panel; a trim component, etc.

According to an exemplary embodiment as shown schematically in the FIGURES, a trim component for a vehicle interior comprising a composite structure CS may be prepared using a mold by a process comprising the steps of: providing a pre-form substrate, joining a reinforcement RB to the pre-form substrate in at least one hinge area to form a reinforced pre-form substrate, disposing the reinforced pre-form substrate onto a first surface of the mold, and compressing the reinforced pre-form substrate between the first surface and a second surface of the mold to form the reinforced pre-form substrate into a structural substrate SB having a shape.

According to an exemplary embodiment as shown schematically in FIG. 11A, a method of manufacturing a vehicle trim component C may comprise the steps of providing a substrate layer (e.g. fiber mat, etc.) as a base for a pre-form substrate, forming the pre-form substrate (e.g. consolidating, compressing, merging/fusing, heating/melting, shaping, cutting/sizing, etc.), joining a reinforcement to the pre-form substrate, pre-treating/heating the reinforced pre-form substrate, forming a structural substrate (e.g. compressing/molding the reinforced pre-form substrate), applying a cover to the structural substrate and finishing/providing a panel assembly (with the cover on the structure/substrate).

According to an exemplary embodiment as shown schematically, a method of manufacturing a vehicle trim component C may comprise the steps of providing a substrate layer (e.g. fiber mat, etc.) as a base for a pre-form substrate, forming the pre-form substrate (e.g. consolidating, compressing, merging/fusing, heating/melting, shaping, cutting/sizing, etc.), joining a reinforcement to the pre-form substrate, pre-treating/heating the reinforced pre-form substrate, forming a structural substrate (e.g. compressing/molding the reinforced pre-form substrate), joining/forming an feature to/on the structural substrate, applying a cover to the structural substrate and finishing/providing a panel assembly (with the cover on the structure/substrate).

According to an exemplary embodiment as shown schematically in FIG. 12, a method of manufacturing a vehicle trim component C may comprise the steps of providing a pre-form substrate, piercing an opening in the pre-form substrate and joining a top stitch to a bottom stitch at the opening, pre-treating/heating the pre-form substrate with the top and the bottom stitch, compressing/molding/forming the pre-form substrate and pressing the top stitch and the bottom stitch into the pre-form substrate to form a structural substrate, applying a cover to the structural substrate, and finishing/providing a panel assembly (with the cover on the structure/substrate).

### Exemplary Embodiments—F

According to an exemplary embodiment as shown schematically in the FIGURES, a fiber mat FPu may comprise a combination of fibers (e.g. natural and/or synthetic fibers) and thermoplastic resin (e.g. polypropylene (PP), acrylonitrile butadiene styrene (ABS), polycarbonate (PC), etc.). According to an exemplary embodiment as shown schematically in the FIGURES, fiber mat FPu may be trimmed into a fiber mat having a thickness. According to an exemplary embodiment, fiber mat may be heated to induce the thermoplastic resin to liquefy. According to an exemplary embodiment as shown schematically, heated fiber mat may be partially compressed into a fiber panel FP/FPc having a thickness less than the thickness of fiber mat FPu. According to an exemplary embodiment as shown schematically, a formed feature such as reinforcement/structure RB may be provided on fiber panel FP to form reinforced fiber panel for the composite structure CS.

According to an exemplary embodiment as shown schematically, fiber panel FP may be heated in an oven OV; fiber panel FP may be transferred into a mold tool MT/MB having a mold top and mold bottom; as shown schematically, a component shown as an instrument panel substrate may be produced by a process of compression forming heated fiber panel FP into a structural substrate SB and injection molding resin as a feature RB onto compression formed fiber panel FP. A recess RC of structural substrate SB may be formed in the process. According to an exemplary embodiment as shown schematically, composite structure comprising the panel may provide a feature shown as a resin/plastic rib/structure RB on a back side of structural substrate SB/FP to improve structural integrity and rigidity; plastic/resin feature such as rib RB may comprise a reinforcement to provide structural support; feature RB may comprise a border to provide reinforcement and/or dimensional accuracy for structural substrate SB/FP. According to an exemplary embodiment, feature RB may be placed at any location on structural substrate SB/FP (e.g. along an edge of structural substrate SB, in the middle of structural substrate SB, etc.). According to an exemplary embodiment, multiple plastic ribs RB may be placed at various different locations on structural substrate SB. According to an exemplary embodiment, feature RB may improve structural integrity of the instrument panel substrate. According to an exemplary embodiment, the panel/substrate may be able to maintain structural integrity during use (e.g. such as an airbag deployment); the position/placement of feature RB may be intended to create a strength differential between different areas of the instrument panel substrate; energy needed for an airbag to break through a vehicle interior component C may be directed to recess RC of structural substrate SB; plastic rib RB may prevent or minimize ripping or tearing of structural substrate SB at any location other than at recess RC during an airbag deployment. According to an exemplary embodiment as shown schematically, feature RB may form a honeycomb shaped pattern structure to improve structural integrity and rigidity. According to an exemplary embodiment, feature RB may be formed in any configuration according to a specific application (e.g. ancillary features for attaching air vents, speakers or infotainment system, etc.) and/or for a structure/reinforcement such as a housing/module or connection point for a functional circuit FR with conductor arrangement CD/CR for the composite structure CS.

Structural substrate SB/FP may comprise a compression-formed component. Compression-formed component SB may comprise a recess RC in the back side of structural substrate SB configured to establish the opening so that airbag AB will deploy through compression-formed component SB at the opening. Structural substrate SB may be formed at least partially from fibers. Trim component C may comprise a cover T to provide a surface on the front side of structural substrate SB. Contact between airbag AB and the door may induce tearing of cover T to establish the opening for the airbag and may facilitate deployment of airbag AB through the opening.

### Exemplary Embodiments—G

Referring to the FIGURES, a vehicle V is shown including an interior I with vehicle interior components shown as trim components such as an instrument panel IP, doors DP and a floor console FC; according to an exemplary embodiment, components of vehicle V such as instrument panel IP and doors DP may include trim components/panels comprised of fiber and plastic. According to an exemplary embodiment as shown schematically, trim components such as instrument panel IP and doors may provide visible surfaces in the vehicle interior of vehicle V. According to an exemplary embodiment as shown schematically, a fiber mat FPu may comprise a combination of fibers (e.g. natural and/or synthetic fibers) and thermoplastic resin (e.g. polypropylene (PP), acrylonitrile butadiene styrene (ABS), polycarbonate (PC), etc.). According to an exemplary embodiment as shown schematically, fiber mat FPu may be trimmed into a fiber mat having a thickness. According to an exemplary embodiment, fiber mat may be heated to induce the thermoplastic resin to liquefy. According to an exemplary embodiment as shown schematically, heated fiber mat may be partially compressed into a fiber panel FPc having a thickness less than the thickness of fiber mat FPu. According to an exemplary embodiment as shown schematically, a method of manufacturing a vehicle trim component C may comprise the steps of providing a fiber panel FP, optionally joining a reinforcement RB to fiber panel FP; reinforced fiber panel onto a first surface of a mold M, compressing reinforced fiber panel FP between a first surface and a second surface of the mold to form reinforced fiber panel FP into a structural substrate FP/SB having a shape and optionally attaching a structure on a side of the structural substrate. The shape may correspond to a first contour of the first surface and a second contour of the second surface. Structural substrate may be configured to provide at least one panel/door; reinforcement RB. According to an exemplary embodiment, a weakened shape/zone on the composite structure may comprise a “U” shape pattern, a “bow tie” shape pattern, or any pattern suitable for airbag deployment.

According to an exemplary embodiment as shown schematically, the instrument panel substrate may provide a feature shown as a plastic structure/rib RB on a back side of structural substrate SB to improve structural integrity and rigidity of structural substrate SB. Resin feature RB may comprise a reinforcement to provide structural support. Resin feature RB may comprise a border to provide reinforcement and/or dimensional accuracy for structural substrate SB. According to an exemplary embodiment, resin feature RB may be placed at any location on structural substrate SB (e.g. along an edge of structural substrate SB, in the middle of structural substrate SB, etc.). According to an exemplary embodiment, multiple resin features RB may be placed at various different locations on structural substrate SB. According to an exemplary embodiment, resin feature RB may improve structural integrity of the instrument panel substrate. According to an exemplary embodiment as shown schematically, resin feature RB may form a honeycomb shaped pattern to improve structural integrity and rigidity. According to an exemplary embodiment, resin feature RB may be formed in any configuration according to a specific application (e.g. ancillary features for attaching air vents, speakers or infotainment system, etc.).

According to an exemplary embodiment as shown schematically, a component for a vehicle interior providing a hinged panel may comprise a composite structure comprising a structural substrate formed from a fiber panel and a cover for the structural substrate providing an exterior surface. The structural substrate may comprise a conductor arrangement/pattern such as conductors/wires or stitch pattern. The conductor arrangement/pattern such as conductors/wires or stitch pattern may comprise a thread. The conductor arrangement/pattern such as conductors/wires or stitch pattern may be provided on the fiber panel. The conductor arrangement/pattern such as conductors/wires or stitch pattern may be formed into the structural substrate so that the conductor arrangement/pattern such as conductors/wires or stitch pattern is not visible at the exterior surface of the cover. The set of threads of the conductor arrangement/pattern such as conductors/wires or stitch pattern may be pressed into a surface of the fiber panel so that the structural substrate comprises a generally flat surface for the cover. The thread may be pressed into a surface of the fiber panel so that the thread is not visible at the exterior surface of the cover of the composite surface. The conductors/thread may comprise a network of conductors/threads in the fiber panel formed into the structural substrate. The component may comprise a feature on the structural substrate. The feature may comprise at least one of (a) a rib; (b) a set of ribs; (c) a feature adjacent to the reinforcement; (d) a feature at the reinforcement; (e) a feature at the hinged panel; (f) a structure for the hinged panel; (g) a resin-formed feature; (h) a resin-formed feature molded on the structural substrate. The composite structure further may comprise a foam layer beneath the cover. The structural substrate may comprise a compression-formed component from the fiber panel. The cover may comprise at least one of (a) leather; (b) synthetic leather; (c) imitation leather; (d) a composite of a plastic layer and textile backing; (e) a coated fabric; (f) polyvinylchloride coated fabric; (g) a woven fabric; (h) a non-woven fabric; (i) an applique; (j) vinyl; (k) a foil; (1) coating on the structural substrate; (m) paint on the structural substrate; (n) the exterior surface of the structural substrate. The component may comprise at least one of an instrument panel; a door panel; a trim panel; a trim component.

### Exemplary Embodiments—H

According to an exemplary embodiment as shown schematically in the FIGURES, a component for a vehicle interior may comprise a composite structure comprising a fiber panel and a cover. The fiber panel may comprise a conductor. The conductor may be configured to provide a functional circuit for the composite structure. The conductor may comprise a pattern of electrically conductive threads. Conductive thread may be within the fiber panel. Conductive thread may be stitched onto the fiber panel. The conductor may comprise a conductor arrangement/pattern such as conductors/wires or stitch pattern comprising conductive thread comprising the functional circuit. The functional circuit may comprise a user interface. The functional circuit may comprise an input device and/or an output device. The functional circuit may comprise a circuit element. The composite structure may comprise a feature on the fiber panel; the feature may comprise at least one of (a) a resin structure; (b) a resin feature; (c) a molded feature; (d) a molded structure; (e) a rib. The composite structure may comprise a resin structure for the fiber panel adjacent to the functional circuit. The fiber panel may comprise a conductor arrangement/pattern such as conductors/wires or stitch pattern comprising at least one of (a) conductive thread; (b) non-conductive thread. The component may comprise at least one of a trim panel, an instrument panel, a door panel, an overhead panel, a console, an overhead console, a floor console, an interior trim component, pillar trim, an operator control, a steering control, a steering wheel.

According to an exemplary embodiment as shown schematically in the FIGURES, a component for a vehicle interior may comprise a composite structure comprising a fiber panel and a cover. The fiber panel may comprise a conductor. The conductor may comprise conductive thread configured to provide a functional circuit. The conductive thread may comprise a pattern of electrically conductive threads. The composite structure may comprise a conductor arrangement/pattern such as conductors/wires or stitch pattern in the fiber panel comprising the conductive thread to provide the functional circuit. The functional circuit may comprise a sensor. The functional circuit may comprise at least one of a light, an LED light, a display, an illuminated feature. The functional circuit may comprise at least one of (a) a user interface; (b) an input device; (c) a switch; (d) an output device; (e) a display. The functional circuit may be configured to be connected to at least one of (a) a control system; (b) a vehicle system; (c) a network; (d) a power source. The composite structure may be configured to facilitate deployment of an airbag; the airbag may be configured to deploy through an airbag door; the airbag door may be configured to be formed adjacent to the functional circuit.

### Exemplary Embodiments—I

According to an exemplary embodiment as shown schematically in the FIGURES, a component for a vehicle interior may comprise a composite structure comprising a fiber panel and a cover. The fiber panel may comprise a conductor. The conductor may be configured to provide a functional circuit for the composite structure. The conductor may comprise conductive thread. The conductor may comprise electrically conductive thread. The conductor may comprise a pattern of electrically conductive threads. The conductor may comprise a set of electrically conductive threads. Conductive thread may be within the fiber panel. Conductive thread may be stitched within the fiber panel. Conductive thread may be stitched into the fiber panel. Conductive thread may be stitched onto the fiber panel. The conductor may comprise a conductor arrangement/pattern such as conductors/wires or stitch pattern comprising conductive thread. The conductor may comprise a conductor arrangement/pattern such as conductors/wires or stitch pattern comprising the functional circuit. The functional circuit may comprise a user interface. The functional circuit may comprise an input device and/or an output device. The functional circuit may comprise an input device and an output device. The functional circuit may comprise a connection point. The functional circuit may comprise a circuit element. The functional circuit may be configured for connection to a power source. The functional circuit may be configured for operation by a control system. The fiber panel may comprise a compressed fiber panel. The composite structure may comprise a feature on the fiber panel. The feature may comprise a resin structure. The feature may comprise a resin feature. The feature may comprise a molded feature. The feature may comprise a molded structure. The feature may comprise a rib. The composite structure may comprise a resin structure for the fiber panel. The feature may comprise a resin structure adjacent to the functional circuit. The fiber panel may comprise a conductor arrangement/pattern such as conductors/wires or stitch pattern comprising conductive thread. The fiber panel may comprise a conductor arrangement/pattern such as conductors/wires or stitch pattern comprising non-conductive thread. The conductor arrangement/pattern such as conductors/wires or stitch pattern comprising non-conductive thread may comprise a reinforcement for the fiber panel; the reinforcement may be configured to provide a hinge area for an airbag door. The component may comprise at least one of a trim panel, an instrument panel, a door panel, an overhead panel, a console, an overhead console, a floor console, an interior trim component, pillar trim, an operator control, a steering control, a steering wheel.

According to an exemplary embodiment as shown schematically in the FIGURES, a component for a vehicle interior may comprise a composite structure comprising a fiber panel and a cover. The fiber panel may comprise a conductor. The conductor may comprise conductive thread configured to provide a functional circuit. The conductive thread may comprise a pattern of electrically conductive threads. The composite structure may comprise a conductor arrangement/pattern such as conductors/wires or stitch pattern in the fiber panel comprising the conductive thread to provide the functional circuit. The functional circuit may comprise a sensor. The sensor may be configured to operate as a switch. The functional circuit may comprise at least one of a light, an LED light, a display, an illuminated feature. The functional circuit may comprise a user interface. The functional circuit may comprise an input device. The input device may comprise a switch. The functional circuit may comprise an output device. The output device may comprise a display. The functional circuit may comprise an input device and an output device. The component may comprise a connector for the functional circuit. The functional circuit may be configured to be connected to a control system. The functional circuit may be configured to be connected to a vehicle system. The functional circuit may be configured to be connected to a network. The functional circuit may be configured to be connected to a power source. The composite structure may be configured to facilitate deployment of an airbag; the airbag may be configured to deploy through an airbag door; the airbag door may be configured to be formed adjacent to the functional circuit. The composite structure may comprise a conductor arrangement/pattern such as conductors/wires or stitch pattern in the fiber panel comprising non-conductive thread; the conductor arrangement/pattern such as conductors/wires or stitch pattern may be configured to provide a reinforcement for a hinge area for the airbag door. The component may comprise at least one of a trim panel, an instrument panel, a door panel, an overhead panel, a console, an overhead console, a floor console, an interior trim component, pillar trim, an operator control, a steering control, a steering wheel.

### Exemplary Embodiments—J

According to an exemplary embodiment as shown schematically in the FIGURES, a component for a vehicle interior may comprise a structural substrate and an electrical conductor coupled to the structural substrate. The structural substrate may comprise a fiber panel. The component may comprise a conductor arrangement/pattern such as conductors/wires or stitch pattern; the stitch pattern may comprise a top stitch and a bottom stitch. The top stitch may comprise the electrical conductor. The bottom stitch may comprise the electrical conductor. The structural substrate may comprise a panel comprised at least partially of fibers; the electrical conductor may be sewn to the panel. The electrical conductor may be pressed into a surface of the panel during a compression forming process. The structural substrate may comprise an ancillary component molded on the panel. The structural substrate may comprise an ancillary component molded on the electrical conductor. The structural substrate may comprise an ancillary component molded on the panel over the electrical conductor. The structural substrate may comprise at least one of (a) a compression-formed component; (b) a generally rigid fiber mat. The component may comprise at least one of (a) an instrument panel; (b) a door panel; (c) a trim panel; (d) an overhead console; (e) a trim component.

According to an exemplary embodiment as shown schematically in the FIGURES, a component for a vehicle interior may be produced in a mold comprising a first surface and a second surface by a process comprising placing a pre-form substrate onto the first surface of the mold; forming a compression-formed structure from the pre-form substrate by compressing the pre-form substrate between the first surface of the mold and the second surface of the mold; and applying a cover to the compression-formed structure to form a panel assembly providing a surface effect. The pre-form substrate may comprise an electrical conductor. The pre-form substrate may comprise a fiber panel; the electrical conductor may be sewn to the fiber panel. The compression-formed structure may comprise a substrate layer and the electrical conductor. The step of forming the compression-formed structure may comprise forming the substrate layer into a generally rigid form. The step of forming the compression-formed structure may comprise forming the electrical conductor and the pre-form substrate with a generally continuous surface. A generally smooth texture of the panel assembly may be provided by (a) a surface effect of the cover and (b) a surface effect of the pre-form substrate. The panel assembly may comprise a composite structure with at least partially a shape of the compression-formed structure; the shape may comprise a first contour provided by the first surface of the mold and a second contour provided by the second surface of the mold. The pre-form substrate may comprise a resin; the process may comprise the step of heating the pre-formed substrate and the pre-formed substrate may be compressed as the pre-formed substrate cools. The process may comprise the step of injecting resin into the mold after the compression-formed structure is formed to form an ancillary component of the panel assembly.

According to an exemplary embodiment as shown schematically in the FIGURES, a component for a vehicle interior may comprise a composite structure comprising a structural substrate formed from a fiber panel and a cover for the structural substrate providing an exterior surface. The structural substrate may comprise a stitch pattern. The stitch pattern may comprise a set of threads. The stitch pattern may comprise an electrical conductor. The stitch pattern may be provided on the fiber panel. The stitch pattern may be formed into the structural substrate so that the stitch pattern is not visible at the exterior surface of the cover. The set of threads of the stitch pattern may be pressed into a surface of the fiber panel so that the structural substrate may comprise a generally flat surface for the cover. The set of threads of the stitch pattern may be pressed into a surface of the fiber panel so that the set of threads is not visible at the exterior surface of the cover of the composite surface. The stitch pattern may comprise a network of threads in the fiber panel formed into the structural substrate. The set of threads for the stitch pattern may comprise an upper set of threads and a lower set of threads. The upper set of threads may comprise the electrical conductor. The lower set of threads may comprise the electrical conductor. The stitch pattern may comprise a set of threads at least partially sewn into the fiber panel of the structural substrate. The component may comprise a feature on the structural substrate. The feature may comprise at least one of (a) a rib; (b) a set of ribs; (c) a reinforcement for the fiber panel; (d) a cover for the electrical conductor; (e) insulation for the electrical conductor; (f) shielding for the electrical conductor; (g) a housing for the electrical connector; (h) a cover for an electrical connector to the electrical conductor; (i) a connection point for the electrical conductor and a wire; (j) a resin-formed feature; (k) a resin-formed feature molded on the structural substrate. The composite structure may comprise a foam layer beneath the cover. The structural substrate may comprise a compression-formed component from the fiber panel. The cover may comprise at least one of (a) leather; (b) synthetic leather; (c) imitation leather; (d) a composite of a plastic layer and textile backing; (e) a coated fabric; (f) polyvinylchloride coated fabric; (g) a woven fabric; (h) a non-woven fabric; (i) an applique; (j) vinyl; (k) a foil; (1) coating on the structural substrate; (m) paint on the structural substrate; (n) the exterior surface of the structural substrate. The component may comprise at least one of an instrument panel; a door panel; a trim panel; a trim component.

According to an exemplary embodiment as shown schematically in the FIGURES, a component for a vehicle interior may comprise a composite structure comprising (a) a structural substrate formed from a fiber panel; (b) a cover for the structural substrate providing an exterior surface; and (c) a feature formed from resin on the structural substrate. The structural substrate may comprise an electrical conductor. The structural substrate may comprise a pattern of threads; the pattern of threads may comprise the electrical conductor.

According to an exemplary embodiment as shown schematically in the FIGURES, a component for a vehicle interior may be prepared using a mold by a process comprising the steps of: (a) providing a pre-form substrate; (b) joining an electrical conductor to the pre-form substrate; (c) disposing the pre-form substrate with the electrical conductor into the mold; and (d) compressing the pre-form substrate between the first surface of the mold and a second surface of the mold to form the pre-form substrate into a structural substrate having a shape. The shape may correspond to a first contour of the first surface and a second contour of the second surface. The step of joining an electrical conductor to the pre-form substrate may comprise sewing the electrical conductor to the pre-form substrate. The step of joining an electrical conductor to the pre-form substrate may comprise piercing an opening in the pre-form substrate and joining the electrical conductor to a stitch at the opening.

According to an exemplary embodiment as shown schematically in the FIGURES, a method of manufacturing a component for a vehicle interior may comprise the steps of: (a) providing a pre-form substrate; (b) joining an electrical connector to the pre-form substrate; (c) disposing the pre-form substrate with the electrical conductor onto a first surface of the mold; and (d) compressing the pre-form substrate between the first surface and a second surface of the mold to form a structural substrate having a shape. The shape may correspond to a first contour of the first surface and a second contour of the second surface.

The component may comprise a composite structure comprising a substrate comprising a fiber panel; the fiber panel may comprise a conductor arrangement; the conductor arrangement may be configured to provide a functional circuit for the composite structure. The conductor arrangement and/or functional circuit may be configured to comprise at least one of: a conductor, a sensor/detector, an input device, an output device, an interactive device, a display; a switch, a light/lighting, a light element, a light guide, etc. The conductor arrangement and/or functional circuit may be configured to comprise at least one of a light/lighting, a light element, a light guide; an LED/LED lighting, a display, a display panel, an antenna, a camera, a video-recorder; an image display/device, a user interface, an input device, an output device, an input/output device; a sensor, a detector, a switch, a touch sensor; an odor/scent detector, a microphone, a sound detector, a wireless charging device, a wireless connection area, a heating element, an electrified area, etc. The fiber panel with functional circuit may be configured for connection by an edge connector. The fiber panel may comprise a conductor pattern comprising a conductive trace; the conductor arrangement may comprise conductive wire and/or conductive thread. The component may comprise a trim panel, an instrument panel, a door panel, an overhead panel, a console, an overhead console, a floor console, an armrest, a trim component, pillar trim, an operator control, a steering control, a steering wheel, a trunk, a frunk, a hatch, a car rear compartment, a car front compartment, a visor, a vanity, a glove box, a receptacle in an instrument panel, a receptacle in a trim panel, etc.

A component for a vehicle interior is disclosed. The component may comprise a composite structure comprising a substrate comprising a fiber panel comprising a conductor arrangement; the conductor arrangement may be configured to provide a functional circuit for the composite structure. The substrate may comprise a structural substrate; the fiber panel may comprise a compression-formed fiber panel. The fiber panel with functional circuit may be configured for connection by an edge connector. The composite structure may comprise a feature comprising a resin/molded structure. The feature may comprise a border/reinforcement for the fiber panel; the feature may comprise structural reinforcement for the composite structure. The fiber panel may comprise a conductor pattern comprising a conductive trace; the conductor arrangement may comprise conductive wire or conductive thread. The component may comprise trim panel, instrument panel, door panel, overhead panel, console, steering wheel, trunk, frunk, hatch, visor, receptacle, etc.

### Exemplary Embodiments—X

According to an exemplary embodiment as shown schematically in the FIGURES, component for a vehicle interior may comprise a composite structure comprising a substrate comprising a fiber panel; the fiber panel may comprise a conductor arrangement; the conductor arrangement may be configured to provide a functional circuit for the composite structure; the substrate may comprise a structural substrate; the structural substrate may comprise a compression-formed fiber panel. The conductor arrangement and/or functional circuit may be configured to comprise at least one of: a conductor; a sensor/detector; an input device; an output device; an interactive device; a display; a switch; a light/lighting; a light element; a light guide. The conductor arrangement and/or functional circuit may be configured to comprise at least one of a light/lighting; a light element; a light guide; an LED; LED lighting; a display; a display panel; an antenna; a camera; a video-recorder; an image display/device; a user interface; an input device; an output device; an input/output device; a sensor; a detector; a switch; a touch sensor; an odor/scent detector; a microphone; a sound detector; a wireless charging device; a wireless connection area; a heating element; an electrified area; other device/technology. The composite structure may comprise a base; the base may comprise a structural substrate; the fiber panel may comprise a compression-formed fiber panel. The substrate may comprise a feature; the feature may comprise a formed feature; the feature may comprise a molded resin feature; the feature may comprise at least one of a molded resin structure and/or a molded resin border and/or a molded resin reinforcement; the conductor arrangement may comprise a formed circuit comprising the functional circuit. The composite structure may comprise a fiber panel with a circuit panel comprising the functional circuit; the composite structure may comprise the fiber panel and a circuit matrix; the composite structure may comprise a cover. The conductor arrangement may comprise a conductor; a conductor may be within the fiber panel; a conductor may be on the fiber panel. The conductor arrangement may comprise a conductive trace; the conductive trace may comprise a conductor; the conductor arrangement may comprise a pattern of electrically conductive traces; the conductor arrangement may comprise a set of electrically conductive traces; a conductive trace may be within the fiber panel and/or on the fiber panel; a conductive trace may be provided into the fiber panel and/or onto the fiber panel. The fiber panel may comprise a mixture of fibers and plastic; the fibers may comprise natural fibers; the fibers comprise at least one of synthetic fibers, glass fibers, carbon fibers and/or polymeric fibers; the fiber panel may comprise a substantially rigid panel; the fiber panel may comprise a plurality of fibers and a resin configured to bind the fibers; the resin may comprise thermoplastic resin; the fiber panel may be configured to provide structural properties comprising rigidity and strength; the fiber panel may comprise a generally rigid panel formed from a fiber mat; the fiber panel may comprise a contoured fiber panel. The composite structure may comprise a feature on the fiber panel; the feature may be configured to provide a connection point for the functional circuit; the feature may comprise a molded resin structure; the feature may comprise a structure configured to provide support for a module for the functional circuit. The composite structure may comprise a flexible circuit formed on and/or in and/or with the fiber panel; the fiber panel may comprise the circuit board comprising the functional circuit; the composite structure may comprise a circuit panel comprising the conductor arrangement comprising a conductor pattern comprising a conductive trace; the conductor arrangement may comprise a conductor pattern comprising the functional circuit; the fiber panel may comprise a circuit panel; the conductor arrangement may comprise a pattern on the fiber panel; the conductor arrangement may comprise a metallic material and/or a metallic trace; the conductor arrangement may comprise a wire and/or an insulated wire; the conductor arrangement may comprise an exposed wire; the conductor arrangement may comprise a generally flat wire; the conductor arrangement may comprise a lead and/or a band; the conductor arrangement may comprise a multi-layer conductor pattern for the fiber panel; the multi-layer conductor pattern may comprise a set of conductive traces providing the functional circuit. The functional circuit may comprise a user interface; the user interface may comprise an input device and/or an output device; the functional circuit may comprise an input device and an output device; the functional circuit may comprise a connection point; the functional circuit may comprise a connector; the functional circuit may comprise a connector configured to connect to a power source and/or at least one vehicle system; the functional circuit may comprise a circuit element; the functional circuit may be configured for connection by an edge connector; the functional circuit may be configured for connection by an internal connector; the functional circuit may be configured for connection by an internal edge connector; the functional circuit may be configured for connection by an edge connector comprising a tab on the composite structure; the functional circuit may be configured for connection by an edge connector comprising a tab on the composite structure configured to fit within a socket; the functional circuit may be configured for operation by a control system; the functional circuit may comprise a controller configured for operation with a control system configured for operation of at least one vehicle system; the functional circuit may comprise a module; the functional circuit may comprise a connection point for a module. The functional circuit may comprise a user interface configured for operation of at least one vehicle system; the functional circuit may comprise a sensor; the functional circuit may comprise a sensor configured to operate as a switch; the functional circuit may comprise at least one of a light, an LED light, a display, an illuminated feature; the functional circuit may comprise an input device; the input device may comprise a switch; the functional circuit may comprise an output device; the output device may comprise a display; the functional circuit may be configured to operate a user interface comprising an input device and an output device. The functional circuit may be configured to operate a mechanism and/or a motor. The component may comprise a connector for the functional circuit; the functional circuit may be configured to be connected to a vehicle system and/or a network and/or a power source. The composite structure may comprise a feature on the fiber panel; the feature may comprise a resin structure; the feature may comprise a molded structure; the feature may comprise a rib; the feature may comprise a resin structure adjacent to the functional circuit; the fiber panel may comprise a conductor pattern comprising a conductive trace and the feature adjacent to the conductive trace; the feature may comprise an ancillary component on the fiber panel; the ancillary component may be molded on the fiber panel over the conductor arrangement; the ancillary component may comprise a structure for functional circuit and/or a support for functional circuit and/or a housing for functional circuit and/or a structure for connection to the functional circuit. The feature may comprise a reinforcement for the fiber panel and/or a reinforcement for the functional circuit; the feature may comprise a structural reinforcement for the composite structure; the conductor arrangement may comprise conductive wire and/or conductive thread; conductive thread may comprise wire; the composite structure may comprise a cover; the composite structure may comprise a foam layer beneath the cover; the composite structure may comprise a cover; the composite structure may comprise an intermediate layer beneath the cover; the conductor arrangement may be configured to be substantially functionally effective; the conductor arrangement may be configured to be substantially visually imperceptible under the cover; the composite structure may be configured so that the functional circuit is substantially visually imperceptible under the cover. The composite structure may comprise a cover; the cover may comprise at least one of (a) leather; (b) synthetic leather; (c) imitation leather; (d) a composite of a plastic layer and textile backing; (e) a coated fabric; (f) polyvinylchloride coated fabric; (g) a woven fabric; (h) a non-woven fabric; (i) an applique; (j) vinyl; (k) a foil; (1) coating on the structural substrate; (m) paint on the structural substrate; (n) the exterior surface of the structural substrate; (o) at least partial concealment for the electrical conductor arrangement. The component may comprise at least one of a trim panel, an instrument panel, a door panel, an overhead panel, a console, an overhead console, a floor console, an interior trim component, pillar trim, an operator control, a steering control, a steering wheel, a trunk, a frunk, a hatch, a car rear compartment, a car front compartment, a visor, a vanity, a glove box, a receptacle in an instrument panel.

According to an exemplary embodiment as shown schematically in the FIGURES, a component for a vehicle interior may comprise a composite structure comprising a substrate and a cover; the substrate may comprise a conductor arrangement; the conductor arrangement may be configured to comprise a functional circuit; the substrate may be formed from a fiber panel; the substrate has a shape. The conductor arrangement may have the shape; the conductor arrangement has a contoured shape conforming to a contoured shape of the substrate; the conductor arrangement may comprise a conductive trace configured to provide the functional circuit; the conductive trace may comprise a layer of electrically conductive traces; the conductive trace may comprise a set of electrically conductive traces; a conductive trace may comprise a set of electrically conductive wires; a conductive trace may comprise a multi-layer set of electrically conductive traces; the conductive trace may comprise a pattern of electrically conductive traces; the conductor arrangement of the composite structure may comprise a conductor pattern in the fiber panel comprising a conductive trace to provide the functional circuit. The functional circuit may comprise a sensor; the sensor may be configured to operate as a switch. The functional circuit may comprise at least one of a light, an LED light, a display, an illuminated feature. The functional circuit may comprise a user interface; the functional circuit may comprise an input device and/or an output device; the functional circuit may comprise an input device and an output device. Th component may comprise a connector for the functional circuit; the functional circuit may be configured to be connected to a control system and/or a vehicle system and/or a network and/or a power source; the functional circuit may be configured to facilitate deployment of an airbag.

According to an exemplary embodiment as shown schematically in the FIGURES, a component for a vehicle interior may comprise a structural substrate; and a conductor arrangement coupled to the structural substrate; the structural substrate may be formed from a panel; the conductor arrangement may be configured to comprise a functional circuit; the panel may comprise a fiber panel; the functional circuit may comprise an electrical circuit. The conductor arrangement may comprise a circuit configured to be powered by a power source. The conductor arrangement may comprise a circuit configured to be connected to at least one vehicle system. The conductor arrangement may comprise a circuit configured to be connected to at least one network. The conductor arrangement may comprise a circuit configured to be connected to at least device. The conductor arrangement may comprise a circuit configured to operate a user interface system. The conductor arrangement may comprise a circuit on a circuit panel. The component may comprise a composite structure comprising the structural substrate and the conductor arrangement; the conductor arrangement may comprise a conductor pattern; the fiber panel may be comprised at least partially of fibers; the electrical conductor arrangement may be provided on the fiber panel; the fiber panel may be comprised at least partially of fibers; the electrical conductor arrangement may be provided in the fiber panel; the fiber panel may be comprised at least partially of fibers; the electrical conductor arrangement may be provided within the fiber panel; the electrical conductor arrangement may be pressed into a surface of the panel during a compression forming process; the structural substrate may comprise a feature molded on the panel; the structural substrate may comprise an ancillary component molded at the conductor arrangement; the structural substrate may comprise at least one of (a) a compression-formed component; (b) a generally rigid fiber mat.

According to an exemplary embodiment as shown schematically in the FIGURES, a component for a vehicle interior may be produced in a mold comprising a first surface and a second surface by a process comprising placing a pre-form substrate onto the first surface of the mold; forming a compression-formed structure from the pre-form substrate by compressing the pre-form substrate between the first surface of the mold and the second surface of the mold; applying a cover to the compression-formed structure to form a panel assembly providing a surface effect; the pre-form substrate may comprise an electrical conductor arrangement. The component of claim 125 the pre-form substrate may comprise a fiber panel; the electrical conductor arrangement may be formed into the fiber panel; the pre-form substrate may comprise a fiber panel; the electrical conductor arrangement may be formed onto the fiber panel; the pre-form substrate may comprise a fiber panel; the electrical conductor arrangement may be within the fiber panel; the pre-form substrate may comprise a fiber panel; the electrical conductor arrangement may be stitched into the fiber panel; the pre-form substrate may comprise a fiber panel; the electrical conductor arrangement may be sewn to the fiber panel. The compression-formed structure may comprise a substrate layer and the electrical conductor arrangement. The step of forming the compression-formed structure may comprise forming the substrate layer into a generally rigid form; the step of forming the compression-formed structure may comprise forming the electrical conductor arrangement and the pre-form substrate with a generally continuous surface. The panel assembly may comprise a composite structure with at least partially a shape of the compression-formed structure; the shape may comprise a contour provided by the first surface of the mold and a contour provided by the second surface of the mold; the pre-form substrate may comprise a resin; comprising the step of heating the pre-formed substrate; the pre-formed substrate may be compressed as the pre-formed substrate cools. The process may comprise the step of injecting resin into the mold after the compression-formed structure may be formed to form a feature on the panel assembly. The process may comprise the step of injecting resin into the mold after the compression-formed structure may be formed to form an ancillary component of the panel assembly.

According to an exemplary embodiment as shown schematically in the FIGURES, a component for a vehicle interior may comprise a composite structure comprising (a) a structural substrate formed from a fiber panel; (b) a cover for the structural substrate providing an exterior surface; (c) a conductor arrangement configured to comprise a functional circuit; the structural substrate may comprise the conductor arrangement. The conductor arrangement may comprise a conductor pattern; the conductor pattern may comprise an electrical conductor arrangement; the conductor pattern may be provided on the fiber panel; the conductor pattern may be formed into the structural substrate so that the conductor pattern is not visible at the exterior surface of the cover; the conductor pattern may comprise a set of traces; the set of traces of the conductor pattern is provided at a surface of the fiber panel so that the structural substrate may comprise a generally flat surface for the cover; the set of traces of the conductor pattern is provided at a surface of the fiber panel so that the set of traces is not visible at the exterior surface of the cover of the composite surface; the set of traces of the conductor pattern may be pressed into a surface of the fiber panel so that the structural substrate may comprise a generally flat surface for the cover; the set of traces of the conductor pattern may be pressed into a surface of the fiber panel so that the set of traces is not visible at the exterior surface of the cover of the composite surface; the set of traces for the conductor pattern may comprise an upper set of traces and a lower set of traces; the conductor pattern may comprise a set of traces at least partially formed into the fiber panel of the structural substrate; the conductor pattern may comprise a network of traces in the fiber panel formed into the structural substrate. The component may comprise a feature on the structural substrate; the feature may comprise at least one of (a) a rib; (b) a set of ribs; (c) a reinforcement for the fiber panel; (d) a cover for the electrical conductor; (e) insulation for the electrical conductor; (f) shielding for the electrical conductor; (g) a housing for the electrical connector; (h) a cover for an electrical connector to the electrical conductor; (i) a connection point for the electrical conductor arrangement and a wire; (j) a resin-formed feature; (k) a resin-formed feature molded on the structural substrate. The composite structure may comprise a foam layer beneath the cover; the structural substrate may comprise a compression-formed fiber panel.

According to an exemplary embodiment as shown schematically in the FIGURES, a component for a vehicle interior may comprise a composite structure comprising (a) a structural substrate formed from a fiber panel; (b) a cover for the structural substrate providing an exterior surface; (c) a feature formed from resin on the structural substrate; the structural substrate may comprise an electrical conductor arrangement; the structural substrate may comprise a pattern of traces; the pattern of traces may comprise the electrical conductor arrangement under the exterior surface.

According to an exemplary embodiment as shown schematically in the FIGURES, a component for a vehicle interior may be prepared using a mold by a process comprising the steps of (a) providing a pre-form substrate; (b) joining an electrical conductor arrangement to the pre-form substrate; (c) disposing the pre-form substrate with the electrical conductor arrangement into the mold; and (d) compressing the pre-form substrate between the first surface of the mold and a second surface of the mold to form the pre-form substrate into a structural substrate having a shape; the shape may correspond to a shape of the first surface and a shape of the second surface; the shape may correspond to a first contour of the first surface and a second contour of the second surface. The step of joining an electrical conductor arrangement to the pre-form substrate may comprise sewing the electrical conductor arrangement to the pre-form substrate; the step of joining an electrical conductor arrangement to the pre-form substrate may comprise piercing an opening in the pre-form substrate and joining the electrical conductor arrangement to a conductor arrangement at the opening.

According to an exemplary embodiment as shown schematically in the FIGURES, a method of manufacturing a component for a vehicle interior may comprise the steps of (a) providing a pre-form substrate; (b) joining an electrical connector to the pre-form substrate; (c) disposing the pre-form substrate with the electrical conductor arrangement onto a first surface of the mold; and (d) compressing the pre-form substrate between the first surface and a second surface of the mold to form a structural substrate having a shape; the shape may correspond to a first contour of the first surface and a second contour of the second surface; the shape may correspond to a shape of the first surface and a shape of the second surface; the shape may correspond to a first shape of the first surface and a second shape of the second surface.

According to an exemplary embodiment as shown schematically in the FIGURES, a component for a vehicle interior may comprise a composite structure comprising a fiber panel and a cover; the fiber panel may comprise a conductor arrangement; the conductor arrangement may be configured to provide a functional circuit for the composite structure. The conductor arrangement may comprise conductive wire; the conductor arrangement may comprise conductive thread; the conductive thread may comprise a wire; the conductor arrangement may comprise electrically conductive conductors; the conductor arrangement may comprise a pattern of electrically conductive conductors; the conductor arrangement may comprise a set of electrically conductive threads; conductive thread may be within the fiber panel; conductive thread may be stitched within the fiber panel; conductive thread may be stitched into the fiber panel and/or stitched onto the fiber panel; the conductor arrangement may comprise a stitch pattern comprising conductive thread; the conductor arrangement may comprise a stitch pattern comprising the functional circuit; the functional circuit may comprise a user interface; the functional circuit may comprise an input device and/or an output device; the functional circuit may comprise a connection point; the composite structure may comprise a feature on the fiber panel; the feature may comprise a resin structure and/or a resin feature and/or a molded feature and/or a molded structure; the feature may comprise a rib; the feature may comprise a resin structure adjacent to the functional circuit; the fiber panel may comprise a stitch pattern comprising conductive thread; the fiber panel may comprise a stitch pattern comprising non-conductive thread.

According to an exemplary embodiment as shown schematically in the FIGURES, a component for a vehicle interior may comprise a composite structure comprising a fiber panel and a cover; the fiber panel may comprise a conductor arrangement; the conductor arrangement may comprise conductors configured to provide a functional circuit. The functional circuit may comprise circuit elements; the conductors may comprise conductive traces configured to provide a functional circuit; the conductors may comprise conductive leads configured to provide a functional circuit; the conductor arrangement may comprise conductive wires configured to provide a functional circuit; conductors comprise a pattern of electrically conductive threads; the composite structure may comprise a stitch pattern in the fiber panel comprising conductive thread to provide the functional circuit; the functional circuit may comprise a sensor configured to operate as an operator control and/or a switch; the functional circuit may comprise at least one of a light, an LED light, a display, an illuminated feature; the functional circuit may comprise a user interface; the functional circuit may comprise an input device; the input device may comprise a switch; the functional circuit may comprise an output device; the output device may comprise a display; the functional circuit may comprise an input device and an output device; the component may comprise a connector for the functional circuit; the component may comprise a stitch pattern; the stitch pattern may comprise a top stitch and a bottom stitch; the structural substrate may comprise a panel comprised at least partially of fibers; the conductor arrangement may be sewn to the panel; the conductor arrangement may be pressed into a surface of the panel during a compression forming process.

According to an exemplary embodiment as shown schematically in the FIGURES, a component for a vehicle interior may may be produced in a mold comprising a first surface and a second surface by a process comprising the steps of placing a pre-form substrate onto the first surface of the mold; forming a compression-formed structure from the pre-form substrate by compressing the pre-form substrate between the first surface of the mold and the second surface of the mold; applying a cover to the compression-formed structure to form a panel assembly providing a surface effect; the pre-form substrate may comprise an electrical conductor arrangement. The pre-form substrate may comprise a fiber panel; the electrical conductor arrangement may be sewn to the fiber panel; the compression-formed structure may comprise a substrate layer and the electrical conductor arrangement; the step of forming the compression-formed structure may comprise forming the substrate layer into a generally rigid form; the step of forming the compression-formed structure may comprise forming the electrical conductor arrangement and the pre-form substrate with a generally continuous surface. A generally smooth texture of the panel assembly may be provided by (a) a surface effect of the cover and (b) a surface effect of the pre-form substrate; (c) a surface effect at least partially concealing the electrical conductor arrangement. The panel assembly may comprise a composite structure with at least partially a shape of the compression-formed structure; the shape may comprise a shape provided by a surface of the mold; the pre-form substrate may comprise a resin; the process may comprise the step of heating the pre-formed substrate and the pre-formed substrate may be compressed as the pre-formed substrate cools. The process may comprise the step of injecting resin into the mold after the compression-formed structure may be formed to form an ancillary component of the panel assembly.

According to an exemplary embodiment as shown schematically in the FIGURES, a component for a vehicle interior may comprise a composite structure comprising: (a) a structural substrate formed from a fiber panel; (b) a cover for the structural substrate providing an exterior surface; the structural substrate may comprise a stitch pattern; the stitch pattern may comprise a set of threads; the stitch pattern may comprise an electrical conductor arrangement. The stitch pattern may be provided on the fiber panel; the stitch pattern may be formed into the structural substrate so that the stitch pattern is not visible at the exterior surface of the cover; the set of threads of the stitch pattern may be pressed into a surface of the fiber panel so that the structural substrate may comprise a generally flat surface for the cover; the set of threads of the stitch pattern may be pressed into a surface of the fiber panel so that the set of threads is not visible at the exterior surface of the cover of the composite surface; the stitch pattern may comprise a network of threads in the fiber panel formed into the structural substrate; the set of threads for the stitch pattern may comprise an upper set of threads and a lower set of threads. A feature formed on the fiber panel may comprise at least one of (a) a rib; (b) a set of ribs; (c) a reinforcement for the fiber panel; (d) a cover for the electrical conductor; (e) insulation for the electrical conductor; (f) shielding for the electrical conductor; (g) a housing for the electrical connector; (h) a cover for an electrical connector to the electrical conductor; (i) a connection point for the electrical conductor arrangement and a wire; (j) a resin-formed feature; (k) a resin-formed feature molded on the structural substrate. The composite structure may comprise a foam layer beneath the cover; the structural substrate may comprise a compression-formed fiber panel.

According to an exemplary embodiment as shown schematically in the FIGURES, a component for a vehicle interior may comprise a composite structure comprising (a) a structural substrate formed from a fiber panel; (b) a cover for the structural substrate providing an exterior surface; (c) a feature formed from resin on the structural substrate; the structural substrate may comprise an electrical conductor arrangement; the electrical conductor arrangement may be configured to comprise a functional circuit for the composite structure. The structural substrate may comprise a pattern of conductors; the pattern of conductors may comprise the electrical conductor arrangement.

According to an exemplary embodiment as shown schematically in the FIGURES, a component for a vehicle interior may comprise a fiber panel; and a structure comprising a resin; the fiber panel may comprise a compression-formed component; the compression-formed component may comprise an edge along a periphery and provides a structural substrate having a shape and a thickness along the edge; the structure may comprise a border of the structural substrate along the thickness of the structural substrate provided by the compression-formed component; the fiber panel may comprise a conductor arrangement; the conductor arrangement may be configured to provide a functional circuit.

According to an exemplary embodiment as shown schematically in the FIGURES, a component for a vehicle interior may comprise a fiber panel comprising a compression-formed component; and a structure formed from a molded resin; the structure may comprise at least one molded feature; the compression-formed component may comprise an edge along a periphery and provides a structural substrate having a shape and a thickness along the edge; the structure may comprise a border of the structural substrate along the thickness of the structural substrate provided by the compression-formed component; and the at least one molded feature may comprise a molded feature configured to support the fiber panel; the fiber panel may comprise a conductor arrangement; the conductor arrangement may be configured to provide a functional circuit.

According to an exemplary embodiment as shown schematically in the FIGURES, a component for a vehicle interior may comprise a structural substrate comprising a compression-formed fiber panel and a structure comprising a resin; the compression-formed fiber panel may comprise a thickness along a periphery; the structure may comprise a border of the structural substrate along the thickness of the periphery of the compression-formed fiber panel; the periphery of the fiber panel may comprise an edge; the structure may be formed on the edge; the fiber panel may comprise a conductor arrangement; the conductor arrangement may be configured to provide a functional circuit.

According to an exemplary embodiment as shown schematically in the FIGURES, a component for a vehicle interior may comprise a structural substrate comprising a fiber panel and a structure comprising a resin; the fiber panel may comprise a thickness along a periphery; the structure may comprise a border of the structural substrate along the thickness of the periphery of the fiber panel; the periphery of the fiber panel may comprise an edge; the structure may be formed on the edge; the fiber panel may comprise a conductor arrangement; the conductor arrangement may be configured to provide a functional circuit.

According to an exemplary embodiment as shown schematically in the FIGURES, a component for a vehicle interior may comprise a fiber panel; a structure comprising a resin; and a cover coupled to at least one of (a) the fiber panel, (b) the structure; the fiber panel may comprise a compression formed component; the compression formed component may comprise an edge along a periphery and provides a structural substrate having a shape and a thickness along the edge; the structure may comprise a border of the structural substrate along the thickness of the structural substrate provided by the compression formed component; the fiber panel may comprise a conductor arrangement; the conductor arrangement may be configured to provide a functional circuit.

According to an exemplary embodiment as shown schematically in the FIGURES, a component for a vehicle interior may comprise a composite structure comprising a substrate comprising a fiber panel; the fiber panel may comprise a conductor arrangement; the conductor arrangement may be configured to provide a functional circuit for the composite structure. The composite structure may comprise a structural substrate; the fiber panel may comprise a compression-formed fiber panel. The composite structure may comprise a functional element comprising the conductor arrangement; the functional element may comprise an insert and/or mat and/or a fabric and/or a woven material and/or a formed material and/or a resin material; the conductor arrangement and/or functional circuit may be configured to comprise at least one of: a conductor; a sensor/detector; an input device; an output device; an interactive device; a display; a switch; a light/lighting; a light element; a light guide. The conductor arrangement and/or functional circuit may be configured to comprise at least one of: a light/lighting; a light element; a light guide; an LED; LED lighting; a display; a display panel; an antenna; a camera; a video-recorder; an image display/device; a user interface; an input device; an output device; an input/output device; a sensor; a detector; a switch; a touch sensor; an odor/scent detector; a microphone; a sound detector; a wireless charging device; a wireless connection area; a heating element; an electrified area; other device/technology. The composite structure may comprise a base; the base may comprise a structural substrate; the fiber panel may comprise a compression-formed fiber panel. The vehicle interior component may comprise a composite structure comprising a substrate such as a fiber panel and a cover and a functional element/layer comprising a conductor arrangement and/or functional circuit. The functional element may comprise an insert/layer and/or the conductor arrangement; the functional element may be configured to comprise a functional circuit; the conductor arrangement may be configured to provide a functional circuit. The composite structure may comprise a functional element comprising the conductor arrangement; the functional element may comprise an insert and/or mat and/or a layer and/or a fabric and/or a woven material and/or a formed material and/or a resin material. The component may comprise a trim panel, an instrument panel, a door panel, an overhead panel, a console, an overhead console, a floor console, an armrest, an interior trim component, pillar trim, an operator control, a steering control, a steering wheel, etc.

According to an exemplary embodiment as shown schematically in the FIGURES, aa vehicle interior component may comprise a composite structure configured to provide a circuit element.

According to an exemplary embodiment as shown schematically in the FIGURES, a vehicle interior component may comprise a composite structure configured to provide an arrangement of conductors for a circuit element.

According to an exemplary embodiment as shown schematically in the FIGURES, a composite structure may be configured to provide an arrangement of conductors for a circuit element to provide a functional circuit.

According to an exemplary embodiment as shown schematically in the FIGURES, a vehicle interior component may comprise a composite structure comprising a fiber panel configured to provide an arrangement of conductors for a circuit element to provide a functional circuit.

### Exemplary Embodiments—Y

A component for a vehicle interior is disclosed. The component may comprise a composite structure comprising a substrate comprising a fiber panel comprising a conductor arrangement; the conductor arrangement may be configured to provide a functional circuit for the composite structure. The substrate may comprise a structural substrate; the fiber panel may comprise a compression-formed fiber panel. The fiber panel with functional circuit may be configured for connection by an edge connector. The composite structure may comprise a feature comprising a resin/molded structure. The feature may comprise a border/reinforcement for the fiber panel; the feature may comprise structural reinforcement for the composite structure. The fiber panel may comprise a conductor pattern comprising a conductive trace; the conductor arrangement may comprise conductive wire or conductive thread. The component may comprise trim panel, instrument panel, door panel, overhead panel, console, steering wheel, trunk, frunk, hatch, visor, receptacle, etc.

TABLE A
REFERENCE SYMBOL LIST

| SYMBOL | ELEMENT, PART OR COMPONENT |
|---|---|
| V | Vehicle |
| I | Interior |
| C | Component/trim component |
| IP | Instrument panel |
| DP | Door/door panel |
| OHP | Overhead panel |
| OC | Overhead console |
| FC | Floor console |
| AR | Arm rest |
| PL | Pillar |
| SM | Side mirror |
| SW | Steering wheel |
| SZ | Seat/seat assembly |
| NTR | Trunk/hatch (rear storage area) |
| NTF | Frunk/hatch (front storage area) |
| VN | Visor/vanity (panel/flap) |
| GB | Receptacle/storage (glove box, etc.) |
| CS | Composite structure |
| PN | Panel/panel layer |
| FP | Fiber panel |
| | Compression-formed component (fiber panel) |
| | Fiber mat |
| | Reinforced Fiber panel |
| T | Cover |
| B | Base |
| SB | Substrate/Structural substrate |
| FM | Foam Layer |
| NL | Intermediate layer |
| | Panel layer |
| | (intermediate layer, insulating layer, |
| | insulator/cover, etc.) |
| TX | Surface |
| ABM | Airbag module |
| ABD | Airbag door |
| UI | User interface |
| | (input device and/or output device) |
| UIS | User interface system |
| FT | Functional layer |
| | (insert, mat, element, etc. with |
| | electrification/conductivity, etc.) |
| FR | Functional region |
| | (functional circuit/circuit element/circuit |
| | arrangement/Functional arrangement/etc.) |
| MX | Base/support layer |
| | (underlayer, backing, base, matrix, |
| | substrate layer, fabric, film, liner, etc.) |
| CR | Conductor/conductor arrangement |
| | (conductive element, circuit element, etc.) |
| CD | Conductor |
| CW | Cable/wire |
| CP | Connection point/connector/plug |
| CN | Connection point |
| CNF | Connection point/tab (plug) |
| CNP | Connection point/receptacle (socket) |
| PC | Pad/contact |
| LT | Light/lighting |
| | (light element, light guide) |
| LG | Light guide |
| LED | LED |
| SF | System to generate field/antenna |
| | (transmit/receive) |
| FL | Field/detection space/area |
| | (field/antenna/etc.) |
| CM | Camera/video-recorder |
| ID | Image display/device |
| | (user interface input/output device, |
| | input device) |
| SN | Sensor/detector (input device/switch) |
| OC | Sensor (occupancy detector/sensor) |
| UV | ultraviolet sensor |
| AX | Accelerometer |
| OD | Odor/scent detector |
| MR | Microphone/sound detector |
| CW | Wireless charging/connection area/surface |
| | (for mobile device) |
| HT | Heating element |
| MD | mobile device |
| OB | object/item |
| TN | Antenna |
| SH | Switch/button |
| DL | Display/display element |
| | (display panel, light panel, etc.) |
| | (output device) |
| M | Motor/mechanism |
| CM | Control system |
| PS | Power source |
| VS | Vehicle system/systems |
| ABM | Airbag module |
| AB | Airbag |
| ABD | Airbag door |
| AC | Airbag chute |
| HG | Hinge/Hinge area |
| TR | Tear line/seam |
| RB | Feature/structure/structural element/ |
| | reinforcement/rib |
| FPc | Compression-formed component (fiber panel) |
| FPu | Fiber mat |
| MW | Sewing machine |
| N | Needle |
| ST | Stitch/stitch pattern |
| SP | Stitch pattern |
| OV | Oven |
| M | Mold |
| MT | Mold top |
| MB | Mold bottom |

It is important to note that the present inventions (e.g. inventive concepts, etc.) have been described in the specification and/or illustrated in the FIGURES of the present patent document according to exemplary embodiments; the embodiments of the present inventions are presented by way of example only and are not intended as a limitation on the scope of the present inventions. The construction and/or arrangement of the elements of the inventive concepts embodied in the present inventions as described in the specification and/or illustrated in the FIGURES is illustrative only. Although exemplary embodiments of the present inventions have been described in detail in the present patent document, a person of ordinary skill in the art will readily appreciate that equivalents, modifications, variations, etc. of the subject matter of the exemplary embodiments and alternative embodiments are possible and contemplated as being within the scope of the present inventions; all such subject matter (e.g. modifications, variations, embodiments, combinations, equivalents, etc.) is intended to be included within the scope of the present inventions. It should also be noted that various/other modifications, variations, substitutions, equivalents, changes, omissions, etc. may be made in the configuration and/or arrangement of the exemplary embodiments (e.g. in concept, design, structure, apparatus, form, assembly, construction, means, function, system, process/method, steps, sequence of process/method steps, operation, operating conditions, performance, materials, composition, combination, etc.) without departing from the scope of the present inventions; all such subject matter (e.g. modifications, variations, embodiments, combinations, equivalents, etc.) is intended to be included within the scope of the present inventions. The scope of the present inventions is not intended to be limited to the subject matter (e.g. details, structure, functions, materials, acts, steps, sequence, system, result, etc.) described in the specification and/or illustrated in the FIGURES of the present patent document. It is contemplated that the claims of the present patent document will be construed properly to cover the complete scope of the subject matter of the present inventions (e.g. including any and all such modifications, variations, embodiments, combinations, equivalents, etc.); it is to be understood that the terminology used in the present patent document is for the purpose of providing a description of the subject matter of the exemplary embodiments rather than as a limitation on the scope of the present inventions.

It is also important to note that according to exemplary embodiments the present inventions may comprise conventional technology (e.g. as implemented and/or integrated in exemplary embodiments, modifications, variations, combinations, equivalents, etc.) or may comprise any other applicable technology (present and/or future) with suitability and/or capability to perform the functions and processes/operations described in the specification and/or illustrated in the FIGURES. All such technology (e.g. as implemented in embodiments, modifications, variations, combinations, equivalents, etc.) is considered to be within the scope of the present inventions of the present patent document.

What is claimed is:

1. A component for a vehicle interior comprising:
a composite structure comprising a structural substrate comprising a compression-formed fiber panel and a conductor arrangement;
wherein the compression-formed fiber panel is formed by compression-forming of a fiber panel with the conductor arrangement;
wherein the conductor arrangement is configured to provide a functional circuit and a connection point;
wherein the composite structure comprises a feature for the connection point;
wherein the connection point comprises a connector for the functional circuit;
wherein the connector comprises a projection and/or a flange and/or a tab.

2. The component of claim 1 wherein the connector comprises a connector block.

3. The component of claim 1 wherein the connector comprises an internal connector.

4. The component of claim 1 wherein the connector comprises an external connector.

5. The component of claim 1 wherein the connector comprises an edge connector.

6. The component of claim 5 wherein the connector comprises an internal edge connector and/or an external edge connector.

7. The component of claim 5 wherein the edge connector comprises a tab on the composite structure configured to fit within a socket.

8. The component of claim 7 wherein the structural substrate comprises a generally flat form; wherein the tab is provided at a perimeter of the structural substrate and/or within a perimeter of the structural substrate.

9. The component of claim 7 wherein the tab is provided at an angle relative to the structural substrate.

10. The component of claim 1 wherein the connector is integrated on and/or within the compression-formed fiber panel; wherein the connector is configured to connect to the functional circuit at the connection point.

11. The component of claim 1 wherein the connector comprises a conductive trace and/or a pattern of conductive traces and/or a set of electrically conductive traces and/or a multi-layer conductor pattern and/or a set of conductive traces and/or a wire and/or an insulated wire and/or an exposed wire and/or a generally flat trace and/or a generally flat wire and/or a lead and/or a band and/or conductive wire and/or conductive thread.

12. The component of claim 1 wherein the connector is provided within the fiber panel and/or provided on the fiber panel and/or provided into the fiber panel and/or provided onto the fiber panel.

13. The component of claim 1 wherein the connector is formed into the compression-formed fiber panel.

14. The component of claim 1 wherein the connector of the composite structure comprises a plug for the connection point.

15. The component of claim 1 wherein the connector comprises a socket and a plug at the connection point; wherein the plug engages the socket to secure the connection of the functional circuit to vehicle systems.

16. The component of claim 1 wherein the feature comprises a formed feature and/or a resin feature and/or a formed resin feature and/or a molded resin feature and/or a formed structure and/or a molded structure and/or a molded resin structure and/or an injection-molded structure and/or a structure configured to provide support for the connector and/or a module for the connector and/or a resin structure and/or a molded structure and/or a reinforcement and/or a rib.

17. The component of claim 1 wherein the feature comprises a structure for the connector and/or a support for the connector and/or a housing for the connector.

18. The component of claim 1 wherein the feature comprises a reinforcement for the fiber panel and/or a reinforcement for the functional circuit and/or a structural reinforcement for the composite structure.

19. The component of claim 1 wherein the feature comprises at least one of a housing for an electrical connector and a cover for an electrical connector to the conductor arrangement and/or a connection point for the conductor arrangement and/or a wire.

20. The component of claim 1 wherein the connector is configured to connect to a power source and/or at least one vehicle system.
